(19) United States
(12) Patent Application Publication
(10) Pub. No.: US 2014/0319508 A1
(43) Pub. Date: Oct. 30, 2014

(54) ORGANIC ELECTROLUMINESCENT DISPLAY DEVICE

(71) Applicant: Konica Minolta, Inc., Tokyo (JP)

(72) Inventors: Norie Tanihara, Kobe-shi (JP); Rieko Ren, Kunitachi-shi (JP); Koji Tasaka, Hino-shi (JP); Yukihito Nakazawa, Kobe-shi (JP); Kenji Mishima, Chuo-ku (JP); Midori Kogure, Kobe-shi (JP)

(21) Appl. No.: 14/355,682

(22) PCT Filed: Nov. 7, 2012
(86) PCT No.: PCT/JP2012/078782

§ 371 Date: May 1, 2014

(30) Foreign Application Priority Data
Nov. 9, 2011 (JP) 2011-245021

(51) Int. Cl. H01L 51/50

(52) U.S. Cl. CPC H01L 51/5012
USPC 257/40

(57) ABSTRACT

In order to provide an organic electroluminescent display device which does not exhibit redness in reflected external light, and exhibits little fluctuation in the hue of a black image as a result of changes in environmental temperature and differences in the light emitting state, the organic electroluminescent display device according to the present invention comprises, in order from the viewing side, a protective film, a polarizer, a λ/4 phase difference film, and an organic electroluminescent element, and is characterized in that the λ/4 phase difference film satisfies formulas (1) and (2) below.

Ro(450)<Ro(550)<Ro(650) Formula (1)

0.90<photoelastic coefficient ratio(450/650)value<1.20 Formula (2)

### FILED OF THE INVENTION

The present invention relates to an organic electroluminescent display device, and specifically, relates to an organic electroluminescent display device that has improved displaying characteristics by virtue of a phase-difference film.

### BACKGROUND ART

An organic electroluminescent element (also referred to as an organic EL element) where a light-emitting layer is provided between electrodes and emits light by applying voltage to the layer has been widely studied and developed for uses in flat lights, light sources for optical fibers, backlights of liquid crystal displays, backlights of liquid crystal projectors and light sources for display devices.

An Organic EL element is excellent in terms of efficiency of light emission, driving at low voltage, lightweight and low production cost and thus has been attracting great attention.

An organic EL element emits visible light according to emission characteristics of a light-emitting layer where electrons and holes are injected from a cathode and an anode, respectively, followed by recombination of them.

For the electrode in a viewing side, indium tin oxide (ITO) is generally used because it has a highest electrical conductivity of transparent conductive materials.

On the other hand, the electrode on the other side is generally a metal electrode.

A metal material of this metal electrode has high light reflectivity, and thus functions not only as an electrode (cathode) but also as a reflector that reflects light emitted in a light-emitting layer, and also increase light intensity (brightness).

Hence, light emitted to the side opposite to the viewing side is specularly reflected by the surface of the metal material, and then extracted through the transparent ITO electrode as emitted light.

However, in a display device in which such organic EL elements are used, i.e., an organic electroluminescent display device (also referred to as an organic EL display device), a metal electrode is a specular surface having high light reflectivity. Thus, when light is not emitted, reflection of external light is very conspicuous.

Thus, background reflections such as reflections of interior lights are intense, which precludes expression of black color. Such an organic EL display device has extremely low contrast in a lit room.

As a remediation of this problem, Patent Document 1 discloses that a polarizing plate including a λ/4 phase difference film, which is a circularly polarizing element, on a viewing side of an organic EL element. Patent Document 1 also discloses a so-called reverse wavelength dispersion film composed of phase difference films as the above-mentioned λ/4 phase difference film where phase difference films which have different λ/4 phase differences are laminated to obtain a phase difference of λ/4 over in wavelengths of visible light for blocking reflection of external light in all wavelengths of visible light.

However, processes for laminating two phase difference films are complex, which increases production cost.

Patent Document 2 discloses that one sheet of λ/4 phase difference film prepared by adding a specific additive to cellulose ester has a good phase difference.

When such a phase difference film is used in an organic EL display device, reflection of external light can be blocked. However, red reflected light slightly remains, and thus neutral black color cannot be obtained. In addition, a hue of a black image is changed due to an ambient temperature change or a surface temperature change of the organic EL display device according to light emission state.

### PRIOR ART DOCUMENT

### Patent Document

Patent Document 1: Japanese Patent Application Laid-Open Publication No. Hei9-127885

Patent Document 2: Japanese Patent Application Laid-Open Publication No. 2011-75924

### SUMMARY OF THE INVENTION

### Problem to be Solved by the Invention

The present invention is made in view of the above problems and situations, and an object of the present invention is to provide an organic electroluminescent display device that cause no redness due to reflection of external light and suppress a change in hue of a black image due to changes in ambient temperature and light emission state.

### Means for Solving Problem

The present inventors have studied to solve the above problems, and revealed that when an in-plane retardation of a λ/4 phase difference film has a reverse wavelength dispersion properties and photoelastic coefficients have the same value in all wavelengths, no redness due to reflection of external light is caused and no change in hue of a black image due to temperature change.

That is, the above object of the present invention is solved by the following ways.

1. An organic electroluminescent display device including a protective film, a polarizer, a λ/4 phase difference film and an organic electroluminescent element in this order from a viewing side of the organic electroluminescent display device, wherein the λ/4 phase difference film satisfies the following expressions (1) and (2).

Ro(450)<Ro(550)<Ro(650) Expression (1)

0.90<ratio of photoelastic coefficients (450/650)<1.20 Expression (2)

In the expression (1), Ro(450), Ro(550) and Ro(650) are in-plane retardations obtained from measurement at 23° C. and 55% RH of the λ/4 phase difference film at a light wavelength of 450 nm, 550 nm and 650 nm, respectively; and in the expression (2), the ratio of photoelastic coefficients (450/650) is obtained by dividing a photoelastic coefficient (450) obtained from measurement at 23° C. and 55% RH of the λ/4 phase difference film at a light wavelength of 450 nm by a photoelastic coefficient (650) obtained from measurement under the same condition of the λ/4 phase difference film at a light wavelength of 650 nm.

2. The organic electroluminescent display device of the above 1, wherein the λ/4 phase difference film includes a cellulose ester(s), and at least one of the cellulose ester(s) satisfies the following expressions (3) and (4).

2.3≦A+B≦2.7 Expression (3)

0≦B≦2.0 Expression (4)

In the expressions (3) and (4), A represents a degree of substitution with an acetyl group, and B represents a degree of substitution with an acyl group other than an acetyl group.

3. The organic electroluminescent display device of the above 1 or 2, wherein the λ/4 phase difference film includes a compound represented by a following general formula (A).

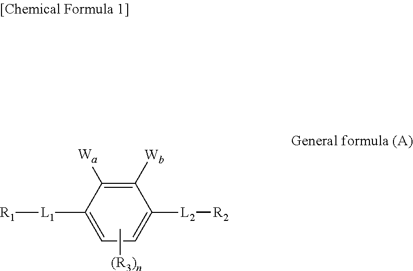

[In the general formula (A), L₁ and L₂ each independently represent a single-bond or divalent linking group; R₁, R₂ and R₃ each independently represent a substituent; n represents an integer from 0 to 2.]

Wa and Wb each represent a hydrogen atom or a substituent, wherein

(I) Wa and Wb are bonded to each other to form a ring;

(II) at least either of Wa and Wb contains a ring structure; or

(III) at least either of Wa and Wb may be an alkenyl group or alkynyl group.

4. The circularly polarizing plate of the above 3, wherein the compound represented by the general formula (A) is a compound represented by a following general formula (1).

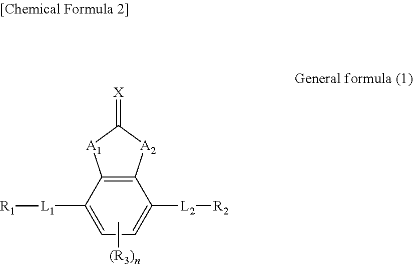

[In the general formula (1), A₁ and A₂ each independently represent O, S, NRx (Rx represents a hydrogen atom or a substituent) or CO; X represents a non-metal atom of Groups 14 to 16 of the periodic table; and L₁, L₂, R₁, R₂, R₃ and n correspond to L₁, L₂, R₁, R₂, R₃ and n of the general formula (A), respectively.]

5. The polarizing plate of the above 3, wherein the compound represented by the general formula (A) is a compound represented by a following general formula (2).

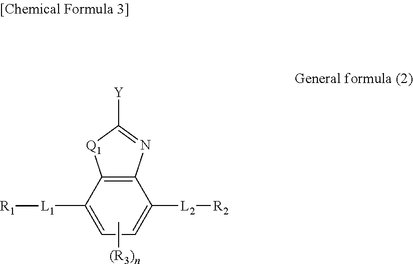

In the general formula (2), Q₁ represents O, S, NRy (Ry represents a hydrogen atom or a substituent), —CRaRb— (Ra and Rb each represent a hydrogen atom or a substituent) or CO; Y represents a substituent; and L₁, L₂, R₁, R₂, R₃ and n correspond to L₁, L₂, R₁, R₂, R₃ and n of the general formula (A), respectively.

6. The polarizing plate of the above 3, wherein the compound represented by the general formula (A) is a compound represented by a following general formula (3).

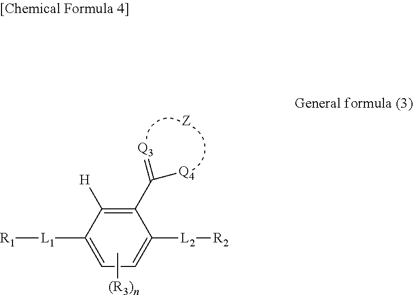

In the formula (3), Q₃ represents N or CRz (Rz represents a hydrogen atom or a substituent); Q₄ represents a non-metal atom of Groups 14 to 16 of the periodic table; Z represents a group of non-metal atoms forming a ring together with Q₃ and Q₄; and L₁, L₂, R₁, R₂, R₃ and n correspond to L₁, L₂, R₁, R₂, R₃ and n of the general formula (A), respectively.

7. The organic electroluminescent display device of any one of the above 1 to 6, wherein the λ/4 phase difference film is an obliquely stretched resin film.

### Effect of the Invention

By the above ways of the present invention, an organic electroluminescent display device that causes no redness due to reflection of external light and no change in hue of a black image due to a change in temperature. Mechanisms that provide effects of the present invention or mechanisms of action are not definitively determined, but the following reasoning can be made.

When a λ/4 phase difference film is used in an organic EL display device, reflection of external light can be suppressed, but remaining light mainly include red component.

Because the above-defined λ/4 phase difference film has reverse wavelength dispersion properties, red component in the reflected light is reduced. Even so, the red component still slightly remains in the reflected light. This means that reflection of external light and a hue change cannot be completely suppressed. The λ/4 phase difference film is adhered to an organic EL element, and their coefficients of thermal expansion are different from each other. Thus, in the case of temperature change or the like, stress arises in the λ/4 phase difference film. If a photoelastic coefficient (i.e., a change ratio of retardations caused by stress) changes according to light wavelength, this stress changes a hue of an image. On the other hand, if a ratio of photoelastic coefficients is adjusted in a certain range, a hue change can be suppressed.

In addition, when compound represented by the general formula (A) of the present invention contains an asymmetric structure, i.e., Wa and Wb, as substituents on the benzene ring and either of Wa and Wb contains an unsaturated group(s), the unsaturated group increases the number of electrons in the direction perpendicular to the bond axis of L₁ and L₂ which are linking groups, which increase the refractive index. Generally, a change in a refractive index according to wavelength tends to increase as the refractive index increases. When a compound represented by the general formula (A) is used in a cellulose acylate matrix, a main axis represented by L₁-benzene ring-L₂ of the compound represented by the general formula (A) is oriented in the direction same as a stretching direction by stretching, which increases changes in refractive indexes according to wavelength in the stretching direction and the direction perpendicular thereto and broadens the spectrum. Thus, redness of the reflected light is reduced.

In the case where the linking groups L₁ and L₂ positioned near the benzene ring have polarity, maldistribution of free electrons over the benzene ring arises. As a result, polarity and interactions in the compound represented by the general formula (A) are changed, which can largely improve solubility of the compound (A) in the cellulose acylate and prevent image blurring due to crystallization, phase separation etc.

### BRIEF DESCRIPTION OF DRAWING

FIG. 1 This is a diagram illustrating an example of a configuration of an organic electroluminescent display device of the present invention.

FIG. 2 This is a schematic diagram illustrating oblique stretching using a tenter.

### EMBODIMENT FOR CARRYING OUT THE INVENTION

The organic electroluminescent display device of the present invention includes a protective film, a polarizer, a λ/4 phase difference film and an organic electroluminescent element in this order from a viewing side of the organic electroluminescent display device, wherein the λ/4 phase difference film satisfies the expressions (1) and (2). This feature is common in the inventions of claims 1 to 7.

As an embodiment of the present invention, it is preferable that the λ/4 phase difference film contains a cellulose ester(s) and at least one of the cellulose ester(s) satisfies the expressions (3) and (4), in terms of benefit from effects of the present invention.

It is also preferable that the λ/4 phase difference film contains a compound represented by the general formula (A) in terms of benefit from effects of the present invention and prevention of image blurring.

It is also preferable that the λ/4 phase difference film contains a compound represented by the general formula (1), in terms of reducing redness due to reflection of external light.

It is also preferable that the λ/4 phase difference film contains a compound represented by the general formula (2) in terms of preventing reflection of external light and suppressing a hue change.

It is also preferable that the λ/4 phase difference film contains a compound represented by the general formula (3) in terms of reducing redness due to reflection of external light.

It is also preferable that the λ/4 phase difference film is an obliquely stretched resin film in terms of effectively producing a circularly polarizing plate.

The present invention, elements of the present invention and embodiments for carrying out the inventions will now be described in detail. In the present application, any range described with numbers includes the values described by the numbers as the minimum and maximum values of the range.

(Organic Electroluminescent Display Device)

The organic electroluminescent display device (also referred to as the organic EL display device) includes a light-emitting layer(s) between a transparent electrode and a metal electrode. Light generated in the light-emitting layer can be viewed through the transparent electrode. A top-emission type in which TFT for selective application of voltage is provided in the side of the metal electrode is preferable because this type has a large opening, highly bright images at low electrical power can be viewed and resolution can be increased.

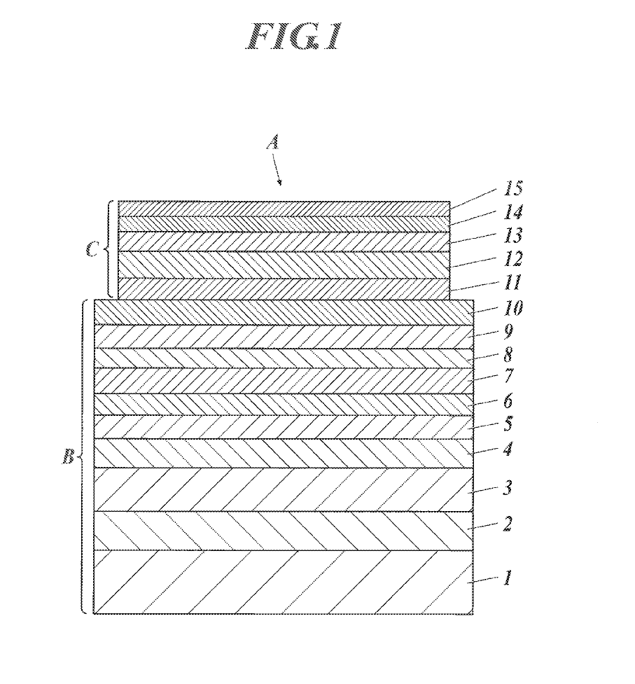

FIG. 1 illustrates a configuration of a top-emission type as an example of the organic EL display device of the present invention, but the present invention is not limited thereto.

In an organic EL display device B, a TFT 2, a metal electrode 3, a transparent electrode 4 (such as ITO), a hole-transporting layer 5, a light-emitting layer 6, a buffer layer 7 (such as calcium), a cathode 8 (such as aluminum), an ITO 9 and an insulating film 10 are provided on or over a substrate 1 in which glass, polyimide or other is used. On the organic EL display device B, a circularly polarizing plate C in which a polarizer 12 is provided between a T2 layer 11 (a λ/4 phase difference film) and a T1 layer 13. An organic EL display device A is thus structured. Preferably, a cured layer 14 is provided on the T1 layer 13. The cured layer 14 can prevents not only flaws on the surface of the organic EL display device but also warpage by the circularly polarizing plate. In addition, a reflection preventing layer 15 may be further provided on the cured layer. The thickness of the organic EL element is about 1 μm.

In general, in an organic EL display device, a metal electrode, an organic layer and a transparent electrode are laminated in this order on or over a transparent substrate to form an element that emits light (organic EL element). The organic layer is composed of laminated various thin organic layers. Examples include laminates with various known layer compositions: a laminate a hole-injecting layer formed of a triphenyl amine derivative or the like and a light-emitting layer formed of a fluorescent organic solid material such as anthracene and/or a phosphorescent substance, a laminate composed of such a light-emitting layer and an electron-injecting layer formed of a perylene derivative or the like, and a laminate composed of such a hole-injecting layer, such a light-emitting layer and such an electron-injecting layer, for example.

Light emission in the organic EL display device occurs on the following mechanism: holes and electrons are injected into a light-emitting layer upon voltage application to a transparent electrode and a metal electrode, energy is generated upon recombination of the holes and the electrons, the energy excites a fluorescent substance or a phosphorescent substance, and the excited fluorescent substance or the excited phosphorescent substance returns to the ground state and then emits light. Mechanisms of the recombination is similar to those of a conventional diode, and thus, current and luminance intensity show strong nonlinearity with rectification properties to the applied voltage as it can be anticipated from that similarity.

In the organic EL display device, at least one of the electrodes is required to be transparent to extract light from the light-emitting layer. Normally, a transparent electrode formed of a transparent electroconductive material such as indium tin oxide (ITO) is used as an anode. On the other hand, to increase efficiency of light emission by enhancing electron injection, it is important to use a material having small work function in a cathode. Normally, a metal electrode formed of Mg—Ag, Al—Li or the like is used.

Preferably, the outermost surface in a viewing side of the organic EL element is protected by a transparent layer. This transparent layer may be a glass plate or a layer formed by deposition. This transparent layer preferably has insulation properties. More preferably, the transparent layer is an insulating layer formed by deposition.

Examples of a material used for forming the transparent protective layer include silicon dioxide and silicon nitride.

In the organic EL display device of such a configuration, the light-emitting layer is a very thin layer with a thickness of about 10 to 20 nm. Thus, the light-emitting layer almost completely transmit light, like the transparent electrode. As a result, when light incident from outside of the transparent electrode passes through the transparent electrode and the light-emitting layer and then reflected by the metal electrode, this light travels to outside the transparent electrode again. Thus, a displaying surface of the organic EL display device is seen as a specular surface when viewed from the outside in a non-light-emitting period.

To prevent exterior light from being reflected by the organic EL element and traveling to outside the surface of the organic EL element, a polarizing plate formed by laminating a λ/4 phase difference film and a polarizer is provided on the surface of the organic EL element.

(Polarizing Plate)

The organic EL element includes the transparent electrode in the obverse side of the light-emitting layer which emits light upon voltage application and includes the metal electrode in the reverse side of the light-emitting layer. In the organic EL display device including this organic EL element, the polarizing plate is provided on the obverse side (i.e., the viewing side) of the organic EL element so that the λ/4 phase difference film faces to the obverse side of the organic EL element. Then, the organic EL display device is configured to include the λ/4 phase difference film between the organic EL element and the polarizer.

The polarizing plate of the present invention is configured to include the polarizer and the protective film, and the λ/4 phase difference film provided therebetween. The polarizing plate can be formed by adhering the protective film and the λ/4 phase difference film to the polarizer.

The λ/4 phase difference film and the polarizer block light that enters from the outside, passes through the polarizer and the λ/4 phase difference film, and is reflected by the metal electrode. Thus, the λ/4 phase difference film and the polarizer can prevent the specular surface of the metal electrode from being viewable from the outside. Especially, when an angle between polarizing directions of the λ/4 phase difference film and the polarizer is adjusted to π/4, it is able to make the specular surface of the metal electrode completely invisible.

Specifically, only linearly polarized component of external light entering into the organic EL display device can be transmitted. Generally, the linearly polarized light is converted into elliptically polarized light by a phase difference film. Especially in the case where the phase difference film is the λ/4 phase difference film and the angle between polarizing directions of the λ/4 phase difference film and the polarizer is π/4, the linearly polarized light is converted into circularly polarized light.

The circularly polarized light then passes through the transparent electrode and the organic thin layer, and is reflected by the metal electrode. Thereafter, the circularly polarized light passes through the organic thin layer and the transparent electrode again and is converted into linearly polarized light by the λ/4 phase difference film. This linearly polarized light is perpendicular to the polarizing direction of the polarizing plate and thus cannot pass through the polarizing plate. As a result, the specular surface of the metal electrode can be made completely invisible.

(Protective Film)

The polarizing plate is composed of the protective film layer, the polarizer and the λ/4 phase difference film in this order. The polarizing plate is adhered to the organic EL element to constitute the organic EL display device. The protective film is an optical film provided in the viewing side in the organic EL display device.

The protective film may be composed of a single layer or multiple layers. When the protective film is composed of multiple layers, a hard coat layer is preferably provided on the outermost surface in the viewing side of the protective film.

Examples of the protective film include cellulose ester films such as triacetylcellulose film, cellulose acetate propionate film, cellulose diacetate film and cellulose acetate butyrate film; polyester films such as polyethylene terephthalate and polyethylene naphthalate; polycarbonate films, polyarylate films, polysulfone films (including polyethersulfone); polyethylene films, polypropylene films, cellophanes, polyvinylidene chloride films, polyvinyl alcohol films, ethylene vinyl alcohol films, syndiotactic polystyrene films, norbornene resin films, polymethylpentene films, poly(ether ketone) films, poly(ether ketone imide) films, polyamide films, fluororesin films, nylon films, cycloolefin polymer films, polymethylmethacrylate films and acrylic films.

Among them, cellulose ester films, polycarbonate films, cycloolefin polymer films and polyester films are preferable. For the present invention, cellulose ester films are preferable in terms of optical properties, productivity and cost.

A cellulose ester used in the protective film has an acetyl group substitution degree of 2.80 to 2.95. In addition, it is preferable that an optical film used in the T1 layer contains a polyester plasticizer.

Examples of cellulose ester film used in the protective film include Konica Minolta TAC KC8UX, KC4UX, KC4UA, KC6UA, KC4CZ, KC5UX, KC8UCR3, KC8UCR4, KC8UCR5, KC8UY, KC4UY, KC4UE and KC12UR (manufactured by KONICA MINOLTA OPTO, INC).

In the case of the organic EL image display device for displaying 3D images, arrangement of the λ/4 phase difference film on the both surface of the polarizer can improve quality of displayed images. Thus, it is also preferable that the λ/4 phase difference film is used as the T1 layer which is the protective film of the present invention.

(Hard Coat Layer)

The protective film may have a hard coat layer (also referred to as a cured layer). The hard coat layer is desired to have high degree of hardness to avoid flaws on the surface caused in using the display device or manufacturing the circularly polarizing plate. The hard coat layer has a pencil hardness of preferably 3H or higher, and more preferably 4H or higher.

The pencil hardness is obtained in accordance with the pencil hardness evaluation of JIS K 5400 using test pencils of JIS S 6006 following humidity conditioning of the protective film with the cured layer at 23° C., 55% RH for 2 hours.

Preferably, Martens hardness (HMs) of the cured layer is 400 N/mm² or more and 800 N/mm² or less.

Martens hardness is determined as follows, using a micro-hardness tester using a triangular pyramid indenter having an angle between the indenter and the ridge line of 115°. The indenter is pressed against the hard coat surface on the film to reach about 1/10 of the thickness of the hard coat layer to obtain a test pressure-depth of indentation curve. In this curve, a slope (m) of the depths of indentation in the range of 50 to 90% of a maximum test pressure (Fmax) in proportion to the square root of the test pressure is obtained. Martens hardness is determined by the following equation using the slope (m).

1 HMs=1(N)/(26.4 mm²)

For the cured layer of the present invention, a known layer can be used without modification. A resin binder forming the cured resin will now be described. A preferable resin binder is an active energy ray curing resin. An active energy ray curing resin is a resin cured through crosslinking caused by irradiation of active ray such as ultraviolet ray and electron ray. Preferably, an active energy ray curing resin contains a monomer having an unsaturated ethylenic double bond(s). An active energy ray curing resin layer is formed by curing such a resin by irradiation of active ray such as ultraviolet ray and electron ray.

Typical examples of the active energy ray curing resin include ultraviolet curing resins and electron ray curing resins. Particularly, ultraviolet curing resins are preferable because they are excellent in mechanical layer strength (abrasion resistance and pencil hardness).

The ultraviolet ray curing resin preferably made using a multi-functional acrylate. Preferably, the multi-functional acrylate is selected from a group including pentaerythritol multifunctional acrylates, dipentaerythritol multifunctional acrylates, pentaerythritol multifunctional methacrylates and dipentaerythritol multifunctional methacrylates.

The multifunctional acrylate is a compound that contains two or more acryloyloxy groups and/or methacryloyloxy groups in its molecule. In using such compounds, one, or two or more compounds are mixed.

Oligomers such as a dimer or trimer of the above monomer may also be used. The content of the active energy ray curing resin is preferably 15% or more and less than 70% by mass to the solid components in the composition for forming the cured layer.

To enhance curing of the active energy ray curing resin, a photopolymerization initiator is preferably used and contained in the cured layer. Preferably, the content of the photopolymerization initiator is as follows: photopolymerization initiator:active energy ray curing resin=20:100 to 0.01:100 by mass.

Examples of the photopolymerization initiator include acetophenone, benzophenone, hydroxybenzophenone, Michler's ketone, α-amiloxime ester, thioxanthone and derivatives thereof, but not limited to them.

In the cured layer, a thermoplastic resin, a heat curing resin and a hydrophilic resin exemplified by gelatin may also be used as a binder. In addition, the hard coat layer may further include inorganic or organic particles to control slipperiness and refractive index.

On the viewing side of the cured layer, it is preferable to provide a reflection preventing layer. The reflection preventing layer can prevent decrease in image contrast caused by reflection of external light by the surface of the protective film or the cured layer.

(λ/4 Phase Difference Film)

The polarizing plate of the present invention is configured to include the protective film, the polarizer and the λ/4 phase difference film laminated in this order. When the polarizing plate is adhered to the organic EL element, the λ/4 phase difference film is then sandwiched by the polarizer and the organic EL element.

As described above, providing the polarizing plate with circularly polarizing properties can prevent decrease in contrast of black in a non-light-emitting cell due to reflection of external light by the metal electrode of the organic EL display device.

The λ/4 phase difference film of the present invention is a film that converts linearly polarized light of a specific wavelength into circularly polarized light (or converts circularly polarized light into linearly polarized light).

In the λ/4 phase difference film, in-plane retardation Ro is about ¼ of certain light wavelength (normally within the visible light region). The λ/4 phase difference film of the present invention has an Ro(550) obtained at a light wavelength of 550 nm of 110 to 170 nm, more preferably 120 to 160 nm, and further more preferably 130 to 150 nm.

In-plane retardation sis obtained by the following equation (5).

Ro=(nx−xy)×d Equation (5)

In the equation, nx and ny represent refractive index nx (the maximum refractive index in the plane of the film or refractive index in the slow axis) and refractive index ny (refractive index in a direction perpendicular to the slow axis in the plane of the film), respectively, at a wavelength of 450 nm, 550 nm or 650 nm at 23° C. and 55% RH; and d represents the thickness (nm) of the film.

In the present invention, Ro(450), Ro(550) and Ro(650) are in-plane retardations obtained at a light wavelengths of 450 nm, 550 nm and 650 nm, respectively, at 23° C. and 55% RH.

The λ/4 phase difference film of the present invention preferably has the in-plane retardation that is about ¼ of wavelength in the visible light region to obtain almost completely circularly polarized light in the visible light region.

To obtain such in-plane retardation that is about ¼ of wavelength in the visible light region, the film is required to have so-called reverse wavelength dispersion properties which strengthens retardation as wavelength increases in the wavelength range of 400 to 700 nm. Especially, DSP(450/550) (a ratio of Ro(450) to Ro(550)) is preferably 0.72 to 0.92, more preferably 0.76 to 0.88, and most preferably 0.79 to 0.85.

As to DSP (550/650) (a ratio of Ro(550) to Ro(650)), this DSP is preferably 0.75 to 0.97, more preferably 0.82 to 0.95, and most preferably 0.84 to 0.93.

A circularly polarizing plate is obtained by laminating the λ/4 phase difference film and the polarizer so that the angle between the slow axis of the film and the transmission axis of the polarizer is practically 45°. Here, “practically 45°” means the angle is between 40° to 50°. The angle between the slow axis of the λ/4 phase difference film and the transmission axis of the polarizer is preferably 41° to 49°, and more preferably 42° to 48°, furthermore preferably 43° to 47°, and most preferably 44° to 46°.

(Ultraviolet Absorber)

The λ/4 phase difference film or the protective film of the present invention preferably contains an ultraviolet absorber. Examples of the ultraviolet absorber include benzotriazoles, 2-hydroxybenzophenone and phenyl salicylate esters. Specific examples include benzotriazoles such as 2-(5-methyl-2-hydroxyphenyl)benzotriazole, 2-[2-hydroxy-3,5-bis(α,α-dimethylbenzyl)phenyl]-2H-benzotriazole and 2-3(3,5-di-t-butyl-2-hydroxyphenyl)benzotriazole; and benzophenones such as 2-hydroxy-4-methoxy benzophenone, 2-hydroxy-4-octoxybenzophenone and 2,2′-dihydroxy-4-methoxy benzophenone.

Among various ultraviolet absorbers, an ultraviolet absorber with a molecular weight of 400 or more is not easy to fly because it has high boiling point and is not easy to vaporize. Thus, even the relatively small amount of such an absorber can effectively improve resistance to climatic conditions.

Examples of the ultraviolet absorber with a molecular weight of 400 or more include benzotriazoles such as 2-[2-hydroxy-3,5-bis(α,α-dimethylbenzyl)phenyl]-2H-benzotriazole and 2,2-methylene bis[4-(1,1,3,3-tetrabutyl)-6-(2H-benzotriazole-2-yl)phenol]; hindered amines such as bis(2,2,6,6-tetramethyl-4-piperidyl) sebacate and bis(1,2,2,6,6-pentametyl-4-piperidyl) sebacate; and hybrid materials each containing a hindered phenol structure(s) and a hindered amine structure(s) in their molecules such as 2-(3,5-di-t-butyl-4-hydroxybenzyl)-2-n-butylmalonate-bis(1,2,2,6,6-pentamethyl-4-piperidyl) and 1-[2-[3-(3,5-di-t-butyl-4-hydroxyphenyl)propionyloxy]etyl]-4-[3-(3,5-di-t-butyl-4-hydroxyphenyl)propionyloxy]-2,2,6,6-tatramethyl piperidine. One of, or a mixture of two or more of them can be used. Among them, 2-[2-hydroxy-3,5-bis(α,α-dimethylbenzyl)phenyl]-2H-benzotriazole and 2,2-methylene bis[4-(1,1,3,3-tetrabutyl)-6-(2H-benzotriazole-2-yl)phenol] are particularly preferable.

Commercially available products of them can also be used. For example, TINUVINS manufactured by BASF Japan Ltd. such as TINUVIN 109, TINUVIN 171, TINUVIN 234, TINUVIN 326, TINUVIN 327, TINUVIN 328 and TINUVIN 928 are preferable used.

In addition to the above, various antioxidants may be used in the λ/4 phase difference film to suppress heat degradation and heat tinting in molding processes. An antistat may also be added to the film to provide the film with antistatic properties.

(Matting Agent)

To improve handleability of the λ/4 phase difference film of the present invention, the film preferably contains a matt agent such as fine particles of an inorganic material such as silicon dioxide, titanium dioxide, aluminum oxide, zirconium oxide, calcium oxide, kaolin, talc, calcinated calcium silicate, hydrated calcium silicate, aluminum silicate, magnesium silicate and calcium phosphate, and crosslinking polymers. Among them, silicon dioxide is preferable because it decrease haze in the film.

The average primary particles size of the fine particles is preferably 20 nm or less, more preferably 5 to 16 nm, and further more preferably 5 to 12 nm.

(Tension Softening Point)

The λ/4 phase difference film of the present invention is required to be durable in use under high temperature. Thus, the tension softening point of the λ/4 phase difference film is preferably 105 to 145° C. to ensure sufficient heat resistance, and particularly preferably 110 to 130° C.

An example of a method for measuring tension softening point is as follows. The TENSILON universal testing machine (RTC-1225A, manufactured by ORIENTEC Co., Ltd.) is used. An 120 mm long and 10 mm wide portion is sampled from the film, and the sample portion is then stretched by a tension of 10 N in temperature rising at a rate of 30° C./min. The temperature at 9 N is measured for three times, and the average of them is obtained as the tension softening point.

(Size Change Ratio)

In using the λ/4 phase difference film of the present invention in the organic EL display device of the present invention, the size change ratio (%) of the λ/4 phase difference film is preferably lower than 0.5%, and more preferably lower than 0.3% to prevent unevenness, change in phase difference, decrease in contrast and color unevenness due to size change caused by moisture absorption.

(Defects)

Preferably, the λ/4 phase difference film of the present invention includes few defects. Defects in this context means voids in the film caused by rapid vaporization during drying a solution for forming the film (foam defects), an extraneous object(s) contaminated in the film, the object(s) being contained in the original solution for forming the film or mixed in the film during the film formation (extraneous object defects), and the like.

Specifically, the number of the defects is preferably 1 per 10 cm square, more preferably 0.5 per 10 cm square, and further more preferably 0.1 per 10 cm square.

When the defect is round, the diameter of the defect is the diameter of the round object. When the defect is not round, the dimension of such a defect is determined as described below by microscope observation and then the maximum diameter (the diameter of its circumscribed circle) is obtained as the diameter of the defect.

When the defect is a gas bubble or an extraneous object, the dimension of the shadow of such a defect observed using a differential interference contrast microscope is obtained as the dimension of the defect. When the defect is a change in the surface shape such as flaws transferred from a roll or scratches, the dimension is obtained through observing the defect using reflected light of a differential interference contrast microscope.

If the dimension of the defect is not clear in the observation using reflected light, aluminum or platinum is deposited on the surface for the observation. To effectively obtain a quality film that is excellent in terms of the number of such defects, it is effective to perform microfiltration on a polymer solution just before casting, to increase cleanness of a surrounding area of the casting machine, and to set stepwise conditions of drying after casting for performing efficient drying preventing foams.

When the number of the defects is more than 1 per 10 cm square, productivity may decrease because the film may fractured from the defect(s) when the film is tensioned in, for example, a processing(s) in a post-process. When the diameter of the defect is 5 μm or more, such a defect can be visually observed with a polarizing plate, and thus a bright spot(s) may be generated when the film is used as an optical element.

(Fracture Elongation)

The fracture elongation of the λ/4 phase difference film of the present invention is preferably 10% or more, and more preferably 20% or more at least one direction in the measurement in accordance with JIS-K7127-1999.

The upper limit of the fracture elongation is not particularly limited, but is about 250% in practice. To increase the fracture elongation, it is effective to suppress the defects such as the extraneous object(s) and the foam(s) in the film.

(Total Light Transmittance)

The total light transmittance of the λ/4 phase difference film is preferably 90% or higher, and more preferably 93% or higher. Its practical upper limit is about 99%. To achieve excellent transparency expressed by the total light transmittance, it is effective to reduce diffusion and absorption of light in the film by avoiding use of any additives and macromolecules that absorb visible light and by removing extraneous objects by microfiltration. In addition, it is effective to reduce diffusion and reflection of light at the surface of the film by decreasing roughness of the film surface through decreasing roughness of the surface of any portion that contacts to the film (such as the surfaces of a cooling roll, a calendar roll, a drum, a belt, a base to which a solution is applied and a conveying roll) used in the film formation.

<Formation of λ/4 Phase Difference Film>

An example of a method for forming the λ/4 phase difference film of the present invention will now be described, but the present invention is not limited thereto. In forming the λ/4 phase difference film, an inflation method, a T-die method, calendaring, cutting, casting, an emulsion method and hot pressing may be used, for example.

The λ/4 phase difference film may be formed by either of solution casting and melt casting.

Solution casting is preferable in terms of avoiding tinting, extraneous object defects and optical defects such as die lines in the film.

In terms of transparency of the film, solution casting is preferable.

(Organic Solvent)

An Organic solvents employable in forming a dope when the λ/4 phase difference film of the present invention by solution casting may be any solvent that can dissolve both of cellulose acetate and other additive(s).

Examples of organochlorine solvents include methylene chloride, and examples of non-organochlorine solvents include methyl acetate, ethyl acetate, amyl acetate, acetone, tetrahydrofuran, 1,3-dioxolane, 1,4-dioxolane, cyclohexanone, ethyl formate, 2,2,2-trifluroethanol, 2,2,3,3-hexafluoro-1-propanol, 1,3-difluoro-2-propanol, 1,1,1,3,3,3-hexafluoro-2-methyl-2-propanol, 2,2,3,3,3-pentafluoro-1-propanol and nitro ethane. Methylene chloride, methyl acetate, ethyl acetate and acetone are preferably used.

In addition to the organic solvent, a linear or branched aliphatic alcohol of 1 to 4 carbons is contained in an amount of 1 to 40% by mass in the dope. When the ratio of the alcohol to the dope is more than 1% by mass, the web is gelled ad easy to be removed from a metal support. When the ratio of the alcohol to the dope is less than 40% by mass, dissolution of cellulose acetate in a non-organochlorine solvent can be enhanced.

An especially preferable dope is a dope composition where an acrylic resin, a cellulose acetate resin and acrylic particles is dissolved in a solvent composed of methylene chloride and a linear or branched aliphatic alcohol of 1 to 4 carbons wherein the content of the three materials is 15 to 45% by mass in the solvent.

Examples of the linear or branched aliphatic alcohol of 1 to 4 carbons include methanol, ethanol, n-propanol, isopropanol, n-butanol, sec-butanol and tert-butanol. Among them, ethanol is preferably because it is stable and has relatively low boiling point and good drying characteristics.

(Solution Casting)

The λ/4 phase difference film of the present invention can be manufactured by solution casting. Solution casting include a step for preparing a dope by dissolving a resin(s) and an additive(s) in a solvent(s), a step for casting the dope to a belt or drum metal support, a step for drying the casted dope to form a web, a step for removing the web, a step for stretching or keeping the width, a step for further drying and a step for rewinding the obtained film.

When the concentration of cellulose acetate in the dope is 10% by mass or more, stress due to the drying after the casting to a metal support can be reduced. When the concentration of cellulose acetate is 35% by mass or less, stress in filtration can be reduced and fineness of filtration can be improved. To obtain both of these advantages, the concentration of cellulose acetate in the dope is preferably 10 to 35% by mass, and more preferably 15 to 25% by mass. A metal support used in the solution casting is preferably a specular metal support. Examples of a preferable metal support include a stainless-steel belt or a drum with a plated surface of a cast.

The width of the cast may be in the range of 1 to 4 m. The surface temperature of the metal support in the casting ranges preferably from −50° C. to a temperature to the extent that the solvent does not boil and foam. Higher temperature is preferable because the speed of the drying of the web can be increased. However, when the temperature is too high, the web may foam or flatness may decrease.

The temperature of the metal support is preferably in the range from 0 to 100° C., and more preferably 5 to 30° C. Otherwise, a method for removing the web rich in a residual solvent by cooling and gelation of the web is also preferable. A method for controlling the temperature of the metal support, and examples include blowing hot or cool air and contacting hot water to the back side. The method using hot water is preferable because this method is efficient in heat conduction and shorten a period until the temperature of the metal support become stable.

In the case of using hot air, considering decrease in the temperature of the web caused by latent heat of vaporization of the solvent, the temperature of the hot air is higher than the boiling point of the solvent and also does not cause foaming.

Especially, it is preferable to conduct the drying effectively by changing the temperatures of the support and the drying air during the casting and the removal.

To provide the λ/4 phase difference film with good flatness, the amount of the residual solvent in the web at the removal of the web from the meal support is preferably 10 to 150% by mass, more preferably 20 to 40% by mass or 60 to 130% by mass, and most preferably 20 to 30% by mass or 70 to 120% by mass.

The amount of the residual solvent is determined by the following equation.

The amount of the residual solvent(% by mass)={(M−N)/N}×100

M represents the mass of a sample taken from the web or the film at any timing during or after the manufacturing of the web or the film, and N represents the mass of the sample after heating the sample of M for an hour at 115° C.

As to the dryings of the λ/4 phase difference film, it is preferable that the web is further dried after removed from the metal support to obtain an amount of the residual solvent of preferably 1% by mass or less, more preferably 0.1% by mass, and most preferably 0 to 0.01% by mass.

For the step of drying the film, roll drying (a drying method using many rolls arranged above the other through which the web is passed one after another to dry the web) or tentering where the web is dried while the web is conveyed.

(Stretching)

The λ/4 phase difference film of the present invention has in-plane retardation (550) obtained from the measurement at a wavelength of 550 nm is 100 to 180 nm. This retardation is preferably obtained by stretching the film.

A method for stretching the film is not particularly limited. Examples include a method for stretching in the longitudinal direction by setting different rim speeds of rolls and utilizing the difference(s) between the rim speeds, a method for stretching in the longitudinal direction by widening the interval of clips or pins that hold the ends of the web, a method for stretching in the lateral direction by the similar way and a method for stretching in both of the longitudinal and lateral directions by widening the intervals in the both directions. These method may be combined. That is, the stretching direction may be lateral, longitudinal or both to the film formation direction. The stretching in the both directions may be conducted simultaneously or successively. In the case of using tentering, it is preferably that the clips are moved by a linear driving technology because this enables smooth stretching and reduces possibility of fracture etc.

For the present invention, tentering in which clips hold the ends of the web in the direction parallel to the conveying direction or perpendicular to the conveying direction (also referred to as the width direction or TD direction) utilizing a difference(s) between rim speeds of film-conveying rolls. A method for stretching the web using a side-to-side clip in which the holding length (the length from one holding position to the other) can be independently controlled at right and left ends. Oblique stretching using this clip us particularly preferable.

To obtain an orientation angle 0 of 35° to 55° to the longitudinal direction of the long λ/4 phase difference film, it is preferable to stretch the λ/4 phase difference film of the present invention in the direction at 45° to the film conveying direction in the stretching step.

When the above-described long polarizing film (polarizer) having a slow axis parallel to its longitudinal direction and a transmission axis perpendicular to its longitudinal direction is adhered to the long λ/4 phase difference film having an orientation angle of practically 45° by matching their longitudinal sides using a roll-to-roll method, a circularly polarizing plate can be manufactured without difficulties, and this is advantageous because loss in film cutting can be reduced.

A method for stretching in the 45-degree direction will now be described.

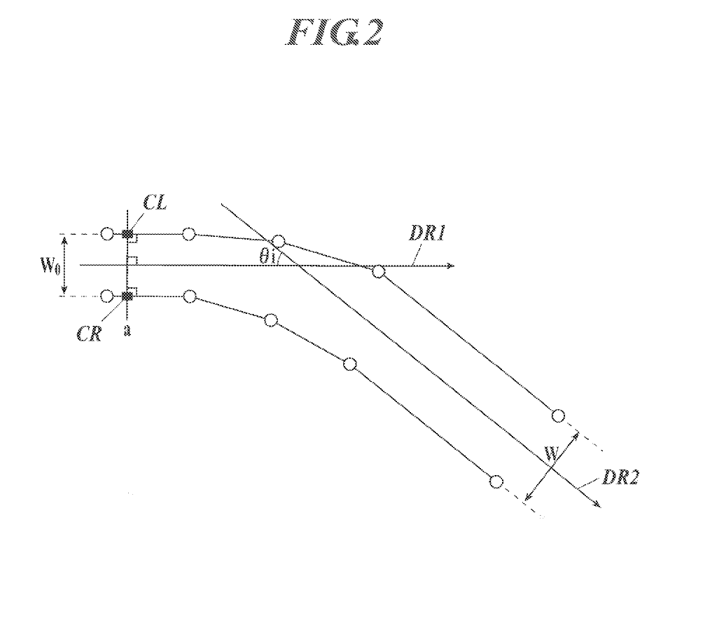

To obliquely stretch the λ/4 phase difference film at practically 45° to its longitudinal direction, a tenter illustrated in FIG. 2 is preferably used. FIG. 2 is a schematic diagram illustrating oblique stretching using a tenter.

A tenter is used for manufacturing the stretched film. The tenter is a device that broaden a film fed from a film roll (feeding roll) in the direction oblique to its conveying direction (direction in which the midpoint in the width direction of the film travels) with heat application using an oven. The tenter includes the oven, a left-and-right-pair of rails on which clips used for conveying the film travel and the clips that travel on the rails. The both ends of the film continuously fed from a film roll and into an inlet portion of the tenter are held by the clips CL and CR to convey the film to the oven. Then the film is released from the clips in an outlet portion of the tenter. The film released from the clips is then rewound on a core. The pair of the rails have endless continuous orbitals. The clips that have released the film travel on the excurvature portions of the rails and successively back to the inlet portion.

The rails of the tenter is asymmetrically shaped depending on the orientation angle to be provided with a stretched film to be manufactured and a stretching ratio and can be adjusted manually or automatically. In the present invention, the adjustment can be made so that the orientation angle can be controlled in the range of 10° to 80° to the direction of the rewinding after the stretching in the stretching of the long thermoplastic resin film. In the present invention, the clips of the tenter travel at a fixed intervals between its adjacent clips at a fixed speed.

FIG. 2 illustrates the track of the rails (rail patterns) of the tenter used for the oblique stretching. The λ/4 phase difference film-feeding direction DR1 is different from the film-rewinding direction (MD direction) DR2 after the stretching. By this configuration, homogeneous optical properties can be obtained in a wide range even in a stretched film having relatively large orientation angle. The feeding angle θi is an angle between the film-feeding direction DR1 before the stretching and the film-rewinding direction DR2 after the stretching. In the present invention, to manufacture a film having an orientation angle of, e.g., 40° to 80°, the feeding angle θi is adjusted to 10°<θ<60°, and preferably 15°<θ<50°. By adjusting the feeding angle θi to be in this range, the obtained film is excellent in variation in optical properties in its width direction (i.e., variation in optical properties in its width direction can be reduced).

The λ/4 phase difference film fed from the film roll (feeding roll) is successively held with the clips at a tenter inlet (the position represented by the letter a) at its both ends, and then conveyed with the travelling clips. The right and left clips CR and CL face to each other in the direction almost perpendicular to the direction in which the film is conveyed (the feeding direction DR1) at the tenter inlet (the position represented by the letter a). The right and left clips CR and CL travel on the asymmetric rails and pass through the oven in which a pre-heating zone, a stretching one and a heat-fixing zone are arranged. The definition of “almost perpendicular to the feeding direction DR1” herein means that the angle between the line connecting the clip CR with the clip CL that face to each other and the film-feeding direction DR1 is 90±1°.

The pre-heating zone is a section where the clips that hold the both ends pass through at a fixed interval between these clips. The stretching zone is a section where the interval between the clips begins to wide and stops widening at the end. A cooling zone is a section where the temperature in the zone is set at the glass temperature Tg of the thermoplastic resin forming the film or less within a zone where the interval between the clips is fixed again and is downstream of the stretching zone.

The temperature in each zone is adjusted, compared to the glass temperature Tg of the thermoplastic resin, preferably as follows: the temperature in the pre-heating zone is Tg+5° C. to Tg+20° C.; the temperature of the stretching zone is Tg to Tg+20° C.; and the temperature of the cooling zone is Tg-30° C. to Tg.

A stretching ratio R (W/Wo) in the stretching step is preferably 1.3 to 3.0, and more preferably 1.5 to 2.8. The stretching ratio in this range is preferable because unevenness of the thickness in the width direction can be reduced. When the stretching employs the temperatures varying in the width direction, the unevenness of the thickness in the width direction can be reduced to a more preferable level. Wo represents the width of the film before the stretching, and W represents the width of the film after the stretching.

The oblique stretching may be conducted within the film formation steps (on the film formation line). Otherwise, the stretching may be conducted after the rewinding of the film through feeding the rewound film using the tenter (off the film formation line).

The λ/4 phase difference film can be dried by any method without particular limitation. Normally, the drying may be conducted using hot air, infrared ray, a heating roll, microwave etc. In terms of simplicity, using hot air is preferable.

The drying steps of the λ/4 phase difference film is conducted preferably at a drying temperature of Tg-5° C. and Tg+100° C. for 10 to 60 min. The drying temperatures are preferably 100 to 200° C., and more preferably 110 to 160° C.

After the drying, it is preferable to cut the edge portions of the film using a slitter before the rewinding to obtain a good roll shape. In addition, knurling is performed on the both edge portions in the width direction.

Knurling can be formed by pressing a heated embossed roll against the film. On the embossed roll, very fine asperities are formed. By pressing the asperities against the film, asperities are formed on the film, and the bulks of the edge portions can be increased.

Preferably, the height of the knurl in the both edge portions of the λ/4 phase difference film in its width direction is 4 to 20 μm, and the width is 5 to 20 mm.

In the present invention, the knurling is formed after the drying and before the rewinding in the film formation steps.

(Melt Film Formation)

The λ/4 phase difference film of the present invention may be formed by melt film formation. Melt film formation is a method in which a composition containing a resin and an additive such as a plasticizer is heated and melted so as to give fluidity to the composition, and then the melted composition containing the cellulose acetate with the given fluidity is casted.

More specifically, molding by heating and melting is categorized into melt extrusion molding, press molding, an inflation method, injection molding and stretch molding, for example. Among them, melt extrusion molding is preferable in terms of mechanical strength and surface fineness. In melt extrusion molding, it is preferable to knead and pelletize materials.

Pelletizing may be conducted by any known method. For example, pellets can be formed through feeding a dried cellulose acetate, a plasticizer and other additive using a feeder to an extruder, kneading the resulting material using the single- or double-screw extruder, extruding the kneaded material in the form of strand through a die, cooling the extruded material with water or air and cutting the cooled material.

The additive(s) may be mixed in advance of the feeding to an extruder or fed thereto with another feeder.

Minor additives such as particles and an antioxidant are preferably mixed in advance to homogeneously mix them.

In using the extruder, it is preferable to suppress shear force of the extruder at as low temperature as possible to enable forming pellets and suppressing deterioration of the resin (e.g., decrease in molecular weights, coloring and gelation etc.). In the case of using a double-screw extruder, it is preferable that its screws are deep groove screws that are rotated to the same direction. In terms of homogeneous kneading, it is preferable that screws mesh with each other.

The pellets obtained as described above are used for forming the film. Otherwise, powders of materials may be fed from a feeder to an extruder and used in the film formation.

A single- or double-screw extruder is used to extrude the pellets at a melting temperature of about 200 to 300° C., and then extraneous objects are removed by filtration using a leaf disk filter or the like. Subsequently, the resultant material is casted in a form of film from a T-die, and the film is nipped by a cooling roll and an elastic touch roll, followed by solidification of the film on the cooling roll.

In feeding from a feeding hopper to the extruder, it is preferable to avoid oxidative decomposition by employing vacuum, depressurized or inert gas atmosphere.

The extrusion amount is preferably stabilized by using a gear pump. The filter used for removing extraneous objects is preferably a sintered stainless fiber filter. A sintered stainless fiber filter is manufactured through compressing complexly entwining stainless fibers and sintering their contacting portion. Fineness of the filtration can be adjusted by controlling the density of the fiber based on the diameters and the compressing amount.

The additives such as a plasticizer and particles may be mixed in the resin in advance or may be kneaded with the resin in the extruder. To homogeneously add the additives, it is preferable to use a mixing device such as a static mixer.

The temperature of the film on the side of the elastic touch roll in the nipping of the film with the cooling roll and the elastic touch roll is preferably Tg of the film or more and the Tg+110° C. The roll having an elastic surface used in this purpose may be a known roll.

The elastic touch roll is also referred to as a gripping rotating body. The elastic touch roll may be a commercially available roll.

In removing the film from the cooling roll, it is preferable to avoid distortion of the film by controlling the tension.

Preferably, the film obtained as described above is stretched by the above stretching after the step in which the film is contacted with the cooling roll.

The stretching may be conducted using a known roll stretching device or tenter. The oblique stretching described in the description of the solution casting is preferable. Normally, preferred stretching temperature is Tg of the resin forming the film to Tg+60° C.

Before the rewinding, it is preferable that the edge portions are cut out from the film to adjust the width of the film in to a width for a commercially available product. In addition, knurling (embossing) may be performed on the edge portions of the film to avoid adhesion or scratches that may be caused in the rewinding. The knurl may be formed by heating or pressing a metal ring having a side surface with asperities. The both end portions held with the clips are cut and reused because these portions are normally distorted and thus cannot be used as a commercialized product.

<Physical Properties of λ/4 Phase Difference Film>

The thickness of the λ/4 phase difference film of the present invention is not particularly limited but preferably 10 to 250 μm. Particularly, the thickness is preferably 10 to 100 μm, and more preferably 30 to 60 μm.

The width of the λ/4 phase difference film of the present invention is 1 to 4 m. The width is preferably 1.4 to 4 m, and more preferably 1.6 to 3 m. The film having a width of longer than 4 m is difficult to convey.

The arithmetic average roughness Ra of the λ/4 phase difference film of the present invention is preferably 2.0 to 4.0 nm, and more preferably 2.5 to 3.5 nm.

(Measurement of In-plane Retardation Ro)

Ro=(nx−ny)×d Equation

In the equation, nx and ny each represent the refractive index nx (the maximum refractive index in the plane of the film or the refractive index in the slow axis) and the refractive index ny (refractive index in the direction perpendicular to the slow axis in the plane of the film) at a light wavelength of 450 nm, 550 nm or 650 nm at 23° C. and 55% RH, and d represents the thickness (nm) of the film.

Ro(450)/Ro(550) and Ro(550)/Ro(650) are each obtained and used to calculate the wavelength dispersions, and the wavelength dispersions are described by DSP(450/550) and DSP(550/650), respectively.

The above-described Ro can be measured using an automatic double refractometer. An automatic double refractometer AxoScan manufactured by Axometrics Inc. is used for the measurement at each wavelength at 23° C. and 55% RH to obtain each Ro.

Simultaneously, the measurement in the slow axis to the width direction of the film is also be conducted. In-plane retardation at a wavelength A is described by Ro(A).

(Ratio of Photoelastic Coefficients)

Photoelastic coefficient correspond with a slope of a curve (or a line) of the in-plane retardation to the tension per width of the film, which in-plane retardation is obtained applying the tension to the film and which curve is obtained by plotting values from the measurement in which the tension is varied.

In the present invention, the photoelastic coefficient is measured by the following way.

KOBRA-31PRW (manufactured by Oji Scientific Instruments) is used to conduct a stretching test through measuring a 15 mm by 60 mm sample piece with 10 different tensions in the range of 1 to 15 N. In-plane retardation at each tension is obtained and then the in-plane retardation is plotted to each tension. The photoelastic coefficient is obtained from the slope and the width of the sample piece. The measurement is conducted at 23° C. and 55% RH.

Light wavelengths at which in-plane retardation are 450 nm, 550 nm and 650 nm. The photoelastic coefficient is obtained for each wavelength. The ratio of the photoelastic coefficient at a wavelength of 450 nm to that at a wavelength of 650 nm is determined as the ratio of photoelastic coefficients.

The ratio of photoelastic coefficients varies depending on the resin used in the λ/4 phase difference film, and thus can be controlled through selecting a resin to be used. In the case of using a cellulose acetate resin, the ratio tends to vary depending on the total acyl group substitution degree. The ratio of photoelastic coefficients also varies depending on the additive(s).

The ratio of photoelastic coefficients (450/650) of the λ/4 phase difference film of the present invention is 0.90 to 1.20. The ratio of photoelastic coefficients (450/650) is preferably 0.93 to 1.15 because a hue change is small, and more preferably 0.95 to 1.10, and most preferably 1.00 to 1.05.

(Compound Represented by General Formula (A))

The general formula (A) will now be described in detail.

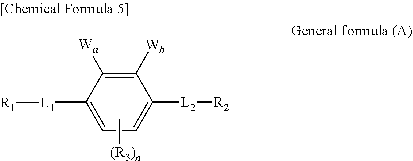

In the general formula (A), L₁ and L₂ each independently represent a single-bond or a divalent linking group.

Examples of L₁ and L₂ include the following structures (R below represents a hydrogen atom or a substituent).

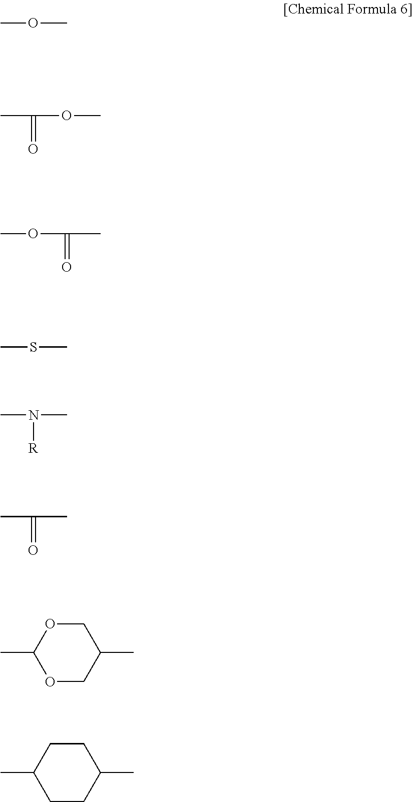

Preferably, L₁ and L₂ are each O, —COO— or —OCO—.

R₁, R₂ and R₃ each independently represent a substituent. Examples of the substituents represented by R₁, R₂ and R₃ include halogen atoms (such as fluorine atom, chlorine atom, bromine atom and iodide atom); alkyl groups (methyl group, ethyl group, n-propyl group, isopropyl group, tert-butyl group, n-octyl group and 2-ethylpentyl group); cycloalkyl groups (such as cyclohexyl group, cyclopentyl group and 4-n-dodecylcyclohexyl group); alkenyl groups (such as vinyl group and allyl groups); cycloalkenyl groups (such as 2-cyclopentene-1-yl group and 2-cyclohexene-1-yl group); alkynyl groups (such as ethynyl group and propargyl group); aryl groups (such as phenyl group, p-tolyl group and naphthyl group); hetero ring groups (such as 2-furyl group, 2-pyrimidinyl group and 2-benzothiazolyl group); cyano group; hydroxyl group; nitro group; carboxy group; alkoxy groups (such as methoxy group, ethoxy group, isopropoxy group, tert-butoxy group, n-octyloxy group and 2-methoxyethoxy group); aryloxy groups (such as phenoxy group 2-methylphenoxy group, 4-tert-butylphenoxy group, 3-nitrohenoxy group and 2-tetradecanoylaminophenoxy group); acyloxy groups (such as formyloxy group, acetyloxy group, pivaloyloxy group, stearoyloxy group, benzoyloxy group, and p-methoxyphenylcarbonyloxy group); amino groups (such as amino group, methylamino group, dimethylamino group, anilino group, N-methyl-anilino group and diphenylamino group); acylamino group (such as formylamino group, acetylamino group, pivaloylamino group, lauroylamino group and benzoylamino group); alkyl and aryl sulfonylamino groups (such as methylsulfonyl amino group, butylsulfonyl amino group, phenylsulfonyl amino group, 2,3,5-trichlorophenylsulfonyl amino group and p-methylsulfonyl amino group); mercapto groups; alkylthio groups (such as methylthio group, ethylthio group and n-hexadecylthio group); arylthio groups (such as phenylthio group, p-chlorophenylthio group and m-methoxyphenylthio group); sulfamoyl groups (such as N-ethylsulfamoyl group, N-(3-dodecyloxypropyl)sulfamoyl group, N,N-dimethylsulfamoyl group, N-acetylsulfamoyl group, N-benzoylsulfamoyl group and N—(N′-phenylcarbamoyl)sulfamoyl group)); sulfo groups; acyl groups (such as acetyl group and pivaloylbenzoyl group); and carbamoyl groups (such as carbamoyl group, N-methylcarbamoyl group, N,N-dimethylcarbamoyl group, N,N-di-n-octylcarbamoyl group and N-(methylsulfonyl)carbamoyl group).

R₁ and R₂ are preferably substituted or non-substituted phenyl group, or substituted or non-substituted cyclohexyl group, more preferably substituted phenyl group or substituted cyclohexyl group, and further more preferably 4-substituted phenyl group or 4-substituted cyclohexyl group.

Preferable examples of R₃ are hydrogen atom, halogen atoms, alkyl groups, alkenyl groups, aryl groups, hetero ring groups, hydroxyl groups, carboxy groups, alkoxy groups, aryloxy groups, acyloxy groups, cyano groups and amino groups. More preferable examples of R₃ are hydrogen atom, alkyl groups, cyano groups and alkoxy groups.

Wa and Wb each represent a hydrogen atom or a substituent, wherein

(I) Wa and Wb are bonded to each other to form a ring(s),

(II) at least one of Wa and Wb contains a ring structure(s), or

(III) at least one of Wa and Wb is an alkenyl group(s) or an alkynyl group(s).

Examples of the substituents represented by Wa and Wb include hydrogen atom, halogen atoms (such as fluorine atom, chlorine atom, bromine atom and iodide atom); alkyl groups (methyl group, ethyl group, n-propyl group, isopropyl group, tert-butyl group, n-octyl group and 2-ethylpentyl group); cycloalkyl groups (such as cyclohexyl group, cyclopentyl group and 4-n-dodecylcyclohexyl group); alkenyl groups (such as vinyl group and allyl groups); cycloalkenyl groups (such as 2-cyclopentene-1-yl group and 2-cyclohexene-1-yl group); alkynyl groups (such as ethynyl group and propargyl group); aryl groups (such as phenyl group, p-tolyl group and naphthyl group); hetero ring groups (such as 2-furyl group, 2-pyrimidinyl group and 2-benzothiazolyl group); cyano group; hydroxyl group; nitro group; carboxy group; alkoxy groups (such as methoxy group, ethoxy group, isopropoxy group, tert-butoxy group, n-octyloxy group and 2-methoxyethoxy group); aryloxy groups (such as phenoxy group 2-methylphenoxy group, 4-tert-butylphenoxy group, 3-nitrohenoxy group and 2-tetradecanoylaminophenoxy group); acyloxy groups (such as formyloxy group, acetyloxy group, pivaloyloxy group, stearoyloxy group, benzoyloxy group, and p-methoxyphenylcarbonyloxy group); amino groups (such as amino group, methylamino group, dimethylamino group, anilino group, N-methyl-anilino group and diphenylamino group); acylamino group (such as formylamino group, acetylamino group, pivaloylamino group, lauroylamino group and benzoylamino group); alkyl and aryl sulfonylamino groups (such as methylsulfonyl amino group, butylsulfonyl amino group, phenylsulfonyl amino group, 2,3,5-trichlorophenylsulfonyl amino group and p-methylsulfonyl amino group); mercapto groups; alkylthio groups (such as methylthio group, ethylthio group and n-hexadecylthio group); arylthio groups (such as phenylthio group, p-chlorophenylthio group and m-methoxyphenylthio group); sulfamoyl groups (such as N-ethylsulfamoyl group, N-(3-dodecyloxypropyl) sulfamoyl group, N,N-dimethylsulfamoyl group, N-acetylsulfamoyl group, N-benzoylsulfamoyl group and N—(N′-phenylcarbamoyl) sulfamoyl group)); sulfo groups; acyl groups (such as acetyl group and pivaloylbenzoyl group); and carbamoyl groups (such as carbamoyl group, N-methylcarbamoyl group, N,N-dimethylcarbamoyl group, N,N-di-n-octylcarbamoyl group and N-(methylsulfonyl) carbamoyl group).

The above-listed substituent may be substituted with the above-listed substituent(s).

In the case (1) where Wa and Wb are bonded to each other to form a ring(s), examples of the compound represented by the general formula (A) include compounds containing the structure described below.

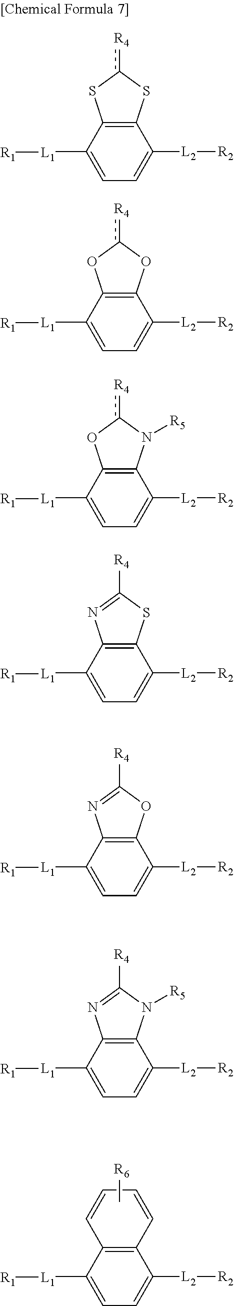

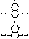

(R₄, R₅ and R₆ each represent a hydrogen atom or a substituent.)

In the case where Wa and Wb are bonded to each other to form a ring(s), the ring is preferably a nitrogen-containing five-membered ring or a sulfur-containing five-membered ring, and more preferably a compound represented by the following general formula (1) or (2).

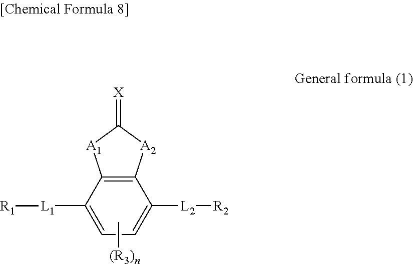

In the general formula (1), A₁ and A₂ each independently represent O, S, NRx (Rx represents a hydrogen atom or a substituent) or CO. Examples of the substituent represented by Rx correspond to the examples of the substituents represented by Wa and Wb. Preferably, Rx is a hydrogen atom, an alkyl group, an aryl group or a hetero ring group.

In the general formula (1), X represents a non-metal atom of Groups 14 to 16 of the periodic table.

Preferably, X is O, S, NRc or C(Rd)Re. Rc, Rd and Rc each represent a substituent, and examples of this substituent correspond to the examples of the substituents represented by Wa and Wb.

L₁, L₂, R₁, R₂, R₃ and n each correspond to L₁, L₂, R₁, R₂, R₃ and n of the general formula (A).

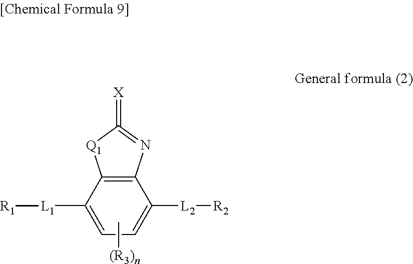

In the general formula (2), Q₁ represents O, S, NRy (Ry represents a hydrogen atom or a substituent), —CRaRb— (Ra and Rb each represent a hydrogen atom or a substituent) or CO. Ra and Rb each represent a substituent, and examples of the substituents represented by Ry, Ra and Rb each correspond to the examples of the substituents represented by Wa and Wb.

Y represents a substituent.

Examples of the substituent represented by Y each correspond to the examples of the substituents represented by Wa and Wb.

Preferably, Y is an aryl group, a hetero ring group, an alkenyl group or an alkynyl group.

Examples of the aryl group represented by Y include phenyl groups, naphthyl groups, anthryl groups, phenanthryl groups and biphenyl groups. Phenyl groups and naphthyl groups are preferable, and phenyl groups are more preferable.

Examples of the hetero ring groups represented by Y include hetero ring groups containing at least one hetero atom such as nitrogen atom, oxygen atom and sulfur atom, such as phenyl groups, naphthyl groups, anthryl groups, phenanthryl groups, thiazolyl groups and benzothiazolyl groups. Furyl groups, pyrrolyl groups, thienyl groups, pyridinyl groups and thiazolyl groups are preferable.

These aryl groups and hetero ring groups may be substituted with at least one substituent. Examples of the substituent include halogen atoms, alkyl groups of 1 to 6 carbons, cyano group, nitro group, alkylsulfonyl groups of 1 to 6 carbons, carboxy group, fluoroalkyl groups of 1 to 6 carbons, alkoxy groups of 1 to 6 carbons, alkylthio groups of to 6 carbons, N-alkylamino groups of 1 to 6 carbons, N,N-dialkylamino groups of 2 to 12 carbons, N-alkylsulfamoyl groups of 1 to 6 carbons and N,N-dialkylsulfamoyl groups of 2 to 12 carbons.

L₁, L₂, R₁, R₂, R₃ and n each correspond to L₁, L₂, R₁, R₂, R₃ and n of the general formula (A).

In the case (2) where at least of Wa and Wb contains a ring structure(s) in the general formula (A), examples of the ring structures include the followings.

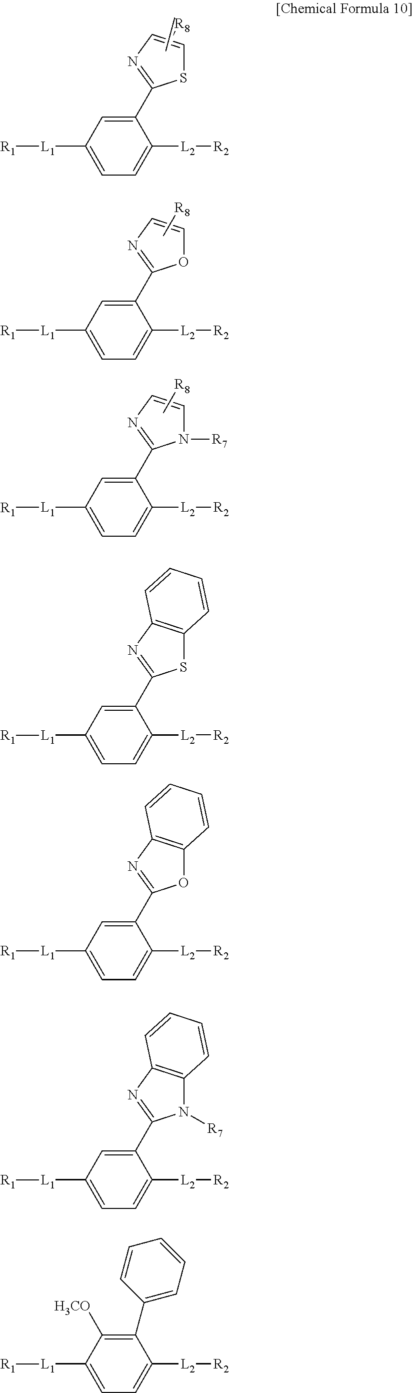

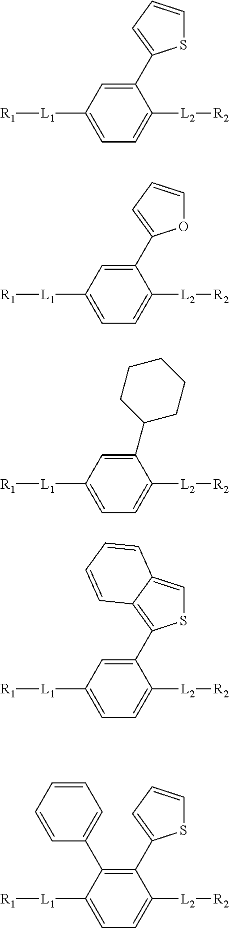

(R7 and R8 each represent a hydrogen atom or a substituent.)

Particularly preferable structures are represented by the following general formula (3).

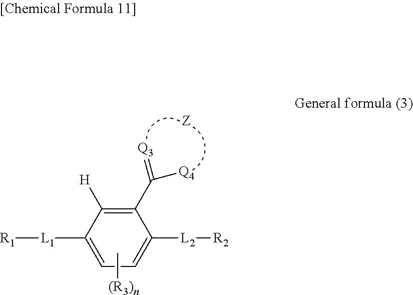

In the general formula (3), Q₃ represents N or CRz (Rz represents a hydrogen atom or a substituent), and Q₄ represents a non-metal atom of Groups 14 to 16 of the periodic table. Z represents a group of non-metal atoms forming a ring together with Q₃ and Q₄

The ring formed of Q₃, Q₄ and Z may be fused with another ring.

The ring formed of Q₃, Q₄ and Z is preferably a nitrogen-containing five or six-membered ring containing a fused benzene rings.

L₁, L₂, R₁, R₂, R₃ and n correspond to L₁, L₂, R₁, R₂, R₃ and n of the general formula (A), respectively.

In the case (3) where at least one of Wa and Wb is an alkenyl group or an alkynyl group, it is preferable that at least one of Wa and Wb is a substituted vinyl group or a substituted ethynyl group.

Among the compounds represented by the general formulae (1), (2) and (3), the compounds represented by the general formula (3) are preferable.

The compounds represented by the general formula (3) are excellent in heat resistance and light resistance compared to the compound represented by the general formula (1), and are excellent is solubility in an organic solvent and compatibility with a polymer compared to the compounds represented by the general formula (2).

The content of the compound represented by the general formula (A) can be adequately controlled to provide desired wavelength dispersibility and blurring preventing properties. This content is preferably 1 to 15% by mass, and more preferably 2 to 10% by mass to the amount of the cellulose derivative. When the content is in this range, sufficient wavelength dispersibility and blurring preventing properties can be provided with the cellulose derivative of the present invention.

Examples of the compounds represented by the general formula (A) are described below, but the compound represented by the general formula (A) is not limited to the following examples.

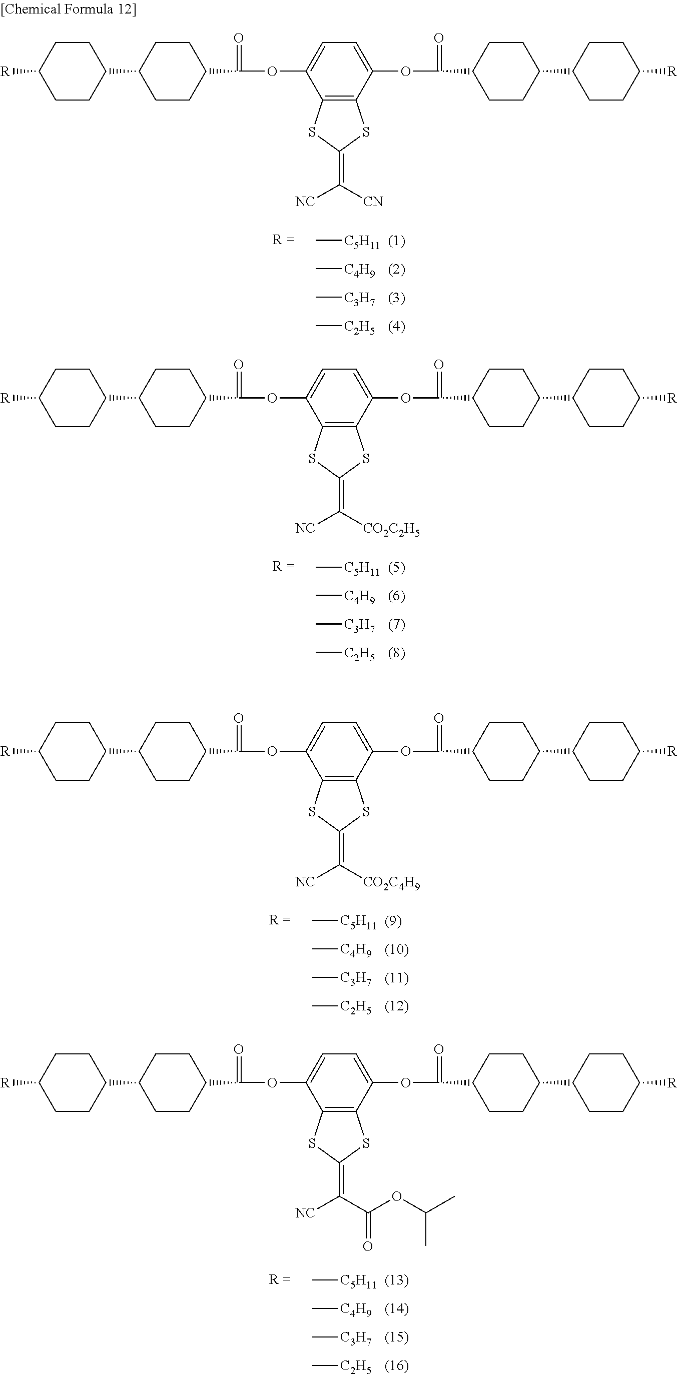

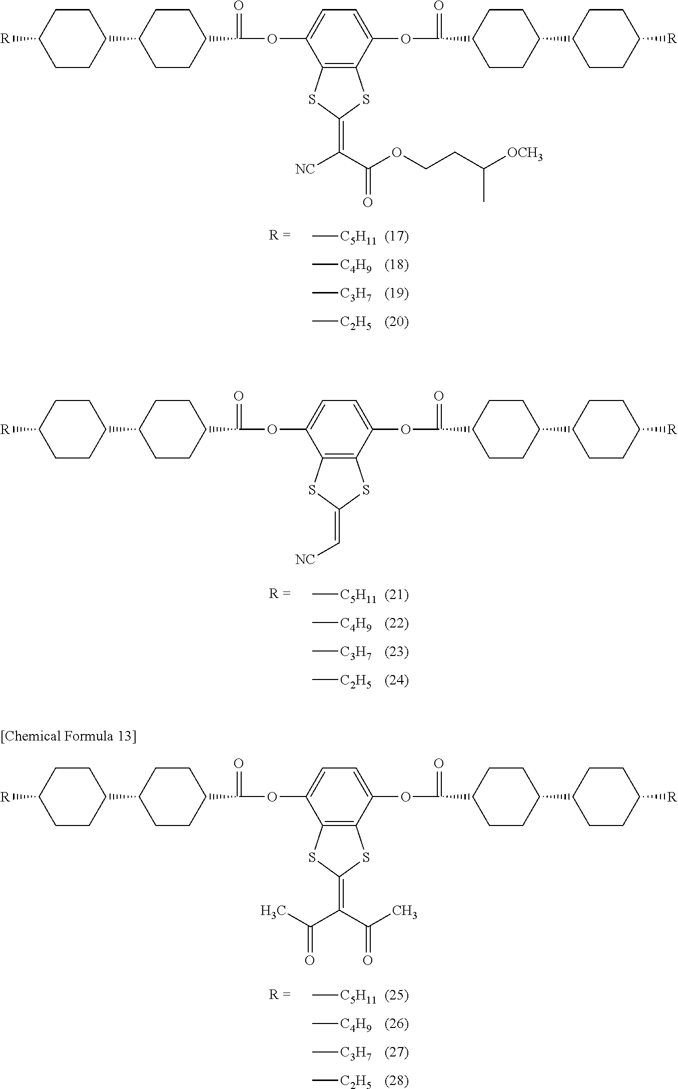

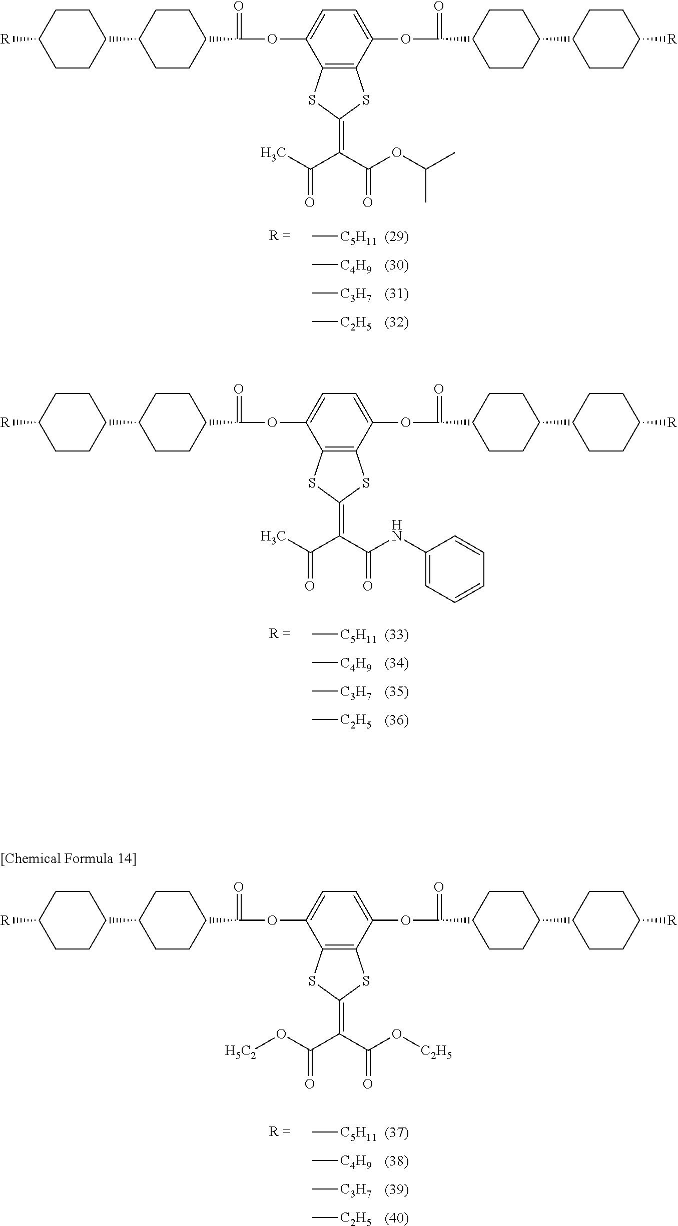

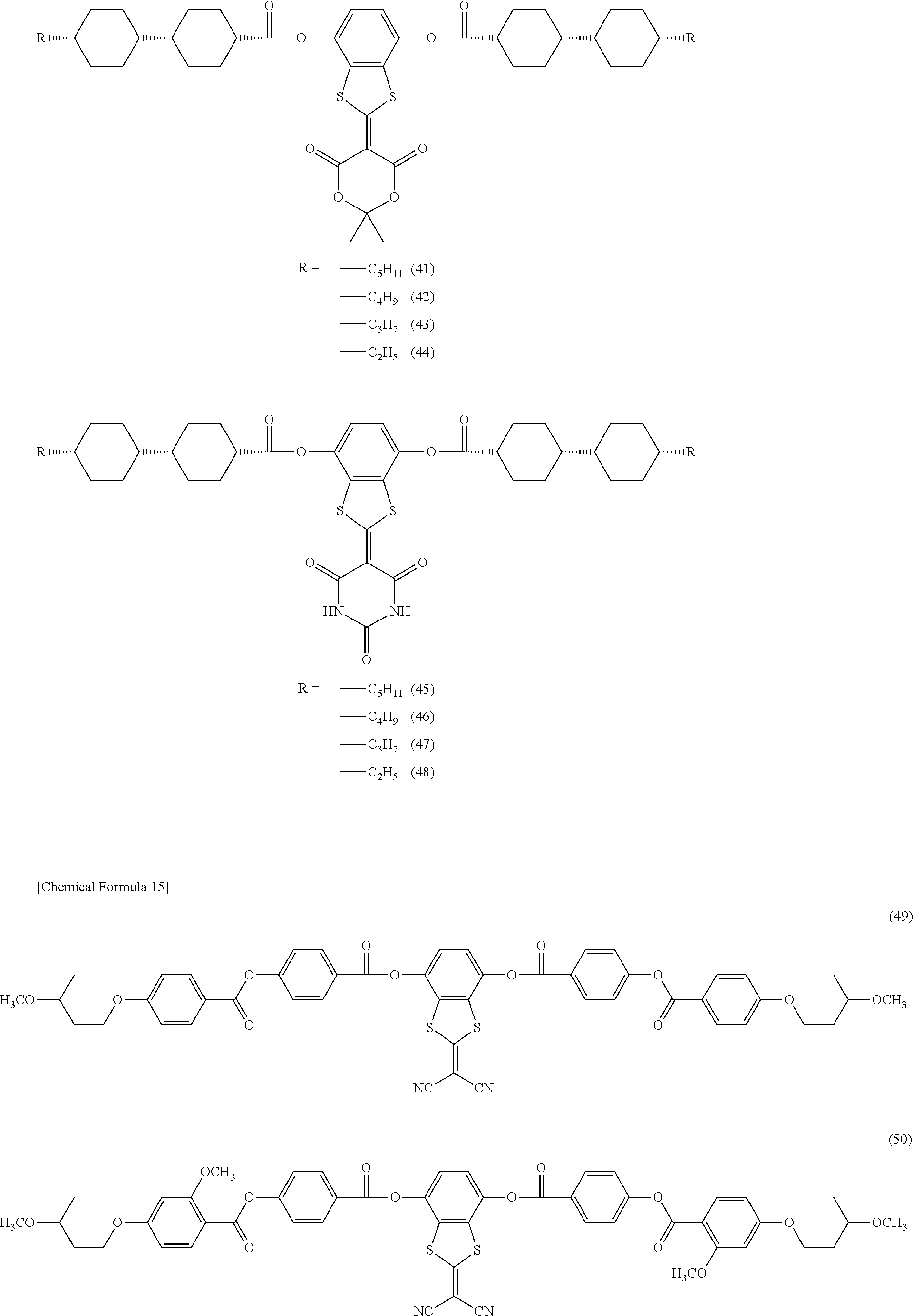

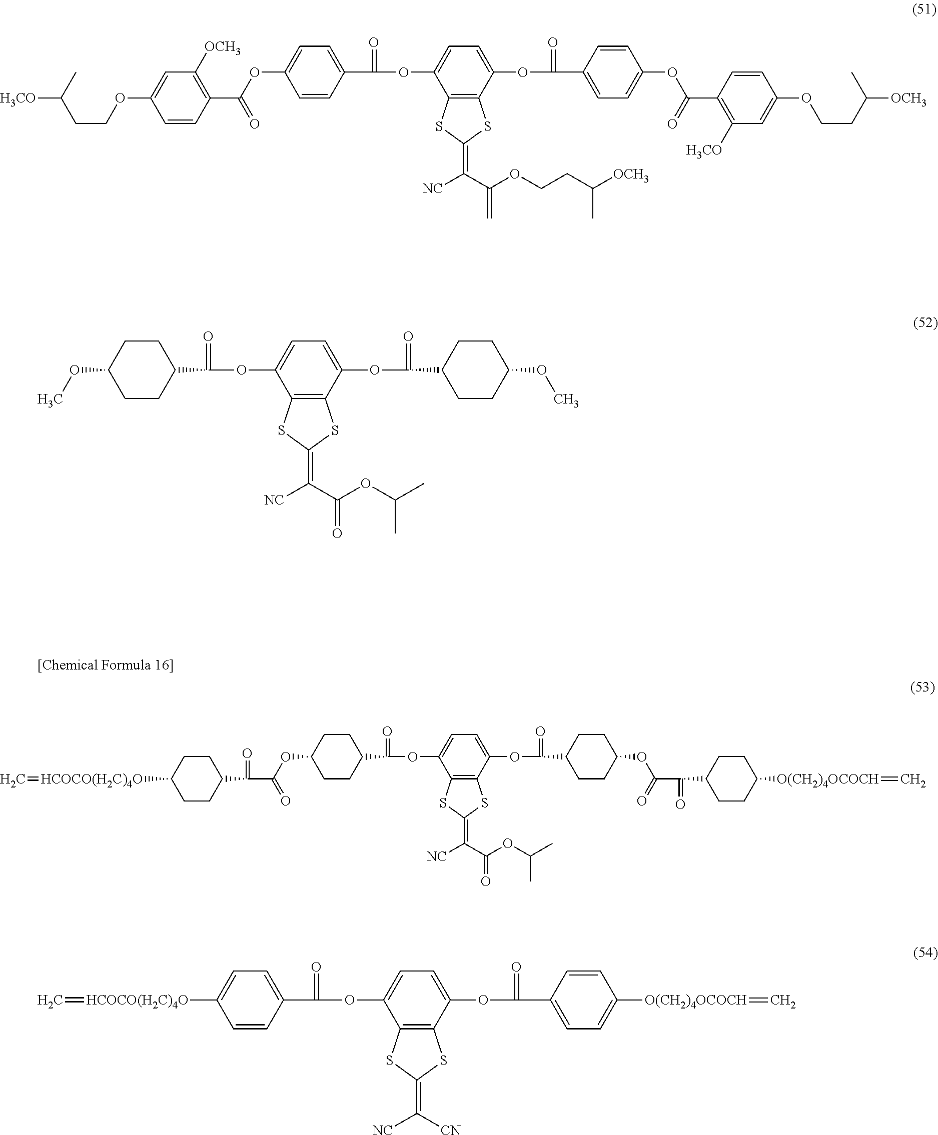

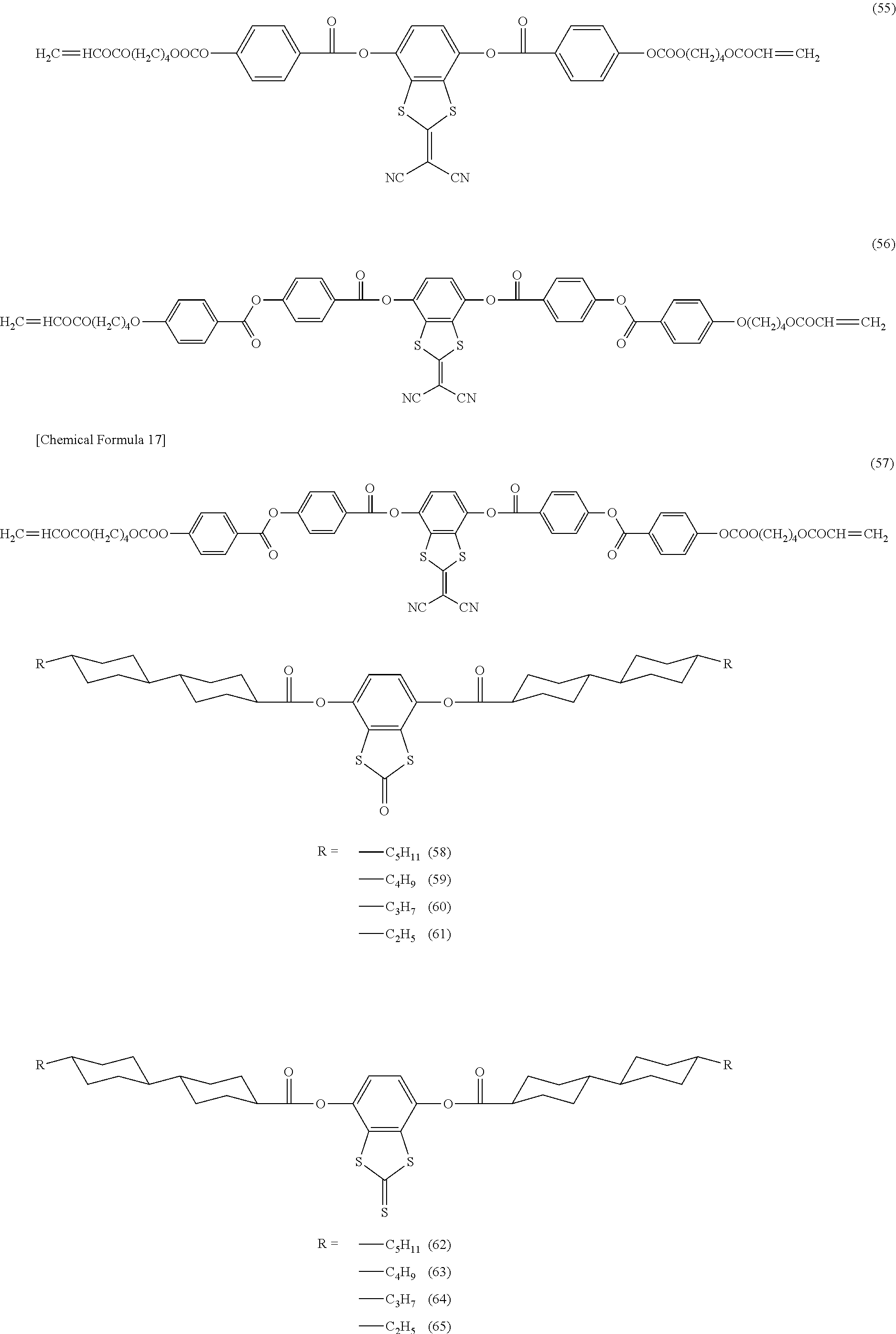

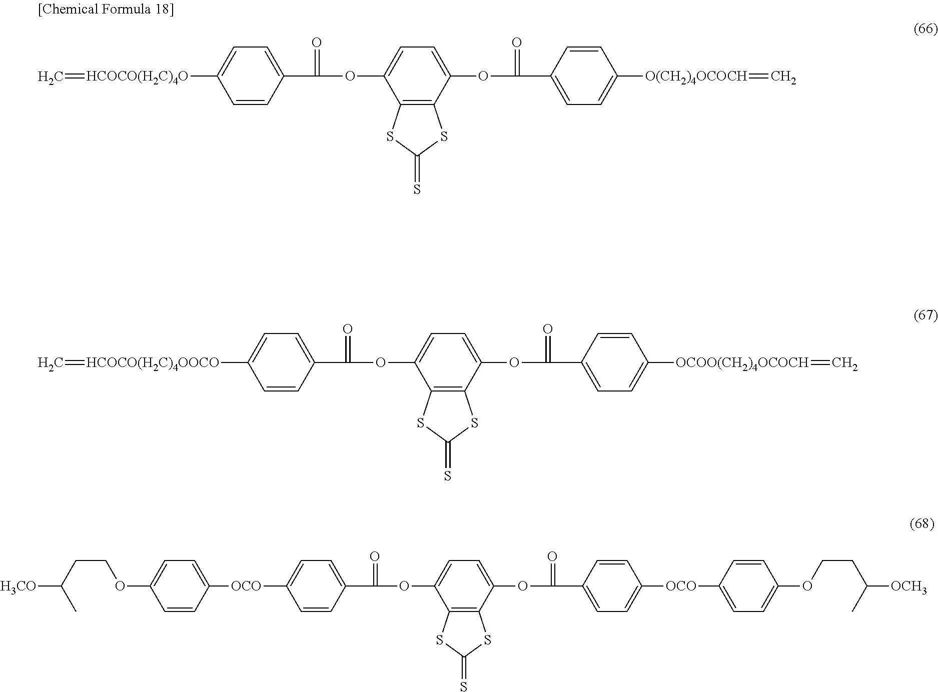

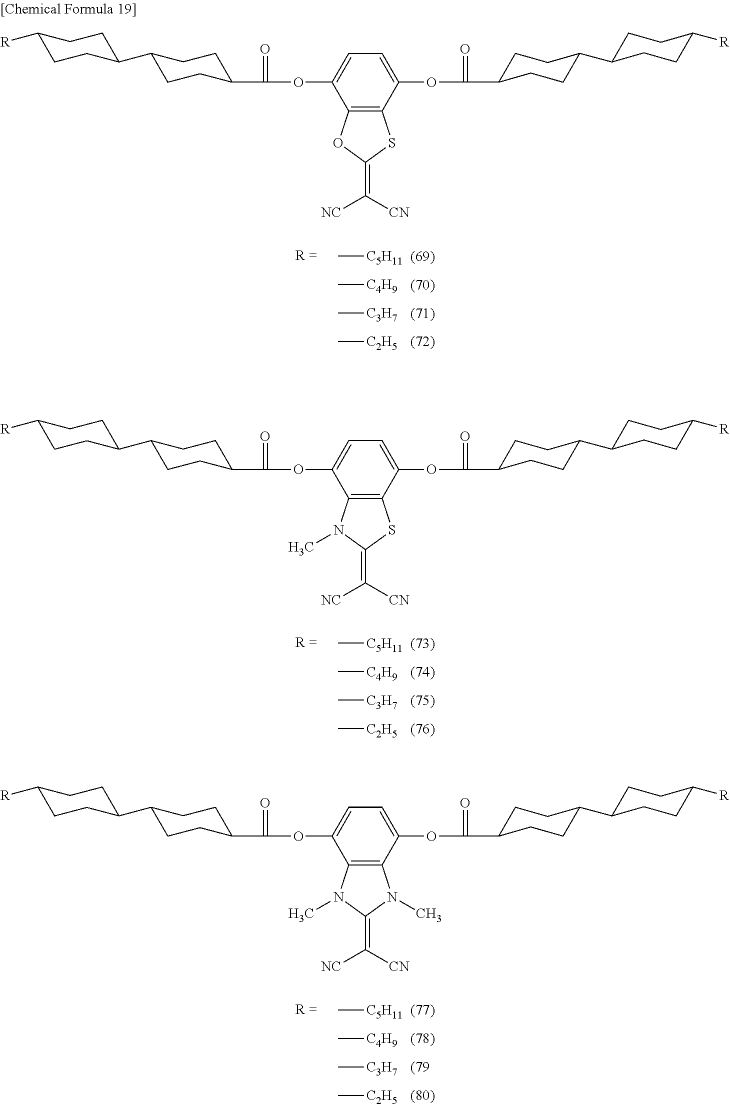

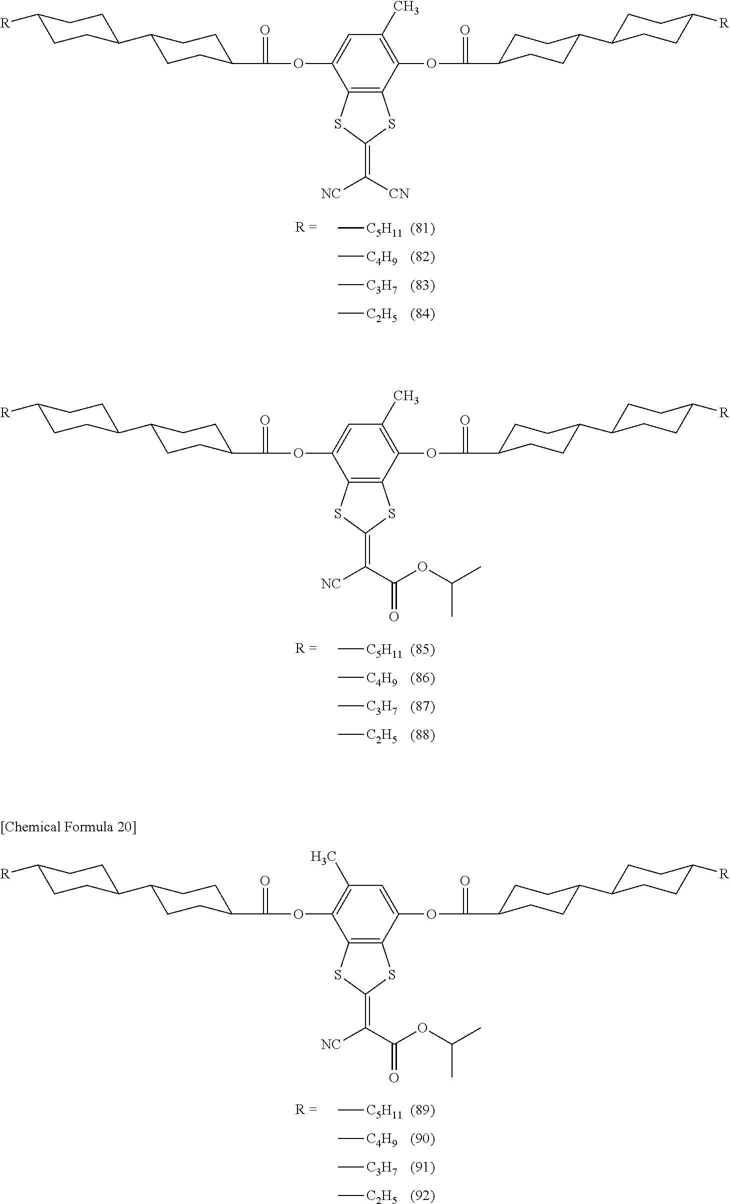

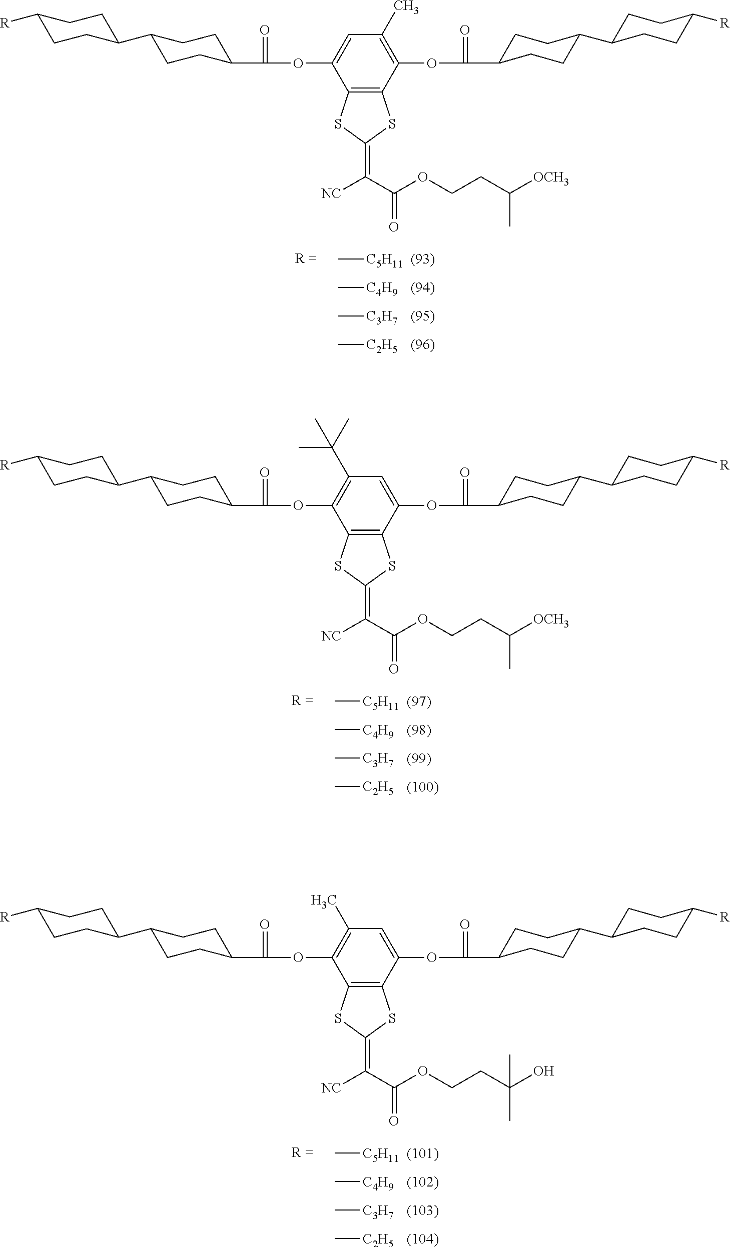

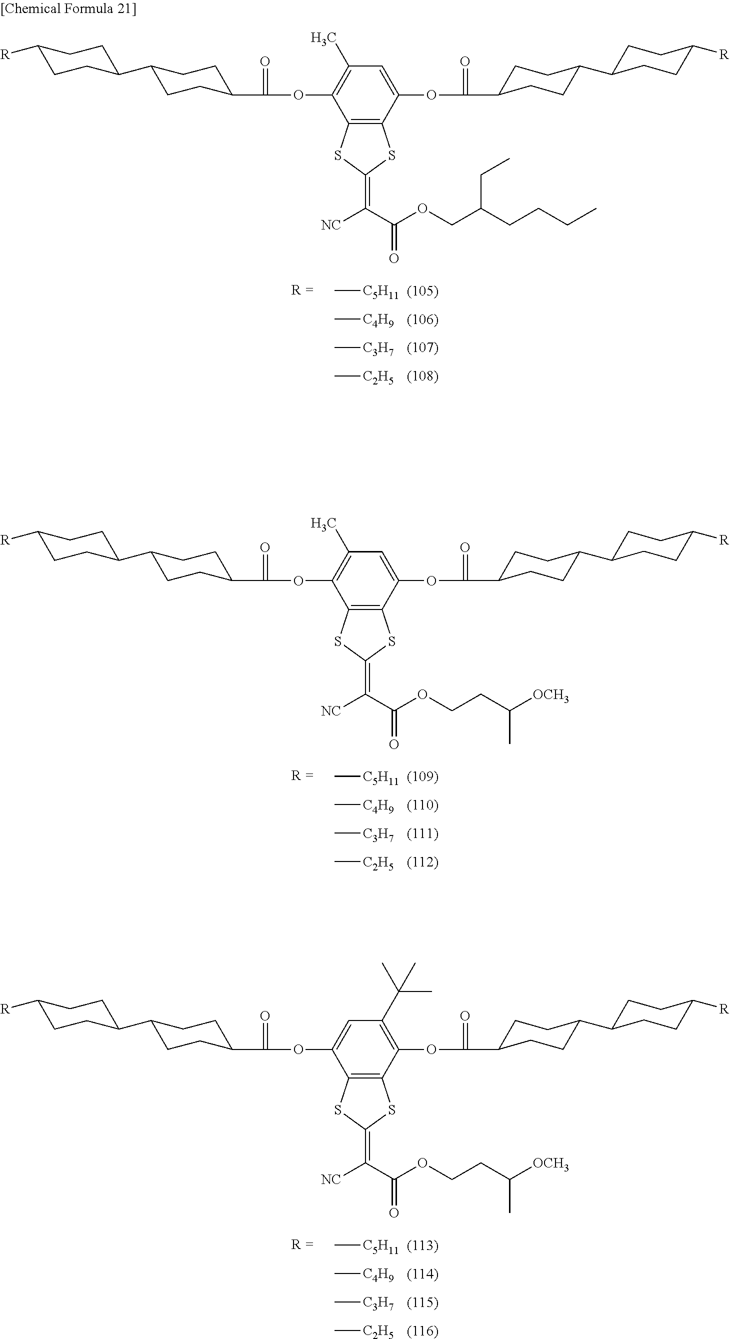

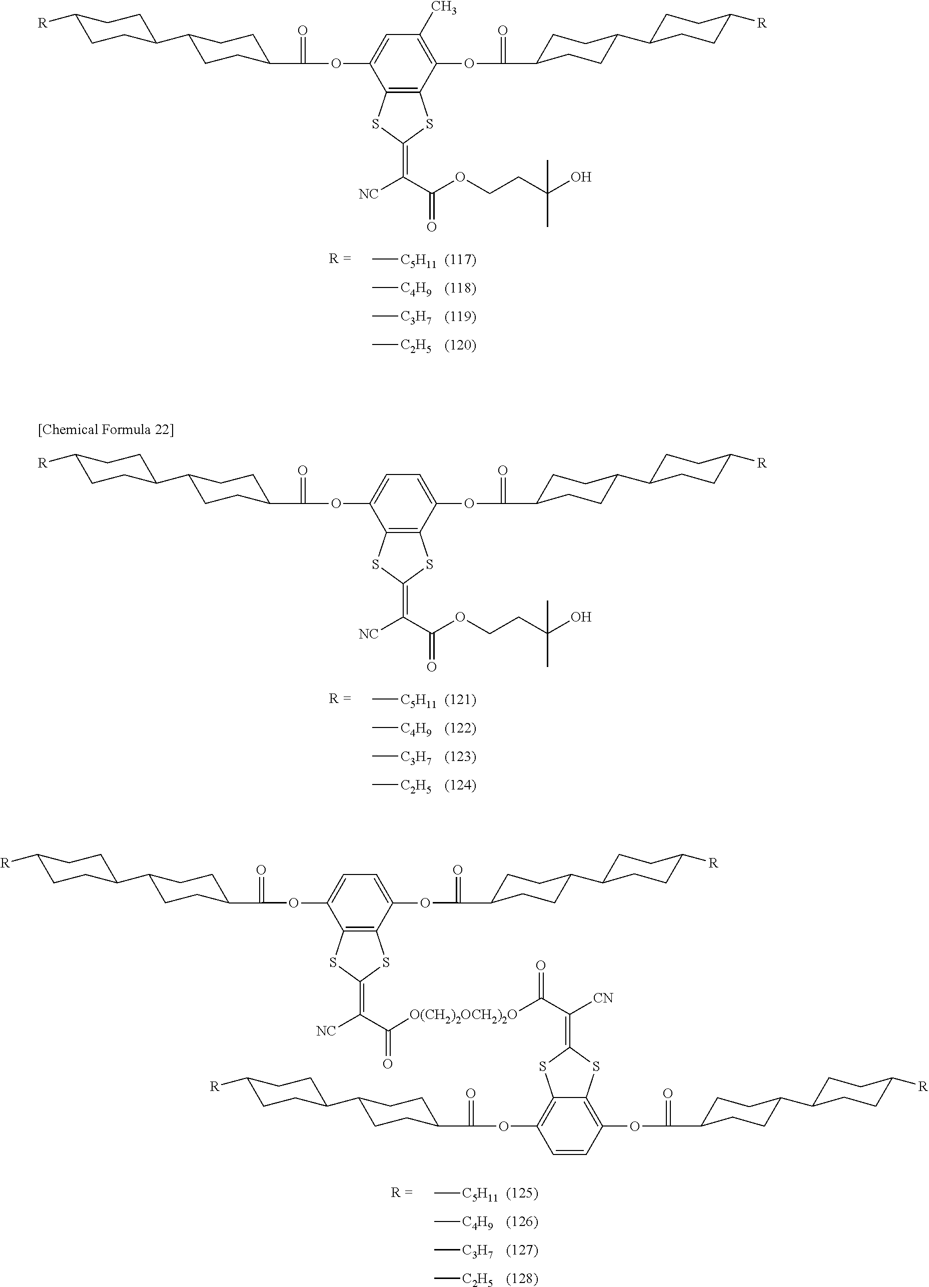

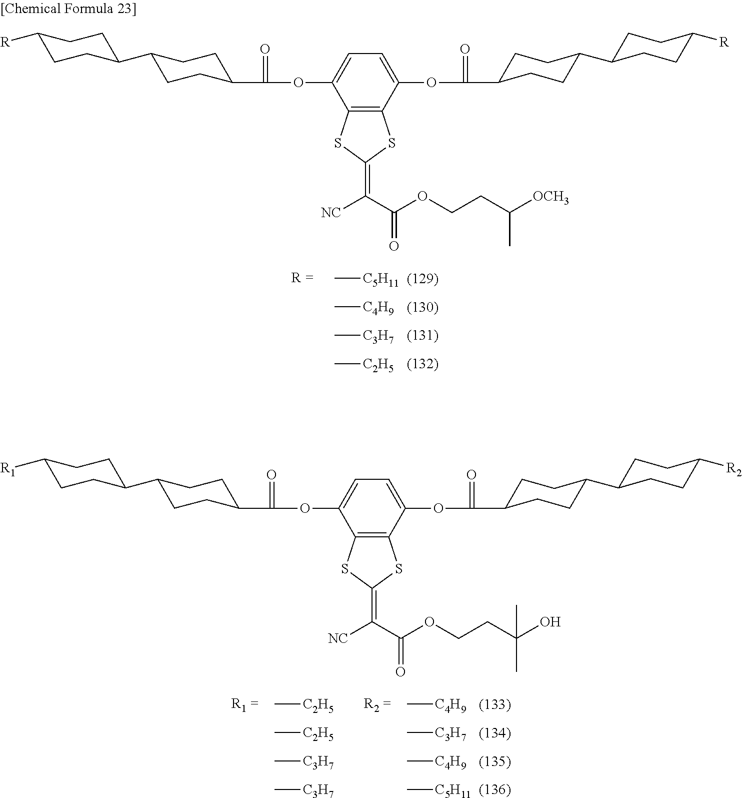

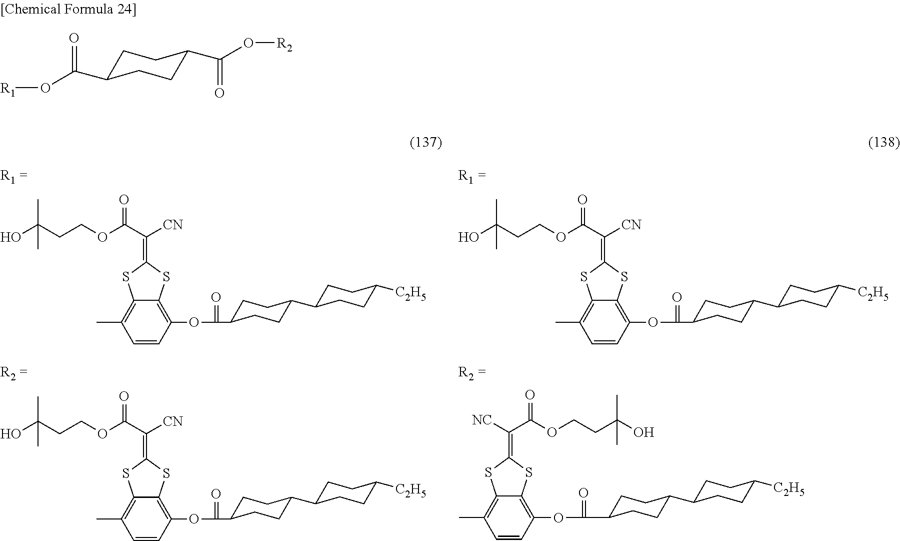

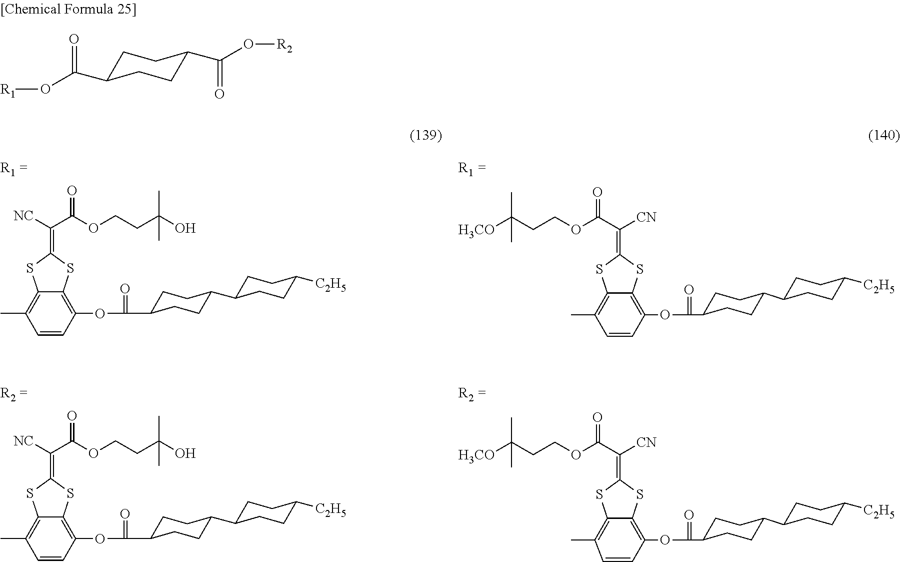

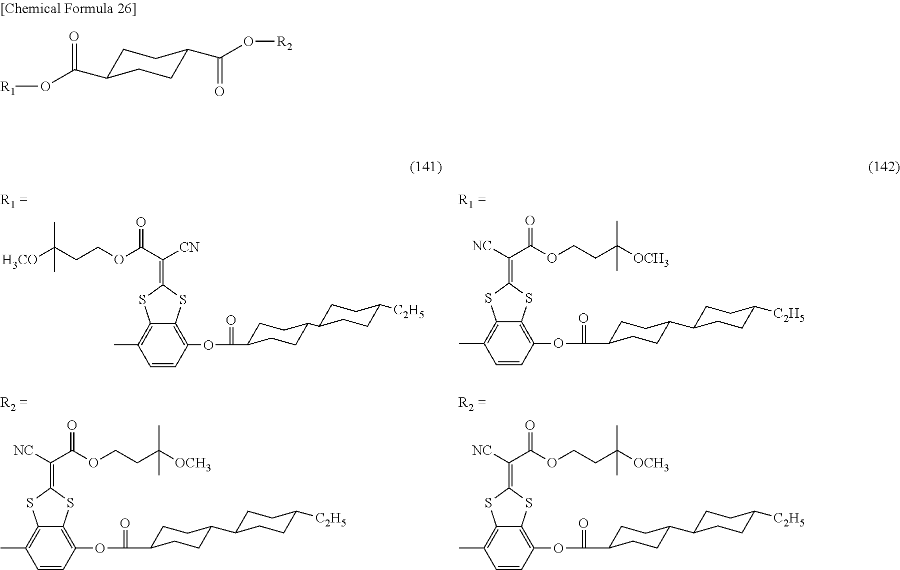

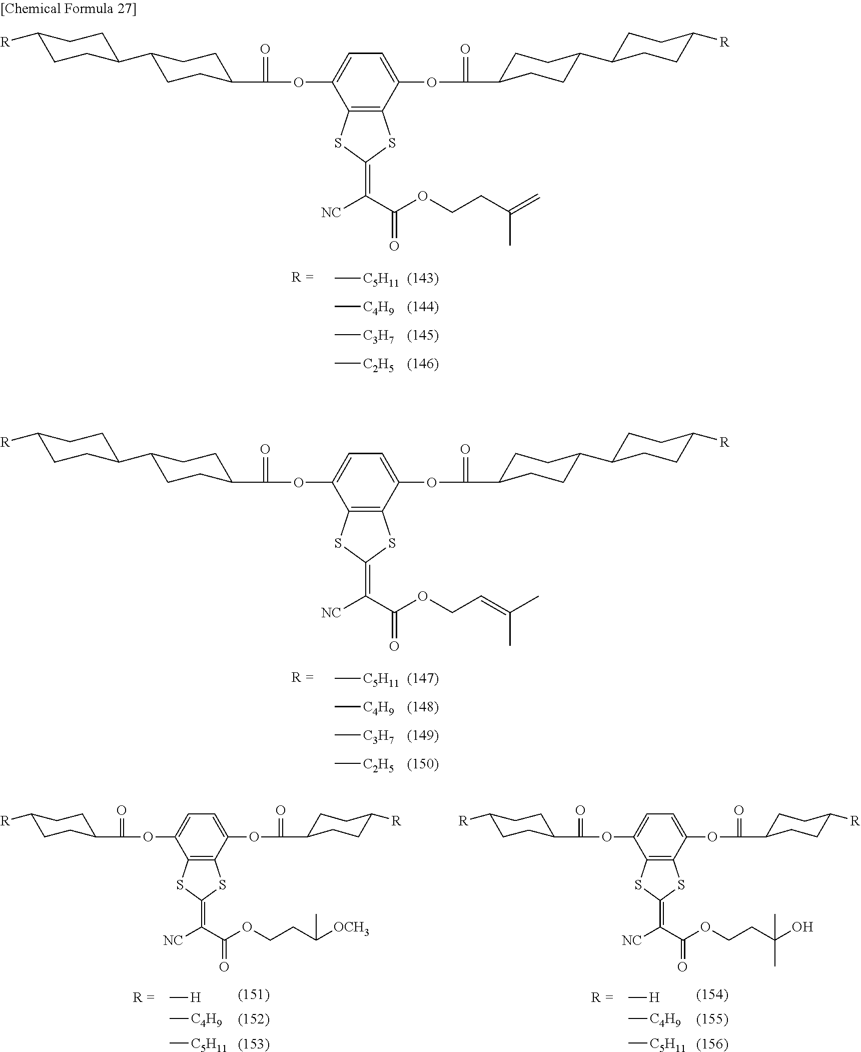

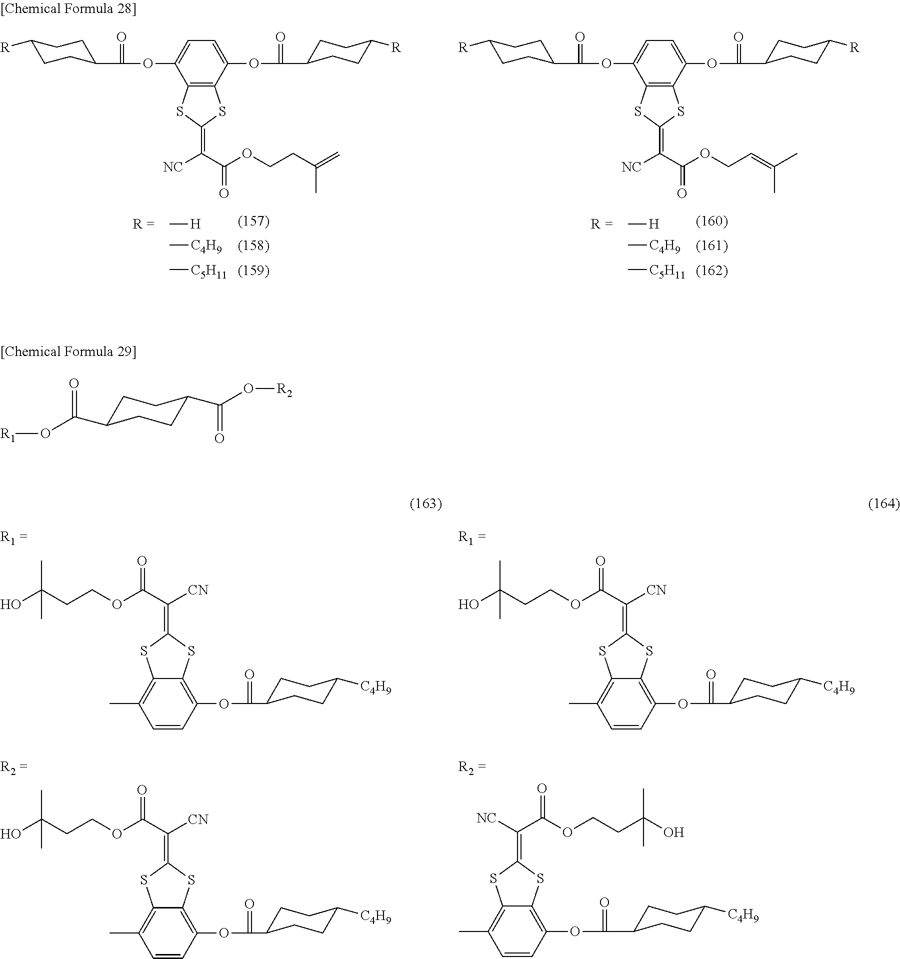

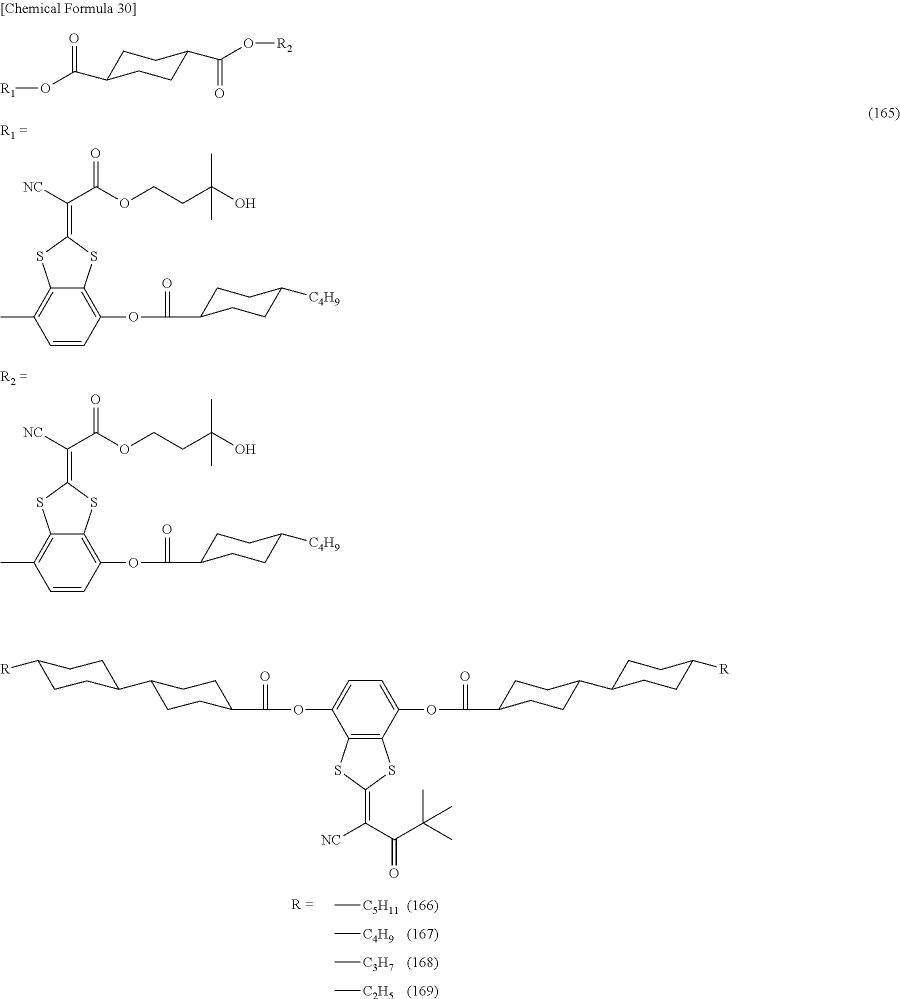

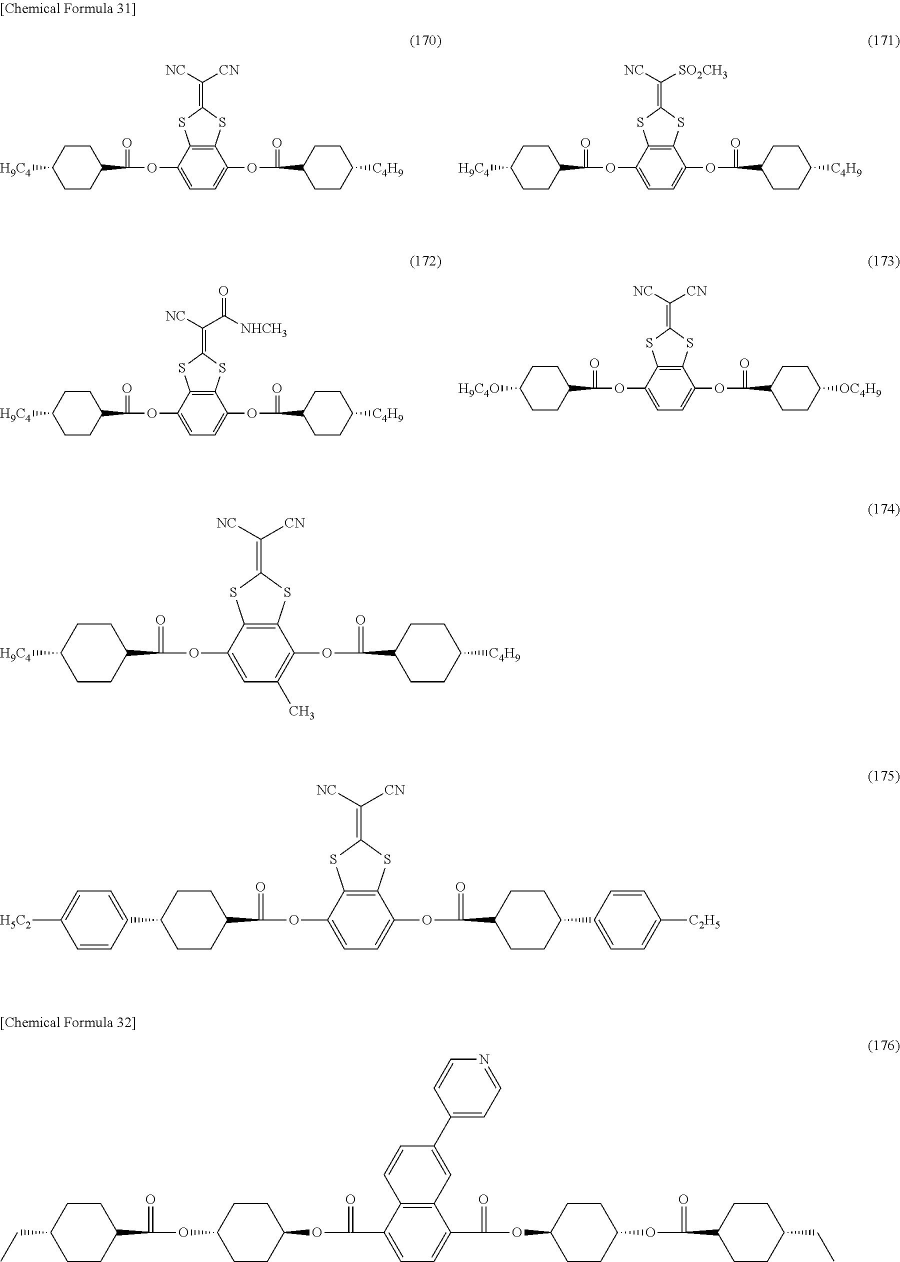

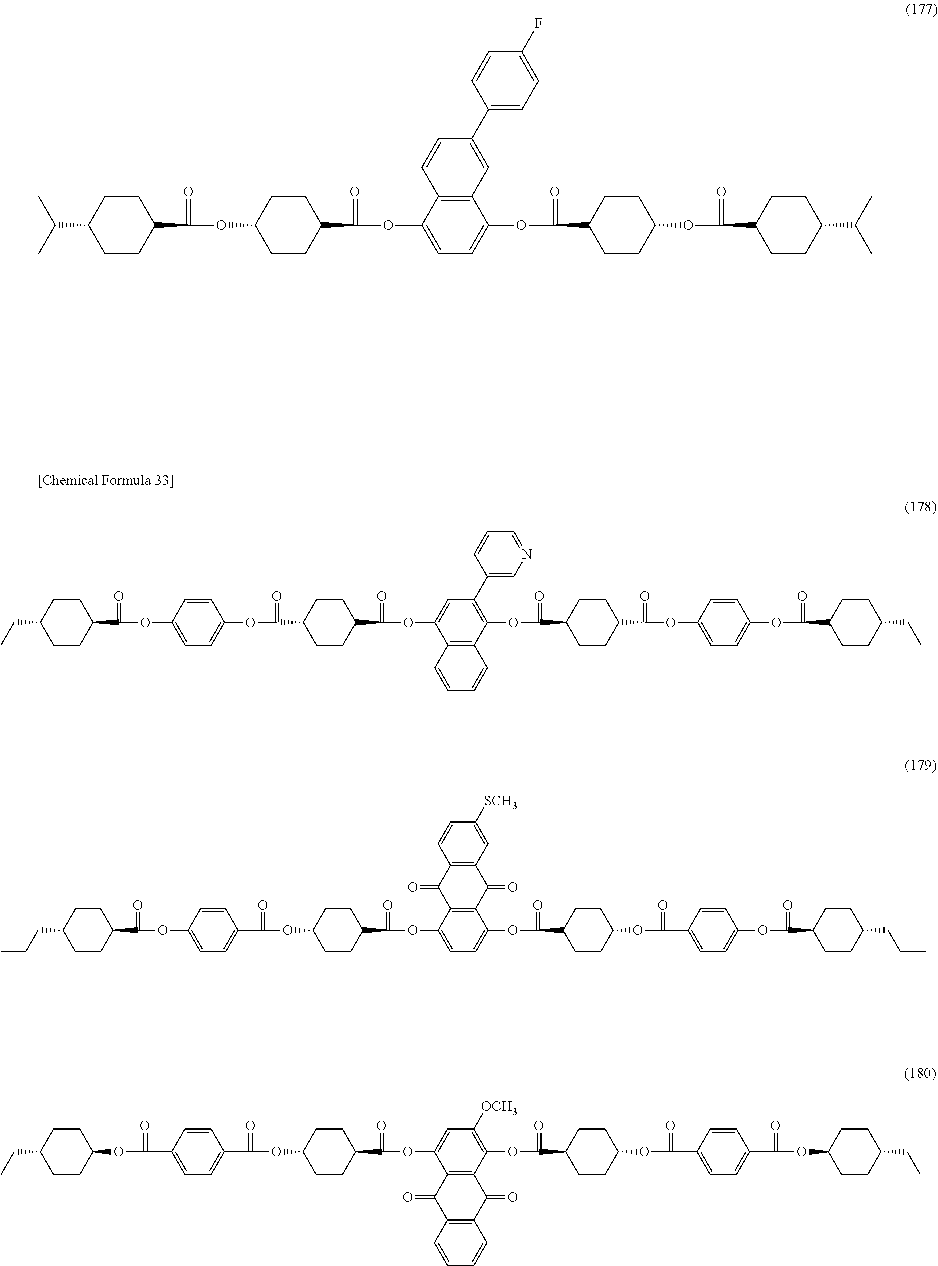

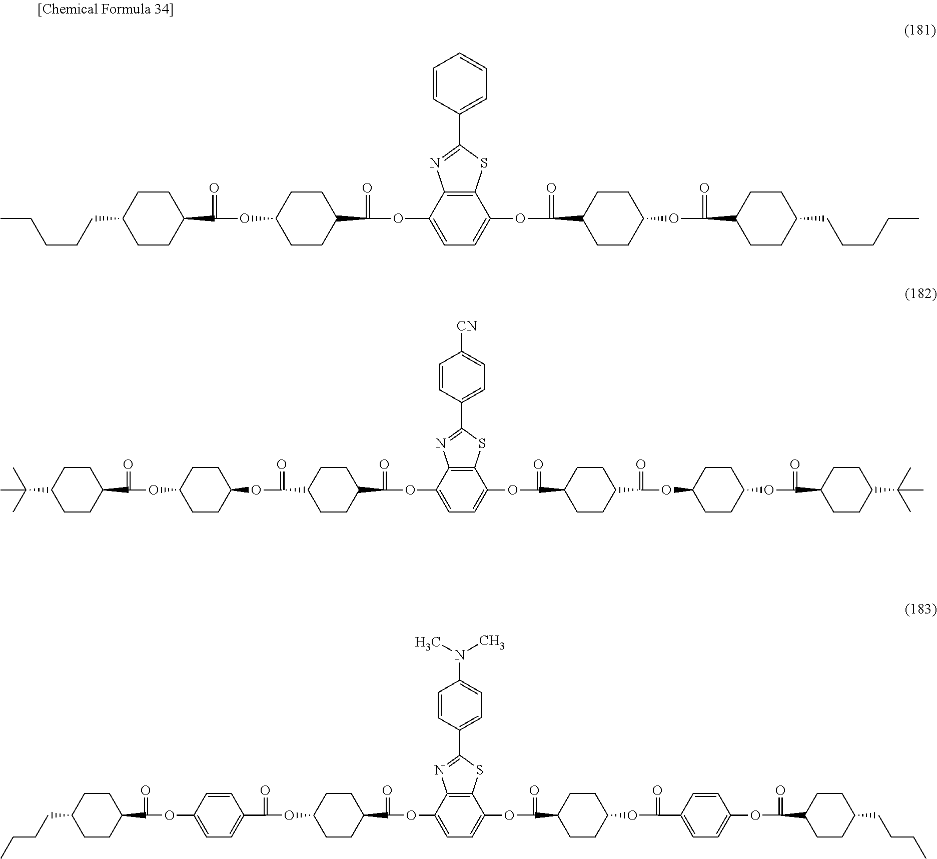

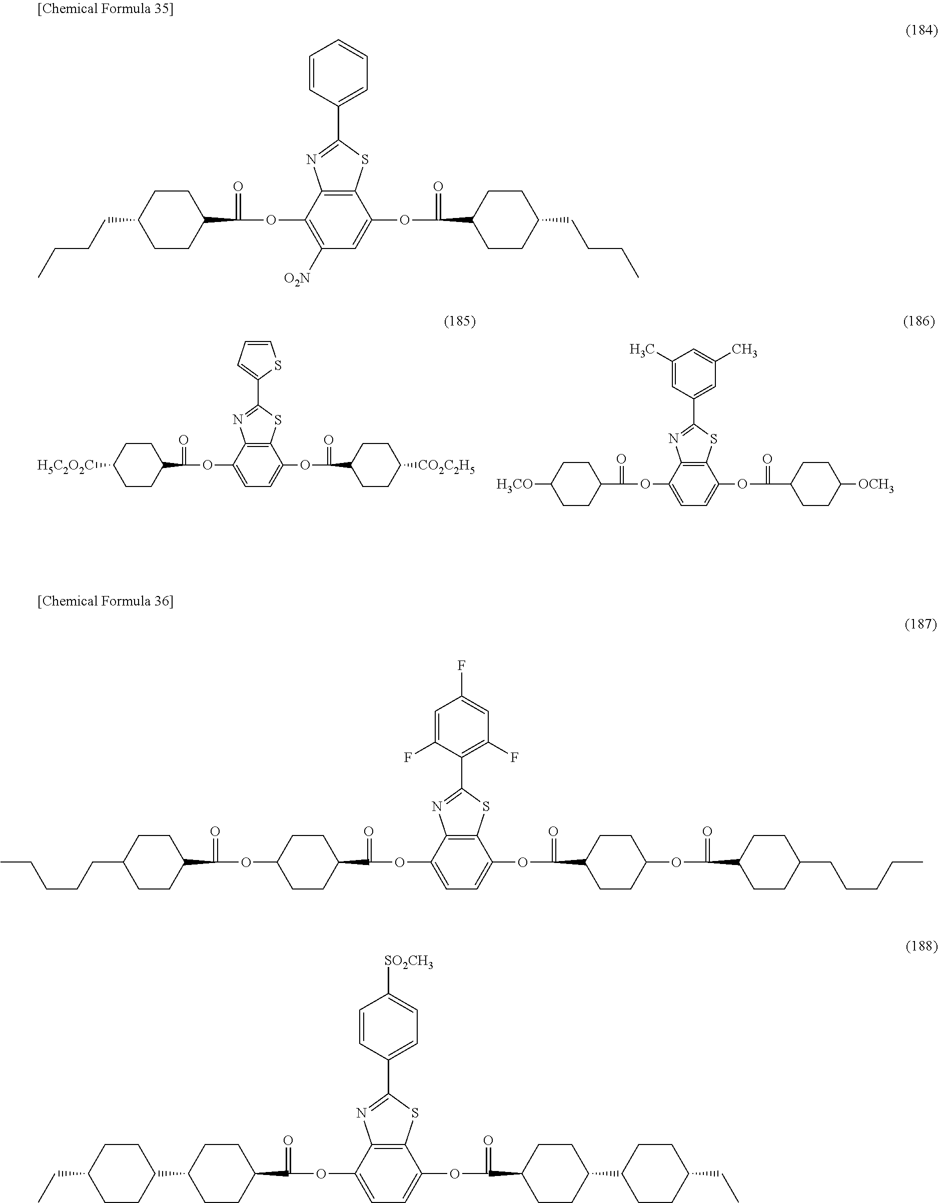

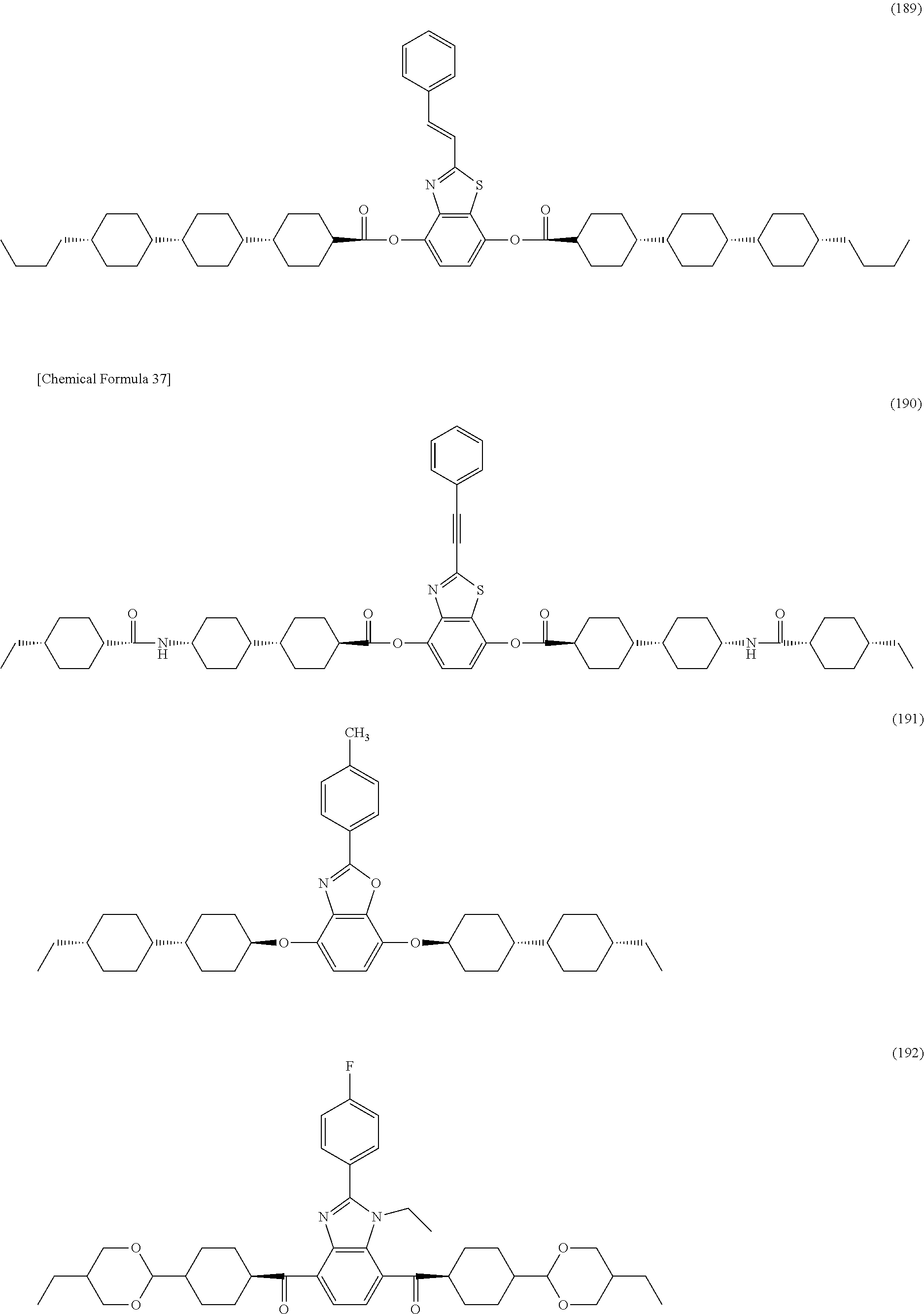

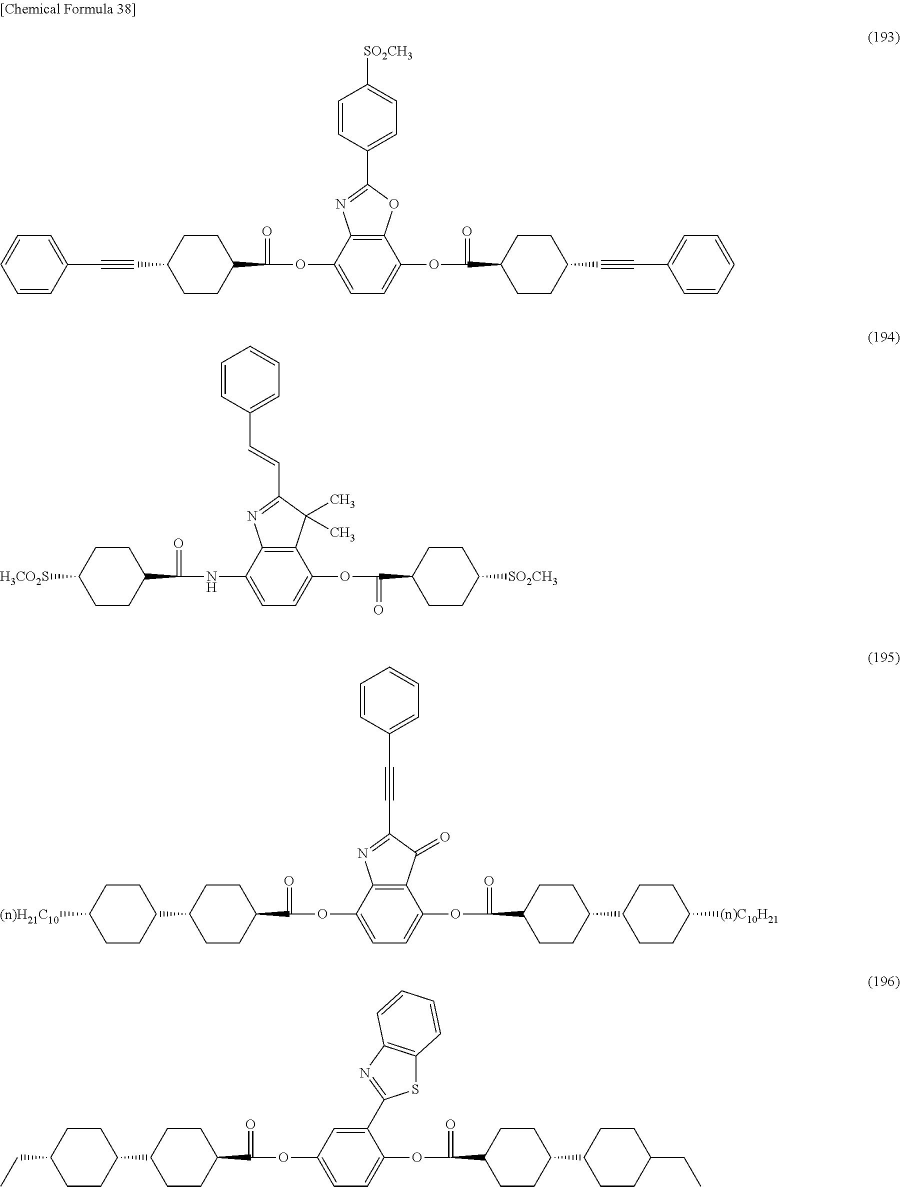

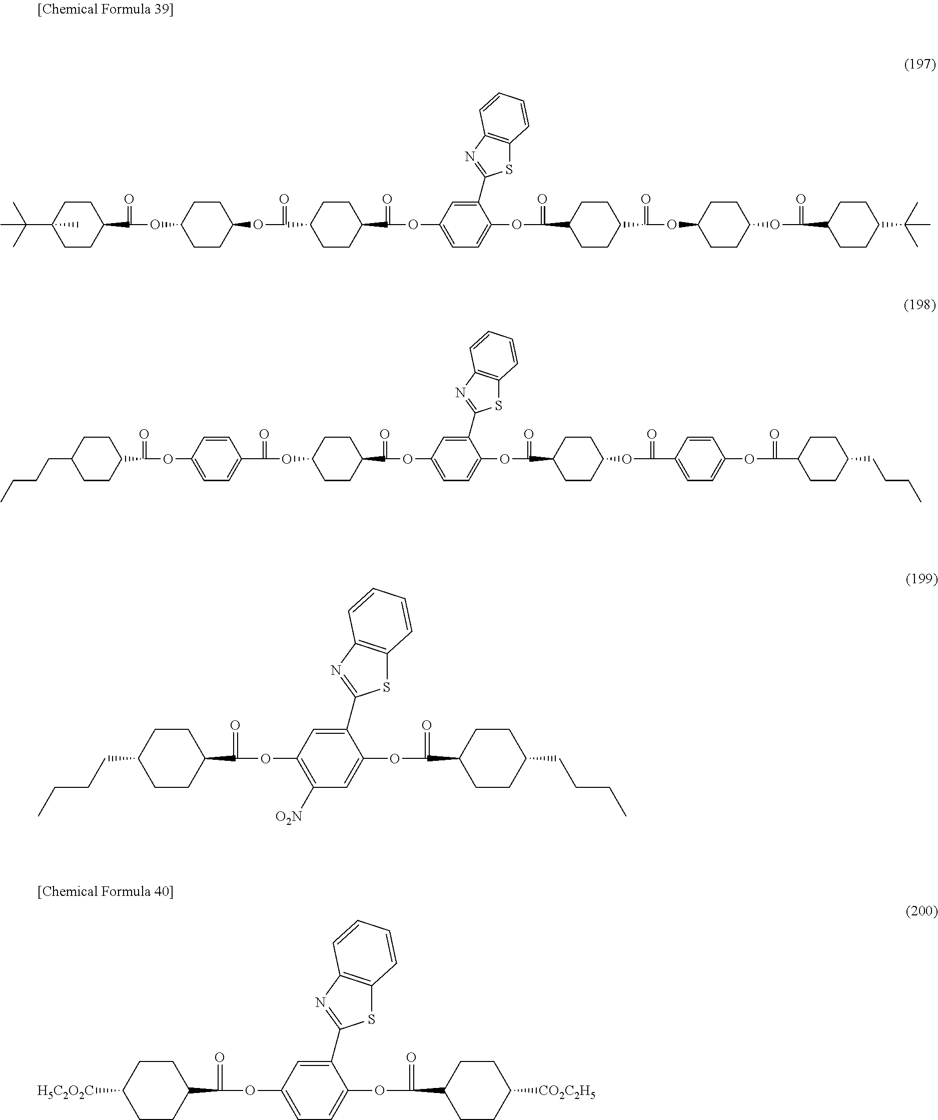

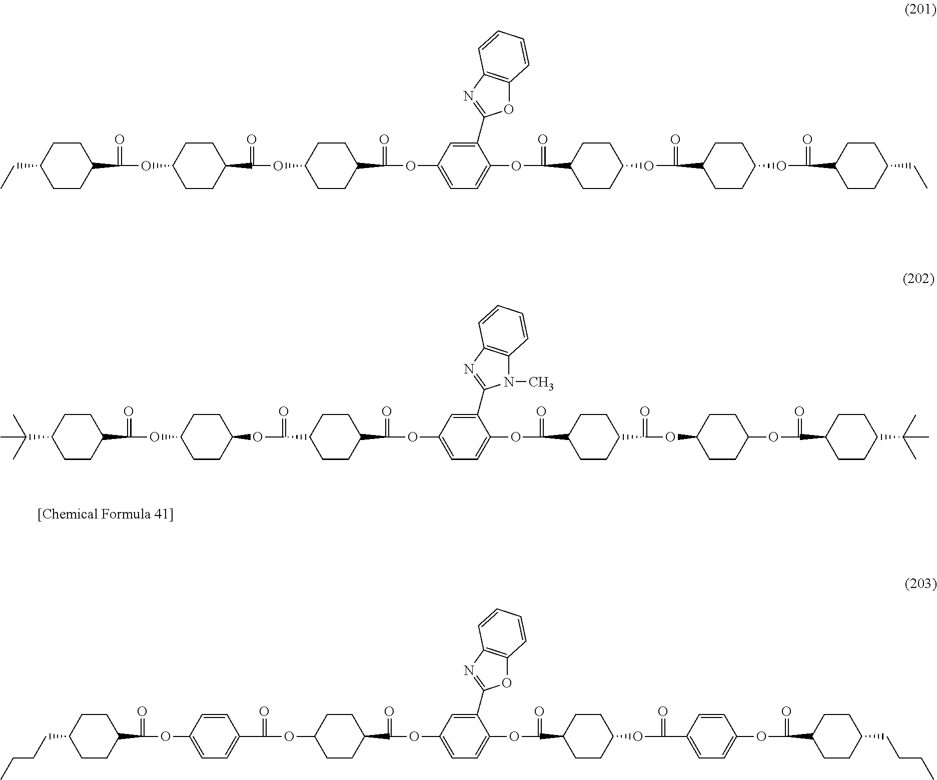

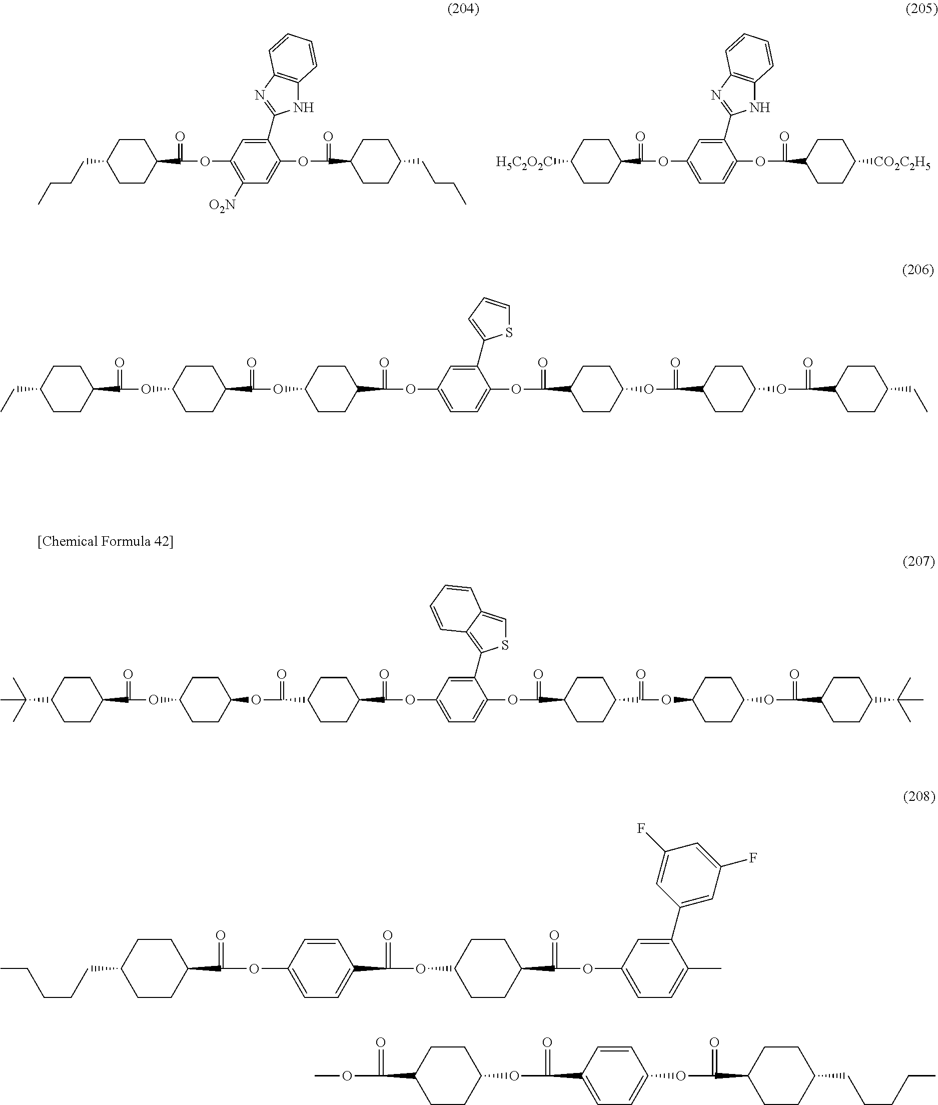

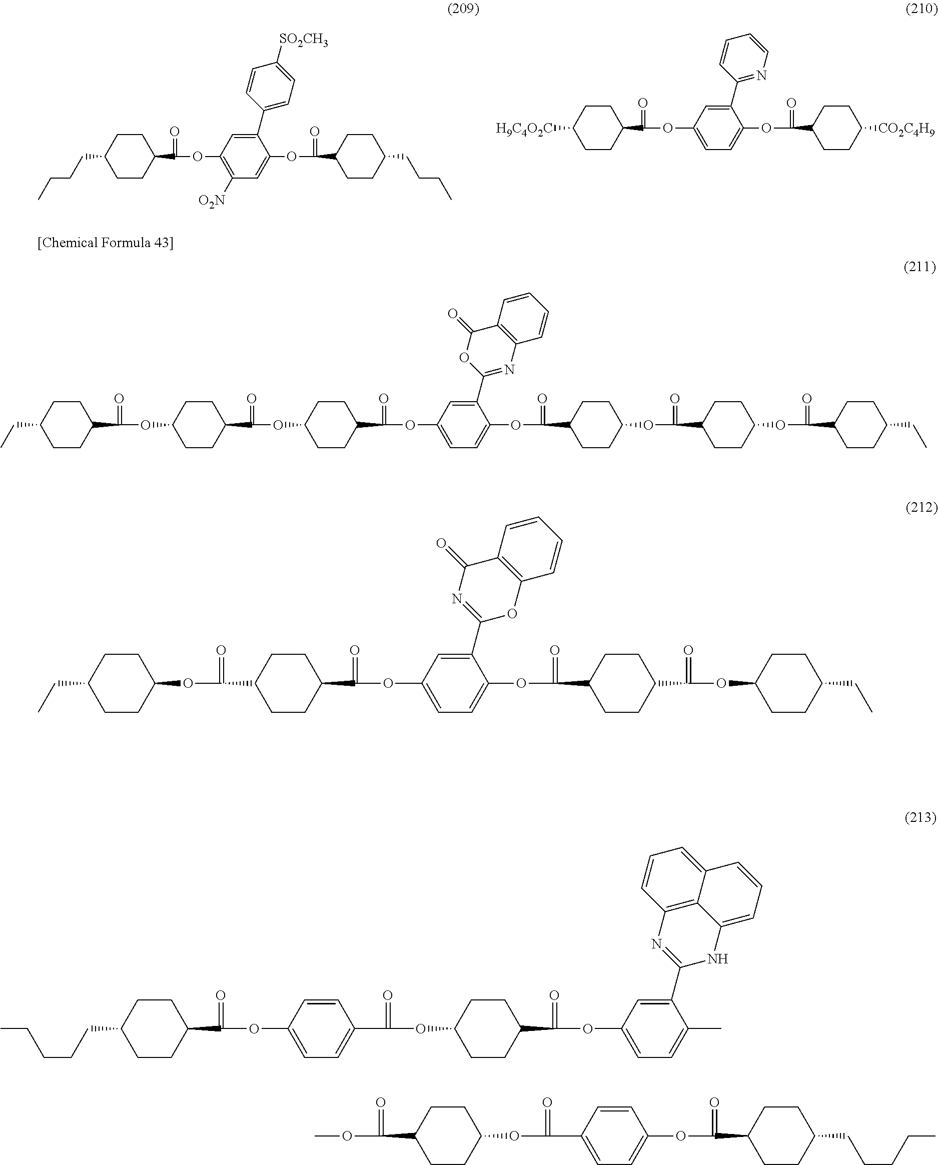

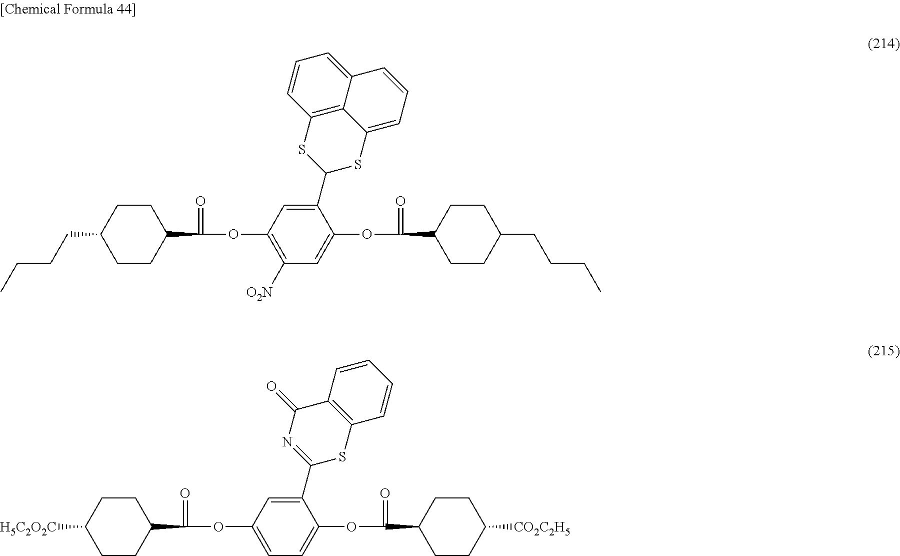

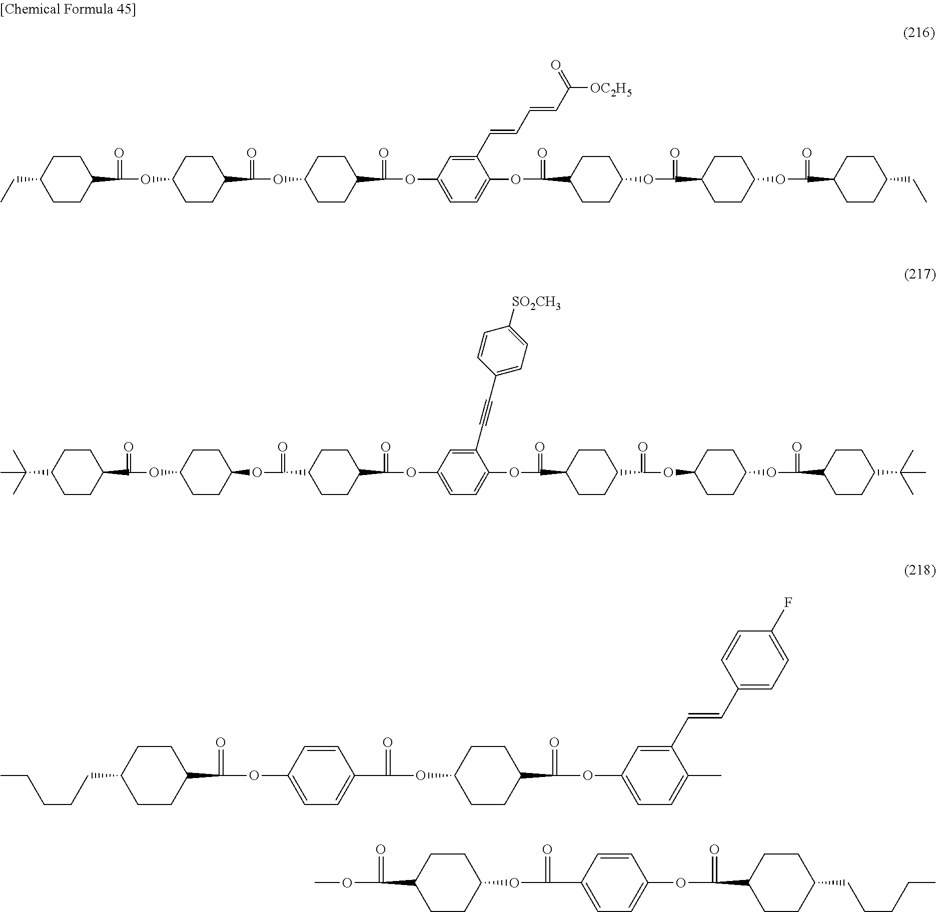

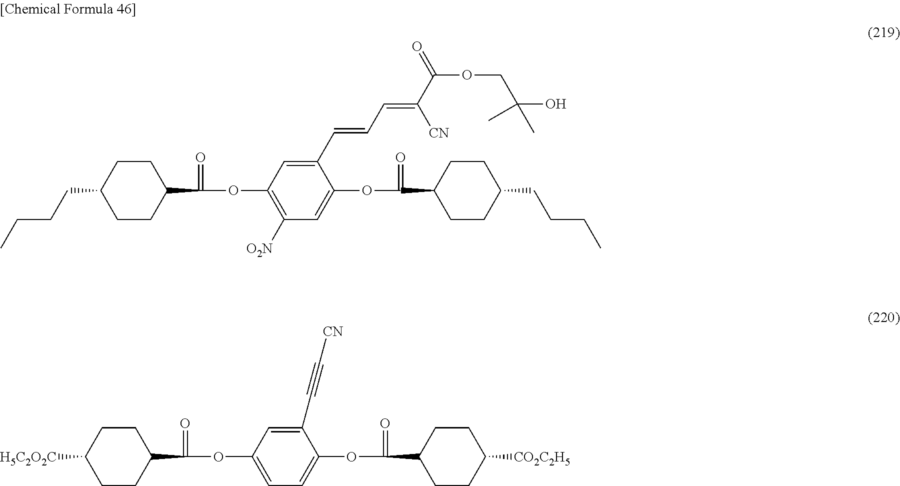

The compounds represented by the general formulae (1), (2) and (3) can be synthesized by known methods. Specifically, these compounds can be synthesized referring to Journal of Chemical Crystallography (1997), 27(9), 512 to 526, Japanese Patent Application Laid-Open Publication No. 2010-31223 and/or Japanese Patent Application Laid-Open Publication No. 2008-107767.

(Cellulose Ester)

A cellulose ester film of one embodiment of the present invention contains a cellulose ester as its main component.

The λ/4 phase difference film of the present invention preferably contains a cellulose ester. More preferably, the content of a cellulose ester in the λ/4 phase difference film is 60 to 100% by mass per 100% by mass of the total mass of the film. The total acyl group substitution degree of the cellulose ester is preferably 2.3 to 2.7.

Examples of the cellulose ester include esters of cellulose and an aliphatic or aromatic carboxylic acid of about 2 to 22 carbons. Esters of cellulose and a short chain fatty acid of 6 or less carbons are particularly preferable.

An acyl group to be bonded to the hydroxyl groups of cellulose may be a linear or branched group, or forms a ring(s). The hydroxyl groups may be substituted with another group(s). Between the cases of each having the same substitution degree, an acyl group(s) of 2 to 6 carbons are preferable because when the number of the carbons are large, double reflection decreases, and the total of the propionyl group substitution degree and the butyryl group substitution degree is preferably 0.5 or more. The number of the carbons of the cellulose ester is preferably 2 to 4, and more preferably 2 to 3.

Examples of the cellulose esters include esters of cellulose and fatty acids in which cellulose are bonded not only to an acetyl group but also to a propionate group, a butyrate group and/or a phthalyl group such as cellulose acetate propionate, cellulose acetate butyrate, cellulose acetate propionate butyrate and cellulose acetate phthalate. The butyryl group forming butyrate can be linear or branched.

In the present invention, the cellulose ester is particularly preferable cellulose acetate cellulose acetate butyrate or cellulose acetate propionate.

The cellulose ester of the present invention preferably satisfies the following expressions (1) and (2).

2.3≦A+B≦2.7 Expression (i)

0≦B≦2.0 Expression (ii)

[In the expressions (i) and (ii), A represents a degree of substitution with an acetyl group, and B represents a degree of substitution with an acyl group other than an acetyl group.]

To obtain a desired optical properties, resins having different substitution degrees may be mixed and used. The mixing ratio is preferably 1:99 to 99:1 (by mass).

Among the above-described examples, cellulose acetate propionate is preferably used as the cellulose ester. In the case of using cellulose acetate propionate, it is preferable to satisfy 0≦B≦2.0 and 0.5≦A≦2.17. The acyl group substitution degree is measured in accordance with ASTM-D817-96.

The number average molecular weight of the cellulose ester is preferably 60000 to 300000 because mechanical strength of the obtained film can be increased. More preferably, the cellulose ester having a number average molecular weight of 70000 to 200000 is used.

The weight average molecular weight (Mw) and the number average molecular weight (Mn) of the cellulose ester are measured by Gel Permeation Chromatography (GPC). Conditions for the measurement are as described below. This method for the measurement may be applied to the measurements of other polymers used in the present invention.

Solvent: Methylene chloride

Column: Shodex K806, K805 and K803G (manufactured by SHOWA DENKO K.K.) that are connected to one another

Column temperature: 25° C.

Sample concentration: 0.1% by mass

Detector: RI Model 504 (manufactured by GL Sciences Inc.)

Pump: L6000 (manufactured by Hitachi, Ltd.)

Flow amount: 1.0 ml/min

Standard curve: a standard curve drawn using 13 samples of the standard polystyrene STK standard with Mw of 500 to 1000000, the intervals between any two of which 13 samples are almost constant

The content of residual sulfuric acid in the cellulose ester is preferably 0.1 to 45 ppm by mass on a sulfur conversion basis. The residual sulfuric acid is thought to be contained in a form of salt. When the content of the residual sulfuric acid is 45 ppm by mass or less, fracture in the heat stretching and slitting after the heat stretching is difficult to occur. The content of the residual sulfuric acid is more preferably 1 to 30 ppm by mass. The content of the residual sulfuric acid can be measured by a method in accordance with ASTM D817-96.

The content of free acid in the cellulose ester is preferably 1 to 500 ppm by mass, because fracture is difficult to occur like the above. More preferably, the content of free acid in the cellulose ester is 1 to 100 ppm by mass because fracture is more difficult to occur. Particularly, it is preferable the content is in the range of 1 to 70 ppm by mass. The content of free acid in the cellulose ester can be measured by a method in accordance with ASTM D817-96.

It is preferable to wash the synthesized cellulose ester more sufficiently compared to washing in the solution casting because the content of residual alkali earth metal, the content of residual sulfuric acid and the content of residual acid can be adjusted to be in the above ranges.

Preferably, the cellulose ester contains less bright spots. The bright spots can be observed as follows. Two sheets of polarizing plates are arranged in the crossed Nichol state, an optical films is positioned between the plates, light irradiation is conducted from the side of one polarizing plate and observation is performed from the side of the other plate, and the bright spots may be sometimes observed from the other side. The number of the bright spots having diameters of 0.01 mm or more is preferably 200/cm² or less, more preferably 100/cm² or less, further preferably 50/cm², further more preferably 30/cm², particularly preferably 10/cm², and most preferably zero/cm².

As to bright spots having diameters of 0.005 to 0.01 mm, the number of such bright spots is preferably 200/cm² or less, more preferably 100/cm² or less, further preferably 50/cm², further more preferably 30/cm², particularly preferably 10/cm², and most preferably zero/cm².

A cellulose as the material of the cellulose ester is not particularly limited, and examples include cotton linter, wood pulp and kenaf. The cellulose ester obtained from each of them may be mixed in any proportions and used.

The cellulose ester can be manufactured by a known method. For example, the cellulose ester can be synthesized referring to a method described in Japanese Patent Application Laid-open Publication No. Hei10-45804.

The cellulose ester is affected by a trace metal component(s) contained therein. The trace metal component(s) may be derived from water used in the manufacturing process. It is preferable that the content of a component that may be insoluble cores is smaller. Especially, the contents of metals such as iron, calcium and magnesium are preferably small because they may form an insoluble matter(s) by forming a salt with a polymer decomposition product that may contain an organic acid group(s). A calcium (Ca) component is easy to form a complex with an acid component such as carboxylic acid and sulfonic acid and/or with various ligands, which may cause scum (insoluble dregs and turbidity) derived from various insoluble calcium components. Thus, the content of calcium components is preferable small.

As to an iron (Fe) component(s), the content thereof in the cellulose ester is preferably 1 ppm by mass or less. As to a calcium component(s), the content thereof in the cellulose ester is preferably 60 ppm by mass or less, and more preferably 0 to 30 ppm by mass. As to a magnesium component(s), the content thereof in the cellulose ester is preferably 0 to 70 ppm by mass, and more preferably 0 to 20 ppm by mass because the higher content causes insoluble matters.

The contents of metals such as iron (Fe), calcium (Ca) and (Mg) can be measured by ICP-AES (Inductively Coupled Plasma-Atomic Emission Spectrometry) following a pre-treatment of an absolutely dried cellulose ester by alkali fusion using a microwave wet digestion device (decomposition with sulfuric acid and nitric acid).

(Evaluation of Organic EL Display Device)

The organic EL display device of the present invention prevents reflection of external light and decreases a hue change. Its evaluations can be conducted as described below.

(Reflection of External Light)

Reflection of external light can be evaluated by the following method.

The organic EL display device is put in a room at 23° C. and 55% RH for 48 hours, and then the organic EL display device is put in an environment at an illuminance of 100 lx in a non-light-emitting state without application of voltage. The redness of reflected light observed from the front is visually estimated, and difference between the estimations are evaluated.

(Hue Change)

The organic EL display device is put in an environment at 5° C. and 55% PH in a non-light-emitting state for 48 hours. Then the organic EL display device is irradiated at 23° C. and 55% PH from the direction perpendicular to the display screen of the organic EL display device so that the illuminance at a height of 5 cm from the outermost surface of the organic EL display device is 1000 Lx, and a hue of the display screen is visually estimated from the direction at 40° to the normal line of the display screen of the organic EL display device. Thereafter, the organic EL display device is put in an environment at 40° C. and 55% PH for 48 hours, and then a hue of the display screen is visually estimated at 23° C. and 55% PH by the way same as the above. The change between the hues are evaluated.

### Example

The present invention will now be specifically described with reference to Examples, but the present invention is not limited thereto. In Examples, “part(s)” and “%” means “part(s) by mass” and “% by mass”, respectively, unless described otherwise.

### Synthesis Example 1

### Synthesis of Exemplary Compound (16)

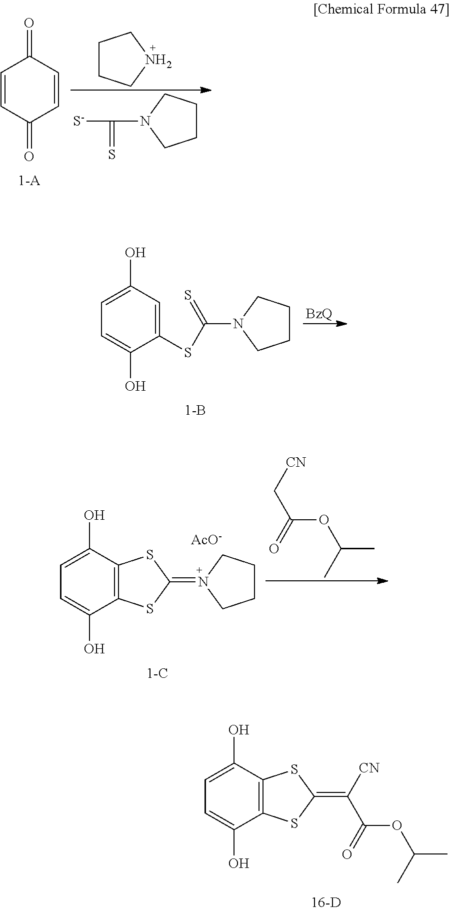

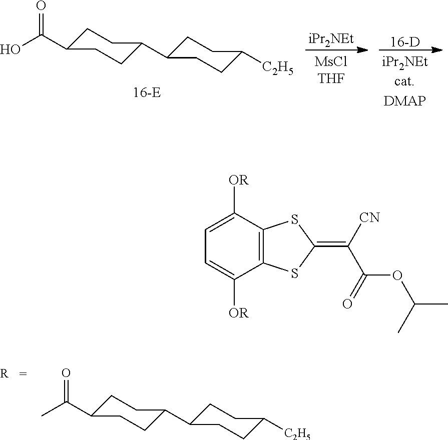

### Exemplary Compound (16)

The compound 1-A to the compound 1-C were synthesized according to the description of Journal of Chemical Crystallography (1977), 27(9), 515 to 526.

Then, 15 ml of cyano acetate isopropyl ester was added to 250 ml of an N-methylpyrrolidone solution dissolving 31 g of the compound (1-C), followed by stirring at 120° C. for 5 hours. The resulting solution was cooled, extraction was then performed on the cooled solution using ethyl acetate, and thereafter the organic layer was washed. Subsequently, the solvent was distilled off under reduced pressure. An obtained solid matter was re-crystallized using methylethyl ketone and hexane, and an intermediate (16-D) was obtained (at a yield of 90%).

Then 5.2 g of (16-E) was dissolved in 50 ml of tetrahydrofuran, and 1.7 ml of methane sulfonyl chloride (MsCl) was added thereto cooling with ice water. Further, 4 ml of N,N-diisopropylethylamine (iPr₂NEt) was dropped into the resulting solution. After an hour passed, the resulting solution was cooled in an ice water bath, and a tetrahydrofuran (THF) solution of the intermediate (16-D) and a tetrahydrofuran (THF) solution of dimethylaminopyridine (DMAP) were each dropped into the above solution. After the dropping, the temperature of the resulting solution was allowed to rise to room temperature and the solution was stirred for 3 hours. Extraction was then performed using ethyl acetate, and the organic layer was washed with hydrochloric acid and water. Subsequently, the solvent in the organic layer was distilled off under reduced pressure. An obtained crude crystal was purified by silica gel column chromatography (ethyl acetate/heptane), and then 2 g of the exemplary compound (16) was obtained at a yield of 33%.

### Synthesis Example 2

### Synthesis of Compound (181)

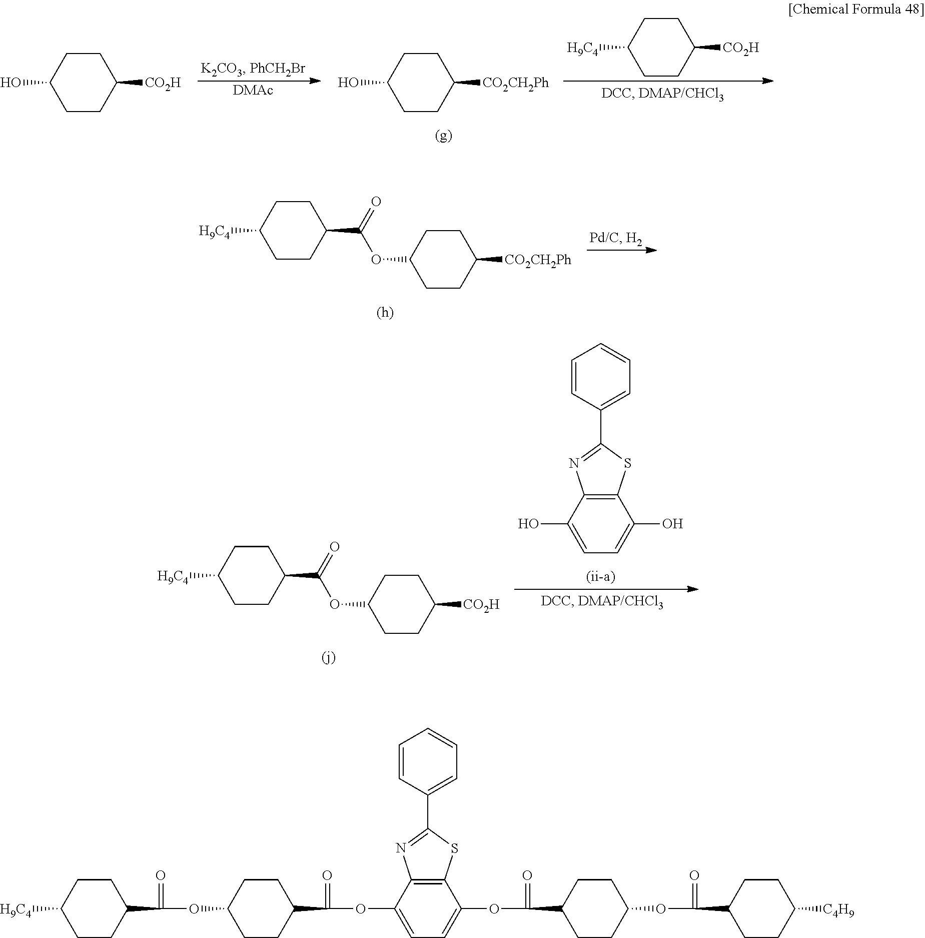

### Exemplary Compound (181)

### Synthesis Example of Intermediate (g)

62 g of trans-4-hydrocyclohexanecarboxylic acid, 72 g of potassium carbonate, 70 g of benzyl bromide (PhCH Br) and dimethylacetamide (DMAc) were mixed with each other. A mixed solution was subjected to nitrogen substitution. Then, the temperature was increased to 80° C. and the mixed solution was stirred. After cooled, the mixed solution was injected in a mixed solution of water and methylethyl ketone/heptane. An obtained solution was stirred, the water layer was removed, and then the organic layer was washed with water. The organic layer was dried and filtrated, and then heptane was added to the residue to obtain a solid matter. The obtained solid matter was subjected to filtration and vacuum drying. Then, 72 g of a benzyl ester (compound (g)) was obtained at a yield of 73%.

### Synthesis Example of Compound (h)

15 g of the compound (g), 17 g of trans-4-butylcyclohexanecarboxylic acid, 15 g of N,N-dicyclohexylcarbodiimide (DCC), 3.1 g of N,N-dimethylaminopyridine (DMAP) and 30 ml of anhydrous chloroform were mixed with each other. An obtained mixed solution was stirred in a nitrogen atmosphere at 40° C. After an hour passed, the mixed solution was cooled and stirred at room temperature. To the obtained reaction solution, heptane was added. Then a precipitated sediment was removed by filtration, and the filtrate was collected. The filtrate was washed with dilute hydrochloric acid. An obtained organic layer was dried and filtrated to obtain a residual. The residual was dissolved in methanol with heat. Thereafter, the solution was allowed to cool and the residual was re-crystallized to obtain 16 g of the compound (h) at yield of 30% on the basis of the compound (g).

### Synthesis Example of Compound (j)

16 g of the compound (h) and 75 ml of 2-propanol were mixed with each other. To the obtained solution, acetic acid (catalytic amount, 0.3 g) and 3.2 g of palladium-carbon (Pd/C) were added, and then the solution was stirred in a nitrogen atmosphere. The reaction solution was depressurized, stirred in a hydrogen atmosphere, and then subjected to nitrogen substitution. Thereafter, the resulting solution was subjected to celite filtration. An obtained residual was washed with water and subjected to vacuum drying to obtain 12 g of the compound (j) at a yield of 48%.

### Synthesis Example of Exemplary Compound (181)

1.0 g of the compound (ii-a), 1.0 g of the compound (j), 0.1 g of 4-dimethylaminopyridine (DMAP) and 90 g of chloroform were mixed with each other. Then a solution in which 2.1 g of N,N′-dicyclohexylcarbodiimide (DCC) was dissolved in 25 g of chloroform was dropped into the mixed solution, followed by stirring the resulting solution. A precipitated sediment was removed from filtration and then washed with dilute hydrochloric acid. Methanol was added to the collected organic layer under reduced pressure to obtain a solid matter. The obtained solid matter was washed with methanol to obtain 2.8 g of the compound (181) at a yield of 80%.

### Synthesis Example 3

### Synthesis of Compound (212)

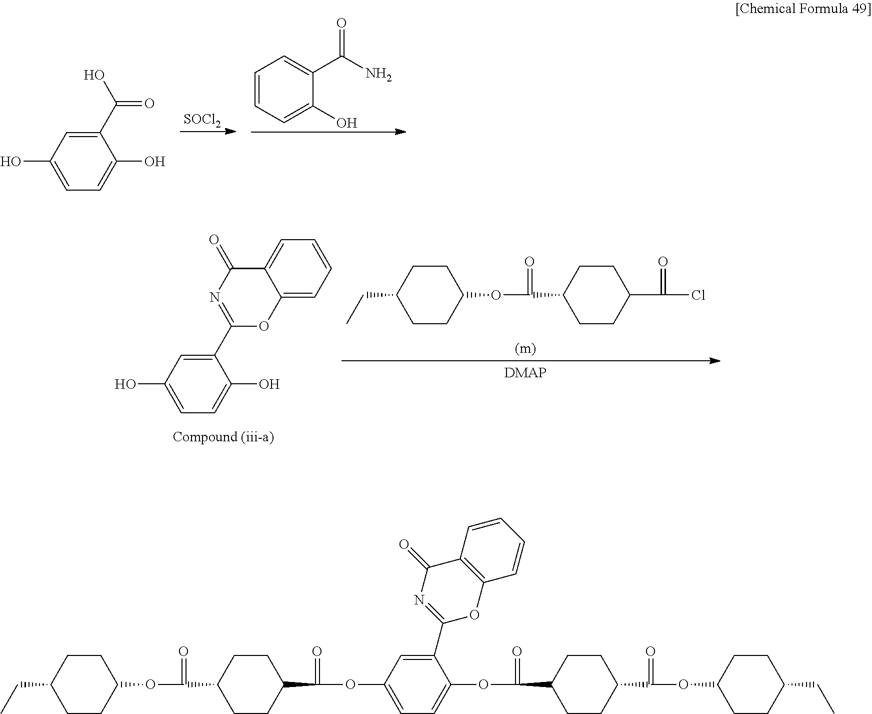

### Exemplary Compound (212)

3 g of 2,5-dihydroxybenzoic acid was dissolved in 30 ml of toluene, and 4.2 ml of sulfonyl chloride (SOCl₂) was then dropper into the solution. The solution was stirred for 2 hours. Toluene and sulfonyl chloride were distilled under reduced pressure. Thereafter, 20 m of toluene was added and 5 ml of a toluene solution dissolving 2.6 g of salicylamide was dropped into the resulting solution. The solution was then stirred at 60° C. for an hour, and extraction was performed adding water and ethyl acetate. The solvent was distilled off under reduced pressure from the organic layer to obtain 4.0 of the intermediate (iii-a) at a yield of 80%.

6.7 ml of sulfonyl chloride was added to 45 ml of a toluene solution dissolving 9.0 mg of the compound (m), followed by stirring at 60° C. for 2 hours. Thereafter, the solvent and sulfonyl chloride were distilled off under reduced pressure. Then 45 ml of tetrahydrofuran was added to the resulting solution and cooled in an ice water bath. Subsequently, 5 ml of a tetrahydrofuran solution dissolving 4.0 g of the intermediate (iii-a) and 1 ml of a tetrahydrofuran solution dissolving 2 mg of dimethylaminopyridine (DMAP) were each dropped into the cooled solution. The resulting solution was stirred at room temperature for 3 hours. Water and ethyl acetate were added thereto, and then the obtained solution was subjected to extraction. The solvent was distilled off under reduced pressure from the organic layer, and then the obtained crude crystal was purified by silica gel chromatography (ethyl acetate/heptane). The amount of the obtained product was 9.1 g and the yield was 75%.

### Synthesis of Polyester 1

251 g of 1,2-propyrene glycol, 278 g of phthalic anhydride, 91 g of adipic acid, 610 g of benzoic acid and 0.191 g of tetraisopropyl titanate as an esterification catalyst were poured into a four-neck 2 liter flask equipped with a thermometer, a stirrer and an Allihn condenser. The temperature was gradually risen to 230° C. in a nitrogen stream while the mixture is stirred. After a 15-hour condensation dehydration reaction, unreacted 1,2-propyrene glycol was distilled off under reduced pressure at 200° C. to obtain the polyester 1. The polyester 1 contains a polyester chain formed through condensation of 1,2-propyrene glycol, phthalic anhydride and adipic acid, and the polyester chain contains a benzoate ester at its end. The acid value of the polyester 1 was 0.10, and the number average molecular weight of the polyester 1 was 450.

(Production of λ/4 Phase Difference Film 101)

<Fine Particle Dispersion Liquid 1>

| | |
|---|---|
| Fine particle (Aerosil R972V manufactured by | 11 parts by mass |
| Nippon Aerosil Co., Ltd.) | |
| Ethanol | 89 parts by mass |

The above materials were mixed and stirred using a dissolver for 50 minutes, and then dispersion was conducted with a Manton-Gaulin homogenizer.

<Liquid Fine Particle Additive 1>

The fine particle dispersion liquid 1 was slowly added to methylene chloride sufficiently stirred in a dissolution container, followed by dispersion with the Attritor so as to adjust a secondary particle diameter(s) to be in a predetermined value(s). This dispersion liquid was filtrated with FINEMET manufactured by Nippon Seisen Co., Ltd. to obtain a liquid fine particle additive 1.

| | |
|---|---|
| Methylene chloride | 99 parts by mass |
| Fine particle dispersion liquid 1 | 5 parts by mass |

(A Main Dope Solution)

A main dope solution having the following composition was prepared. Firstly, methylene chloride and ethanol were poured in a pressurization dissolution tank. Then a cellulose ester was added to the solvent being stirred in the pressurization dissolution tank. The resulting solution was heated and stirred to completely solve the cellulose ester. Thereafter, the compound 170 represented by the general formula (A), TINUVIN 928 and the liquid fine particle additive were sequentially added to the solution and the solution was stirred. The stirred solution was then filtrated using the Azumi Filter No. 244 manufactured by AZUMI FILTER PAPER CO., LTD to obtain the main dope solution.

<Composition of Main Dope Solution>

| | | |
|---|---|---|
| Methylene chloride | 340 | parts by mass |
| Ethanol | 64 | parts by mass |
| Cellulose ester (Mw of 210000, the acetyl group | 100 | parts by mass |
| substitution degree of 2.30, and the total | | |
| substitution degree of 2.30) | | |
| Compound represented by general formula (A) | 2.5 | parts by mass |
| (170 in [Chemical Formula 31]) | | |
| TINUVIN 928 (ultraviolet absorber, | 2.0 | parts by mass |
| manufactured by BASF Japan Ltd.) | | |
| Liquid fine particle additive 1 | 1.0 | part by mass |

The above constituents were put in a sealed container, and then dissolution with stirring was conducted to prepare the dope solution. Subsequently, the dope solution was casted evenly on a stainless belt support of an endless belt casting device.

On the stainless belt support, the solvent in the casted film was allowed to vaporize until that the content of the solvent decreased to 75%, and then the film was removed from the stainless belt support. The removed cellulose ester film was stretched with heat in the width direction using a tenter. Thereafter, the film was conveyed through the drying zone with lots of the rolls to complete drying. The edge portions held with the tenter clips were then cut off using a laser cutter, and thereafter the resulting film was rewound.

The obtained film was obliquely stretched at 168° C. in the direction so that the angle between the slow axis and the longitudinal direction was 45° and a stretching ratio of 2.0. The λ/4 phase difference film 101 having a thickness of 50 μm (long film) was thus produced.

(Production of λ/4 Phase Difference Films 102 to 104 and 107 to 115)

λ/4 phase difference films 102 to 104 and 107 to 115 were each produced by the same way as the λ/4 phase difference film 101 was produced except that the resin, the additive (the compound represented by the general formula (A)), the stretching direction and the thickness were changed as described in Table 1.

In Table 1, CE represents the cellulose ester. The number average molecular weight of each cellulose ester was 210000, and the acetyl group substitution degree, the propionyl group substitution degree and the total substitution degree were varied as described in Table 1.

The λ/4 phase difference film 102 was stretched in the conveying direction at a stretching ratio of 2.0, and the λ/4 phase difference films 103, 104 and 107 to 115 were stretched in the same manner as the λ/4 phase difference film 101 was stretched.

### Synthesis of Polyester 1

251 g of 1,2-propyrene glycol, 278 g of phthalic anhydride, 91 g of adipic acid, 610 g of benzoic acid and 0.191 g of tetraisopropyl titanate as an esterification catalyst were poured into a four-neck 2 liter flask equipped with a thermometer, a stirrer and an Allihn condenser. The temperature was gradually risen to 230° C. in a nitrogen stream while the mixture is stirred. After a 15-hour condensation dehydration reaction, unreacted 1,2-propyrene glycol was distilled off under reduced pressure at 200° C. to obtain the polyester 1. The polyester 1 contains a polyester chain formed through condensation of 1,2-propyrene glycol, phthalic anhydride and adipic acid, and the polyester chain contains a benzoate ester at its end. The acid value of the polyester 1 was 0.10, and the number average molecular weight of the polyester 1 was 450.

(Production of λ/4 Phase Difference Film 105)

(Formation of First Oriented Film)

An 100 μm thick, 650 mm wide and 500 mm long rolled optical isotropic triacetylcellulose film was used as a transparent support. A diluent of the following copolymer (1) was seamlessly applied on the transparent support to obtain a first (perpendicular) oriented film having a thickness of 0.5 μm. Subsequently, rubbing was performed seamlessly on the obtained oriented film in the direction at 16° to the right of the longitudinal direction of the transparent support.

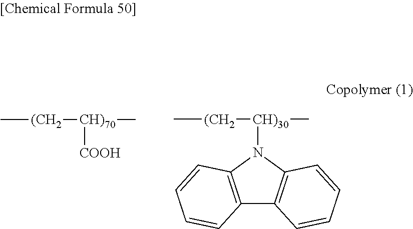

(Formation of First Optical Anisotropic Layer)

On the first oriented film, an application liquid of the following composition was seamlessly applied using a bar coater and then dried and heated (orientating and maturing). Subsequently, ultraviolet irradiation was conducted to obtain a first optical anisotropic layer having a thickness of 1.6 μm. The first optical anisotropic layer had the slow axis at 74° to the longitudinal direction of the transparent support.

(Composition of Application Liquid of First Optical Anisotropic Layer)

| | | |
|---|---|---|
| Rod-like liquid crystal compound (1) below | 14.5 | parts by mass |
| Sensitizer below | 1.0 | part by mass |
| Photopolymerization initiator below | 3.0 | parts by mass |
| Horizontal orientation promoter below | 1.0 | part by mass |
| Methylethyl ketone | 80.5 | parts by mass |

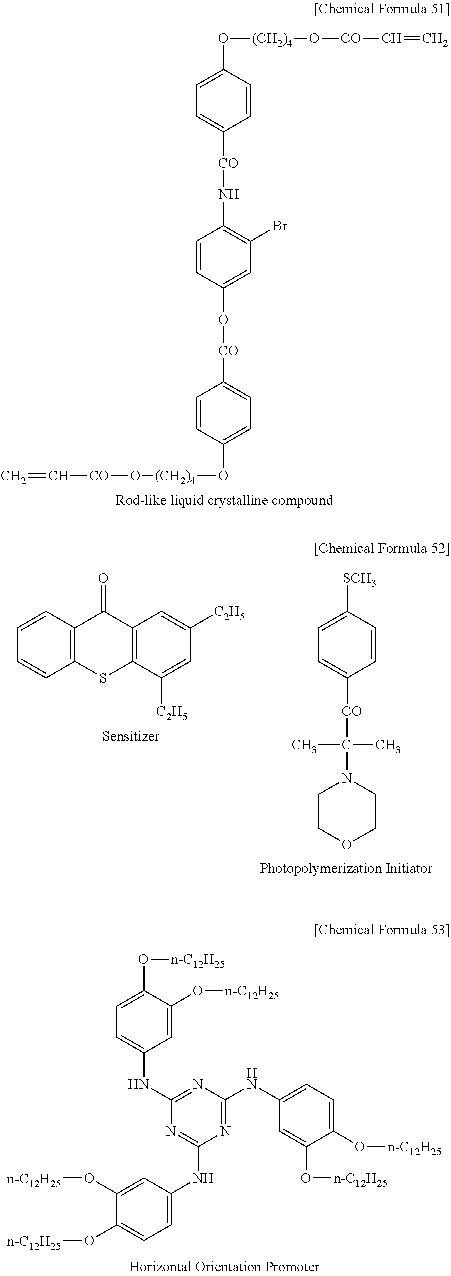

(Formation of Second Oriented Film)

On the first optical anisotropic layer, a diluent of the copolymer (2) below was seamlessly applied to obtain a second (parallel) oriented film having a thickness of 0.5 μm. Subsequently, rubbing was performed seamlessly on the obtained orientated film in the direction at 16° to the left of the longitudinal direction of the transparent support (at 58° to the right of the slow axis of the first optical anisotropic layer).

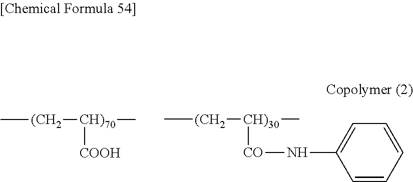

(Formation of Second Optical Anisotropic Layer)

On the second oriented film, an application liquid of the following composition was seamlessly applied using a bar coater and then dried and heated (orientating and maturing). Subsequently, ultraviolet irradiation was conducted to obtain a second optical anisotropic layer having a thickness of 0.8 μm. The λ/4 phase difference film 105 was thus produced. The second optical anisotropic layer had the slow axis at 16° to the right of the longitudinal direction of the transparent support.

(Composition of Application Liquid of Second Optical Anisotropic Layer)

| | | |
|---|---|---|
| Rod-like liquid crystal compound (1) used in | 13.0 | parts by mass |
| first optical anisotropic layer | | |
| Sensitizer used in first optical anisotropic layer | 1.0 | part by mass |
| Photopolymerization initiator used in | 3.0 | parts by mass |
| first optical anisotropic layer | | |
| Horizontal orientation promoter used in | 1.0 | part by mass |
| first optical anisotropic layer | | |
| Methylethyl ketone | 82.0 | parts by mass |

(Production of λ/4 Phase Difference Film 106)

A λ/4 phase difference film 106 was produced by the same way as the λ/4 phase difference film was produced except that the above-synthesized polyester 1 was added in an amount of 3.0% by mass and triazine below was added in an amount of 5.0% by mass instead of adding the compound 170 represented by the general formula (A) in an amount of 2.5 parts by mass.

Triazine 1

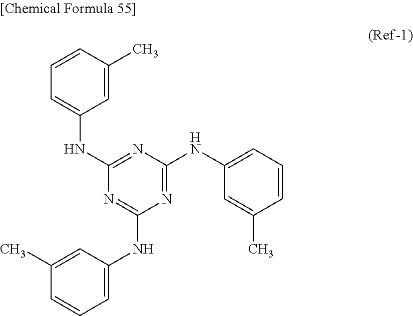 [SMILES: Cc1cccc(Nc2nc(Nc3cccc(C)c3)nc(Nc3cccc(C)c3)n2)c1]

(Production of λ/4 Phase Difference Film 116)

A norbornene resin film with a target dry thickness of 87 μm was produced using a melt casting film formation device.

A norbornene resin (ZEONOR 1420, manufactured by ZEON CORPORATION) is melted using a double-screw extruder at 250° C. Thereafter, the melt was filtrated using FINEMET NF manufactured by Nippon Seisen Co., Ltd. (nominal fineness of the filtration of 15 μm) and then was pelletized. A second filtration was performed with FINEMET NF manufactured by Nippon Seisen Co., Ltd. (nominal fineness of the filtration of 20 μm) using the pellet. Thereafter, melt extrusion was conducted at 250° C. and the melt was fed in a sheet form on a cooling drum at 30° C. to cool and solidify the melt to obtain a norbornene resin sheet.

The obtained resin sheet is obliquely stretched at 170° C. and a stretching ratio of 1.5 so that the angle between the slow axis and the longitudinal direction of the film was 45°. The λ/4 phase difference film 116 which is an alicyclic polyolefin resin was thus produced.

(Provision of λ/4 Phase Difference Films 117 and 118)

PURE-ACE WRS148 (polycarbonate film with a thickness of 50 μm, manufactured by TEIJIN LIMITED) was used as the λ/4 phase difference film 117.

PURE-ACE TT-138 (polycarbonate film with a thickness of 40 μm, manufactured by TEIJIN LIMITED) was used as the λ/4 phase difference film 118.

The λ/4 phase difference films 117 and 118 were provided as described above.

(Measurement of Ro(450), Ro(550) and Ro(650))

In-plane retardation at each light wavelength was obtained by the method described in the “Measurement of In-plane Retardation” section above.

In addition, DSP(450/550) and DSP(550/650) were obtained using the above in-plane retardation.

(Measurement of Photoelastic Coefficient)

The photoelastic coefficients were measured by the method described in the “Photoelastic Coefficient” section above, and then the ratio of photoelastic coefficients (450/650) was obtained.

Results are shown in Table 2.

TABLE 1

| | RESIN | | | | | | |
|---|---|---|---|---|---|---|---|
| | | ACETYL | PROPIONYL | | | | |
| λ/4 PHASE | | GROUP | GROUP | TOTAL | | | |
| DIFFERENCE | | SUBSTITUTION | SUBSTITUTION | SUBSTITUTION | | STRETCHING | THICKNESS |
| FILM | TYPE | DEGREE | DEGREE | DEGREE | ADDITIVE | DIRECTION | [μm] |
| 101 | CE | 2.3 | 0 | 2.3 | 170 | OBLIQUE | 50 |
| 102 | CE | 2.45 | 0 | 2.45 | 171 | CONVEYING | 64 |
| | | | | | | DIRECTION | |
| 103 | CE | 2.55 | 0 | 2.55 | 181 | OBLIQUE | 50 |
| 104 | CE | 2.65 | 0 | 2.65 | 196 | OBLIQUE | 70 |
| 105 | ISOTROPIC TAC (TOTAL SUBSTITUTION DEGREE OF 2.8)/ORIENTED | | | | | — | 102 |
| | FILM/ROD-LIKE CURED LIQUID CRYSTAL LAYER | | | | | | |
| 106 | CE | 1.9 | 0.4 | 2.3 | TRIAZINE 1/ | OBLIQUE | 50 |
| | | | | | POLYESTER 1 | | |
| 107 | CE | 1.5 | 0.9 | 2.4 | 212 | OBLIQUE | 60 |
| 108 | CE | 2.3 | 0.4 | 2.7 | 16 | OBLIQUE | 80 |
| 109 | CE | 0.7 | 2 | 2.7 | 171 | OBLIQUE | 80 |
| 110 | CE | 1.7 | 1 | 2.7 | 181 | OBLIQUE | 80 |
| 111 | CE | 1.2 | 1.5 | 2.7 | 212 | OBLIQUE | 80 |
| 112 | CE | 2.2 | 0 | 2.2 | 212 | OBLIQUE | 60 |
| 113 | CE | 2.8 | 0 | 2.8 | 212 | OBLIQUE | 200 |
| 114 | CE | 1.5 | 0.6 | 2.1 | 212 | OBLIQUE | 60 |
| 115 | CE | 1.1 | 1.7 | 2.8 | 212 | OBLIQUE | 200 |
| 116 | COP | — | — | — | — | OBLIQUE | 120 |
| 117 | PC1 | — | — | — | — | CONVEYING | 50 |
| | | | | | | DIRECTION | |
| 118 | PC2 | — | — | — | — | CONVEYING | 40 |
| | | | | | | DIRECTION | |

TABLE 2

| | | | | WAVELENGTH | | PHOTOELASTIC | | | RATIO OF |
|---|---|---|---|---|---|---|---|---|---|
| λ/4 PHASE | IN-PLANE RETARDATION | | | DISPERSION | | COEFFICIENT | | | PHOTOELASTIC |
| DIFFERENCE | Ro (450) | Ro (550) | Ro (650) | DSP | DSP | (×10⁻¹²Pa⁻¹) | | | COEFFICIENTS |
| FILM | [nm] | [nm] | [nm] | (450/550) | (550/650) | (450) | (550) | (650) | (450/650) |
| 101 | 132 | 138 | 140 | 0.96 | 0.99 | 87.9 | 84.1 | 80.3 | 1.09 |
| 102 | 137 | 148 | 153 | 0.93 | 0.97 | 89.4 | 87.8 | 85.0 | 1.05 |
| 103 | 122 | 132 | 140 | 0.92 | 0.94 | 91.8 | 90.5 | 89.3 | 1.03 |
| 104 | 113 | 135 | 150 | 0.84 | 0.90 | 97.5 | 93.2 | 90.2 | 1.08 |
| 105 | 110 | 136 | 146 | 0.81 | 0.93 | 135.4 | 120.8 | 116.3 | 1.16 |
| 106 | 129 | 131 | 133 | 0.98 | 0.98 | 93.4 | 89.5 | 85.6 | 1.09 |
| 107 | 137 | 140 | 153 | 0.98 | 0.92 | 101.8 | 97.5 | 92.7 | 1.10 |
| 108 | 117 | 148 | 164 | 0.79 | 0.90 | 95.3 | 94.3 | 93.4 | 1.02 |
| 109 | 110 | 130 | 143 | 0.85 | 0.91 | 89.3 | 87.8 | 85.1 | 1.05 |
| 110 | 120 | 145 | 163 | 0.83 | 0.89 | 102.2 | 100.3 | 98.7 | 1.04 |
| 111 | 103 | 128 | 145 | 0.80 | 0.88 | 101.4 | 96.2 | 92.1 | 1.10 |
| 112 | 136 | 140 | 145 | 0.97 | 0.97 | 91.0 | 85.6 | 79.1 | 1.15 |
| 113 | 117 | 148 | 164 | 0.79 | 0.90 | 104.3 | 91.5 | 85.2 | 1.22 |
| 114 | 144 | 145 | 146 | 0.99 | 0.99 | 89.1 | 83.7 | 77.8 | 1.15 |
| 115 | 120 | 141 | 160 | 0.85 | 0.88 | 107.7 | 98.1 | 92.6 | 1.16 |
| 116 | 140 | 140 | 140 | 1.00 | 1.00 | 59.4 | 63.3 | 67.4 | 0.88 |
| 117 | 129 | 144 | 148 | 0.90 | 0.97 | 232.6 | 228.6 | 223.4 | 1.04 |
| 118 | 149 | 138 | 128 | 1.08 | 1.08 | 228.4 | 223.8 | 217.4 | 1.05 |

(Production of Polarizing Plate 201)

A long polyvinyl alcohol film having a thickness of 120 μm was uniaxially stretched (at 110° C. and a stretching ratio of 5).

This stretched film was then immersed in an aqueous solution composed of 0.075 g of iodide, 5 g of potassium iodide and 100 g of water for 60 seconds, and subsequently immersed in an aqueous solution at 68° C. composed of 6 g of potassium iodide, 7.5 g of boric acid and 100 g of water. The immersed film was washed with water and then dried. A long polarizer was thus obtained.

The obtained λ/4 phase difference film 101 was adhered to one side of the long polarizer using a 5% aqueous solution of a completely saponified polyvinyl alcohol as an adhesive. In the adhesion, the longitudinal direction of the polarizer and that of the λ/4 phase difference film were matched to each other, and the angle between the transmission axis of the polarizer and the slow axis of the λ/4 phase difference film was 45°. Similarly, TAC film KC4UA (manufactured by KONICA MINOLTA OPTO, INC.) saponified with alkali was adhered to the other side of the polarizer. The polarizing plate 201 (long plate) was thus produced.

(Production of Polarizing Plates 202 to 218)

Polarizing plates 202 to 218 were prepared by the same way as the polarizing plate 201 was produced except that the λ/4 phase difference films 102 to 118 were used, respectively, in place of the λ/4 phase difference film 101. In the production of the polarizing plate 205, the polarizer was adhered to the side opposite to the second optical anisotropic film of the λ/4 phase difference film 105.

(Production of Organic EL Display Device 201)

An organic EL display device was produced by the following procedures.

For forming the organic EL display device of the Example, a TFT was formed on a glass substrate; on the glass substrate, a reflection electrode formed of chrome and having a thickness of 80 nm by sputtering; on the reflection electrode, an anode was formed using ITO by sputtering to obtain a thickness of 40 nm; on the anode, a hole-transporting layer having a thickness of 80 nm was formed using poly(3,4-ethylenedioxythiophene)-polystyrene sulfonate (PEDOT:PSS) by sputtering; on the hole-transporting layer, and on the hole-transporting layer, light-emitting layers each having a thickness of 100 nm and for colors of R, G or B were formed using a shadow mask. The red light-emitting layer having a thickness of 100 nm was formed by co-deposition of tris (8-hydroxy quinolinato) aluminum (Alq₃) as a host and a light-emitting material [4-(dicyanomethylene)-2-methyl-6 (p-dimethylaminostyryl)-4H-pyran] (DCM) (at a ratio of 99:1 by mass). The green light-emitting layer having a thickness of 100 nm was formed by co-deposition of Alq₃ as a host and a light-emitting compound Coumarin6 (at a ratio of 99:1 by mass). The blue light-emitting layer having a thickness of 100 nm was formed by co-deposition of BAlq as a host and a light-emitting compound Perylene (at a ratio of 90:10 by mass).

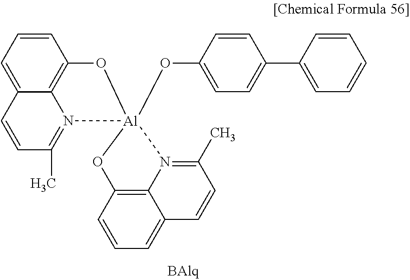

On the light-emitting layer, a first cathode having a thickness of 4 nm and low work function that enables effective injection of electrons (also referred to as a buffer layer) was formed using calcium by vacuum deposition; on the first cathode, a second cathode having a thickness of 2 nm was formed using aluminum. Aluminum used in the second cathode can prevent calcium in the first cathode from being chemically changed when a transparent electrode is formed on the second cathode by sputtering. An organic light-emitting layer was thus obtained. Thereafter, a transparent electroconductive film having a thickness of 80 nm was formed on the cathode by sputtering. ITO was used for forming the transparent electroconductive film. On the transparent electroconductive film, an insulation film having a thickness of 200 nm was formed using silicon dioxide by a CVD method. An organic EL element was thus obtained.

Subsequently, an adhesive layer was applied to the surface to face to the λ/4 phase difference film of the polarizing plate 201. Then, as illustrated in FIG. 1, the polarizing plate was adhered to the above-described insulation film. The organic EL display device 201 was thus produced.

(Production of Organic EL Display Devices 202 to 218)

Organic EL display devices 202 to 218 were prepared by the same way as the organic EL display device 201 was produced except that polarizing plates 202 to 218 were used, respectively.

(Evaluation of Reflection of External Light)

The organic EL display devices 201 to 218 were evaluated for a red hue due to the reflection of external light by the method described in the “Reflection of External Light” subsection in the “Evaluation of Organic EL Display Device” section above, and judged according to the following criteria.

⊚: no reflection of external light was observed

◯: redness due to reflection of external light was slightly observed but can be ignored

Δ: redness due to refection of external light was annoying

X: redness due to reflection of external light was very annoying

(Evaluation of Hue Change)

The organic EL display devices 201 to 218 were evaluated by the method described in the “Hue Change” subsection in the “Evaluation of Organic EL Display Device” section above involving 10 observers, and were judged according to the following criteria.

In the case where a hue at 5° C. and 55% RH and a hue at 40 C and 55% RH were judged equal, 3 points were scored; in the case where these hues were judged slightly different from each other, one point was scored; and in the case where these hues were judged clearly different from each other, no point was scored.

(Criteria for Evaluation of Hue Change)

⊚: the sum of the scores from the observation by 10 observers was 27 points or more

◯: the sum of the scores from the observation by 10 observers was 24 or more and less than 27 points

Δ: the sum of the scores from the observation by 10 observers was 18 or more and less than 24 points

X: the sum of the scores from the observation by 10 observers was 17 points or less

Results are shown in Table 3.

TABLE 3

| | | | EXTERNAL | | |
|---|---|---|---|---|---|
| ORGANIC EL | POLARIZING | λ/4 PHASE | LIGHT | | |
| DISPLAY DEVICE | PLATE | DIFFERENCE FILM | REFLECTION | HUE CHANGE | NOTE |
| 201 | 201 | 101 | ⊚ | ◯ | PRESENT INVENTION |
| 202 | 202 | 102 | ◯ | ⊚ | PRESENT INVENTION |
| 203 | 203 | 103 | ⊚ | ⊚ | PRESENT INVENTION |
| 204 | 204 | 104 | ⊚ | ◯ | PRESENT INVENTION |
| 205 | 205 | 105 | ◯ | Δ | PRESENT INVENTION |
| 206 | 206 | 106 | ◯ | ◯ | PRESENT INVENTION |
| 207 | 207 | 107 | ⊚ | ◯ | PRESENT INVENTION |
| 208 | 208 | 108 | ⊚ | ⊚ | PRESENT INVENTION |
| 209 | 209 | 109 | ⊚ | ⊚ | PRESENT INVENTION |
| 210 | 210 | 110 | ⊚ | ⊚ | PRESENT INVENTION |
| 211 | 211 | 111 | ⊚ | ◯ | PRESENT INVENTION |
| 212 | 212 | 112 | ◯ | Δ | PRESENT INVENTION |
| 213 | 213 | 113 | ⊚ | X | COMPARATIVE EXAMPLE |
| 214 | 214 | 114 | ◯ | Δ | PRESENT INVENTION |
| 215 | 215 | 115 | ⊚ | Δ | PRESENT INVENTION |
| 216 | 216 | 116 | X | X | COMPARATIVE EXAMPLE |
| 217 | 217 | 117 | ◯ | Δ | PRESENT INVENTION |
| 218 | 218 | 118 | X | Δ | COMPARATIVE EXAMPLE |

As evident from Table 3, the organic EL display devices of the present invention are excellent because the reflection of external light and the hue change are small. The hue change is more improved when the λ/4 phase difference film has a degree of substitution with an acetyl group of 2.3 to 2.7 and a degree of substitution with an acyl group other than an acetyl group of 0 to 2.0. In addition, when the λ/4 phase difference film contains the compound represented by the general formula (A), the reflection of external light is further improved. Further, in the organic EL display device of the present invention, when the ratio of photoelastic coefficients is 1.0 to 1.5, the hue change is further improved.

### INDUSTRIAL APPLICABILITY

The organic EL display device that prevents reflection of external light and improves its contrast and color tone can be applied to various displays that are used for reproducing quality images even in a light place.

### DESCRIPTION OF SIGNS

A Organic electroluminescent display device
B Organic EL element
C Polarizing plate
1 Substrate
2 TFT
3 Metal Electrode
4 ITO
5 Hole-transporting layer
6 Light-emitting layer
7 Buffer layer
8 Cathode
9 ITO
10 Insulation film
11 Optical film for T2 layer
12 Polarizer
13 Optical film for T1 layer
14 Cured layer
15 Reflection preventing layer
DR1 Feeding direction
DR2 Rewinding direction
θi Feeding angle (angle between Feeding angle and Rewinding angle)
CR, CL Clip
Wo Width of Film before stretching
W Width of Film after stretching

1. An organic electroluminescent display device comprising:
a protective film;
a polarizer;
a λ/4 phase difference film; and
an organic electroluminescent element in this order from a viewing side of the organic electroluminescent display device, wherein
the λ/4 phase difference film satisfies following expressions (1) and (2):
Ro(450)<Ro(550)<Ro(650) Expression (1)
0.90<ratio of photoelastic coefficients(450/650)<1.20 Expression (2)
wherein in the expression (1), Ro(450), Ro(550) and Ro(650) are in-plane retardations obtained from measurement at 23° C. and 55% RH of the λ/4 phase difference film at a light wavelength of 450 nm, 550 nm and 650 nm, respectively; and
in the expression (2), the ratio of photoelastic coefficients (450/650) is obtained by dividing a photoelastic coefficient (450) obtained from measurement at 23° C. and 55% RH of the λ/4 phase difference film at a light wavelength of 450 nm by a photoelastic coefficient (650) obtained from measurement under the same condition of the λ/4 phase difference film at a light wavelength of 650 nm.

2. The organic electroluminescent display device of claim 1, wherein
the λ/4 phase difference film comprises a cellulose ester(s), and at least one of the cellulose ester(s) satisfies following expressions (3) and (4):
2.3≦A+B≦2.7 Expression (3)
0≦B≦2.0 Expression (4)
wherein in the expressions (3) and (4), A represents a degree of substitution with an acetyl group, and B represents a degree of substitution with an acyl group other than an acetyl group.

3. The organic electroluminescent display device of claim 1, wherein
the λ/4 phase difference film comprises a compound represented by a following general formula (A) 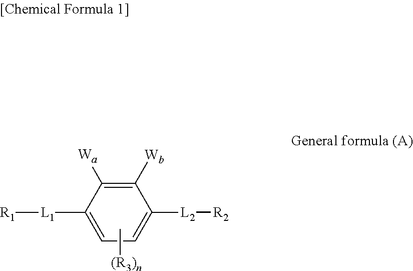
wherein in the general formula (A), L₁ and L₂ each independently represent a single-bond or divalent linking group; R₁, R₂ and R₃ each independently represent a substituent; n represents an integer from 0 to 2; and Wa and Wb each represent a hydrogen atom or a substituent, wherein
(I) Wa and Wb are bonded to each other to form a ring;
(II) at least either of Wa and Wb contains a ring structure; or
(III) at least either of Wa and Wb may be an alkenyl group or alkynyl group.

4. The organic electroluminescent display device of claim 3, wherein
the compound represented by the general formula (A) is a compound represented by a following general formula (1): 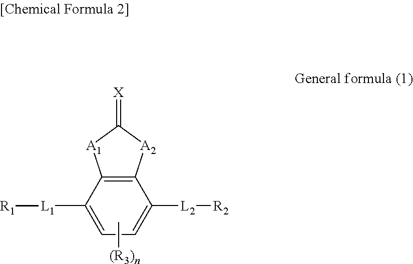
wherein in the general formula (1), A₁ and A₂ each independently represent O, S, NRx (Rx represents a hydrogen atom or a substituent) or CO; X represents a non-metal atom of Groups 14 to 16 of the periodic table; and L₁, L₂, R₂, R₂, R₃ and n correspond to L₁, L₂, R₂, R₂, R₃ and n of the general formula (A), respectively.

5. The organic electroluminescent display device of claim 3, wherein
the compound represented by the general formula (A) is a compound represented by a following general formula (2): 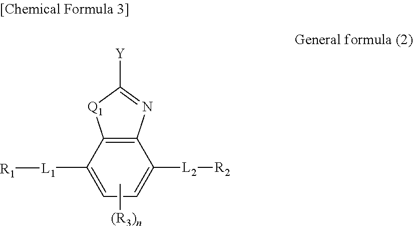
wherein in the general formula (2), Q₁ represents O, S, NRy (Ry represents a hydrogen atom or a substituent), —CRaRb— (Ra and Rb each represent a hydrogen atom or a substituent) or CO; Y represents a substituent; and L₁, L₂, R₁, R₂, R₃ and n correspond to L₁, L₂, R₁, R₂, R₃ and n of the general formula (A), respectively.

6. The organic electroluminescent display device of claim 3, wherein
the compound represented by the general formula (A) is a compound represented by a following general formula (3): 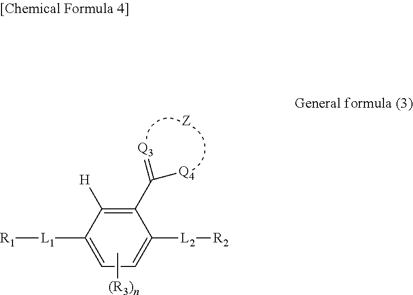
wherein in the formula (3), Q₃ represents N or CRz (Rz represents a hydrogen atom or a substituent); Q₄ represents a non-metal atom of Groups 14 to 16 of the periodic table; Z represents a group of non-metal atoms forming a ring together with Q₃ and Q₄; and L₁, L₂, R₂, R₂, R₃ and n correspond to L₁, L₂, R₂, R₂, R₃ and n of the general formula (A), respectively.

7. The organic electroluminescent display device of claim 1, wherein
the λ/4 phase difference film is an obliquely stretched resin film.
